(19) United States
(12) Patent Application Publication
(10) Pub. No.: US 2025/0107088 A1
(43) Pub. Date: Mar. 27, 2025

(54) SEMICONDUCTOR MEMORY DEVICE

(71) Applicant: Kioxia Corporation, Tokyo (JP)

(72) Inventors: Junpei HASHIMOTO, Yokkaichi (JP); Takuro URAYAMA, Mie (JP); Daigo ICHINOSE, Nagoya (JP); Akiko NOMACHI, Yokkaichi (JP)

(73) Assignee: Kioxia Corporation, Tokyo (JP)

(21) Appl. No.: 18/884,563

(22) Filed: Sep. 13, 2024

(30) Foreign Application Priority Data
Sep. 21, 2023 (JP) 2023-154209

(51) Int. Cl. H10B 43/27; H10B 41/27

(52) U.S. Cl. CPC H10B 43/27; H10B 41/27

(57) ABSTRACT

A semiconductor memory device includes finger structures arranged in a first direction. The finger structures include a first structure and a second structure different in position in a stacking direction. The first structure and the second structure include insulating member rows including insulating members. Among the insulating member rows in the first structure and the second structure of a first finger structure, one closet to a second finger structure includes a first insulating member and a second insulating member. Among the insulating member rows in the first structure and the second structure of the second finger structure, one closet to the first finger structure includes a third insulating member and a fourth insulating member. A distance in the first direction between the first insulating member and the third insulating member is smaller than a distance in the first direction between the second insulating member and the fourth insulating member.

### CROSS-REFERENCE TO RELATED APPLICATIONS

This application is based upon and claims the benefit of Japanese Patent Application No. 2023-154209, filed on Sep. 21, 2023, the entire contents of which are incorporated herein by reference.

### BACKGROUND

### Field

Embodiments described herein relate generally to a semiconductor memory device.

### Description of the Related Art

There has been known a semiconductor memory device including a plurality of conductive layers stacked in a stacking direction, a semiconductor layer opposed to these plurality of conductive layers, and a gate insulating film disposed between the plurality of conductive layers and the semiconductor layer. The gate insulating film includes a memory portion that is, for example, an insulating electric charge accumulating film of silicon nitride (SiN) or the like or a conductive electric charge accumulating film of a floating gate or the like and configured to store data.

### BRIEF DESCRIPTION OF THE DRAWINGS

FIG. 1 is a schematic circuit diagram illustrating a configuration of a semiconductor memory device according to a first embodiment;

FIG. 2 is a schematic plan view illustrating a part of the configuration of the semiconductor memory device;

FIG. 3 is a schematic plan view illustrating a part of the configuration of the semiconductor memory device;

FIG. 4 is a schematic plan view illustrating a part of the configuration of the semiconductor memory device;

FIG. 5 is a schematic plan view illustrating a part of the configuration of the semiconductor memory device;

FIG. 6 is a schematic cross-sectional view illustrating a part of the configuration of the semiconductor memory device;

FIG. 7 is a schematic cross-sectional view illustrating a part of the configuration of the semiconductor memory device;

FIG. 8 is a schematic cross-sectional view illustrating a part of the configuration of the semiconductor memory device;

FIG. 9 is a schematic plan view illustrating a part of the configuration of the semiconductor memory device;

FIG. 10 is a schematic cross-sectional view illustrating a part of the configuration of the semiconductor memory device;

FIG. 11 is a schematic cross-sectional view illustrating a part of the configuration of the semiconductor memory device;

FIG. 12 is a schematic cross-sectional view illustrating a part of the configuration of the semiconductor memory device;

FIG. 13 is a schematic cross-sectional view illustrating a part of the configuration of the semiconductor memory device;

FIG. 14 is a schematic cross-sectional view for describing a method for manufacturing the semiconductor memory device according to the first embodiment;

FIG. 15 is a schematic cross-sectional view for describing the manufacturing method;

FIG. 16 is a schematic cross-sectional view for describing the manufacturing method;

FIG. 17 is a schematic cross-sectional view for describing the manufacturing method;

FIG. 18 is a schematic cross-sectional view for describing the manufacturing method;

FIG. 19 is a schematic cross-sectional view for describing the manufacturing method;

FIG. 20 is a schematic plan view for describing the manufacturing method;

FIG. 21 is a schematic cross-sectional view for describing the manufacturing method;

FIG. 22 is a schematic cross-sectional view for describing the manufacturing method;

FIG. 23 is a schematic cross-sectional view for describing the manufacturing method;

FIG. 24 is a schematic cross-sectional view for describing the manufacturing method;

FIG. 25 is a schematic cross-sectional view for describing the manufacturing method;

FIG. 26 is a schematic cross-sectional view for describing the manufacturing method;

FIG. 27 is a schematic cross-sectional view for describing the manufacturing method;

FIG. 28 is a schematic cross-sectional view for describing the manufacturing method;

FIG. 29 is a schematic plan view for describing the manufacturing method;

FIG. 30 is a schematic cross-sectional view for describing the manufacturing method;

FIG. 31 is a schematic cross-sectional view for describing the manufacturing method;

FIG. 32 is a schematic cross-sectional view for describing the manufacturing method;

FIG. 33 is a schematic cross-sectional view for describing the manufacturing method;

FIG. 34 is a schematic cross-sectional view for describing the manufacturing method;

FIG. 35 is a schematic cross-sectional view for describing the manufacturing method;

FIG. 36 is a schematic cross-sectional view for describing the manufacturing method;

FIG. 37 is a schematic cross-sectional view for describing the manufacturing method;

FIG. 38 is a schematic cross-sectional view for describing the manufacturing method;

FIG. 39 is a schematic cross-sectional view for describing the manufacturing method;

FIG. 40 is a schematic plan view for describing the manufacturing method;

FIG. 41 is a schematic cross-sectional view for describing the manufacturing method;

FIG. 42 is a schematic cross-sectional view for describing the manufacturing method;

FIG. 43 is a schematic plan view for describing the manufacturing method;

FIG. 44 is a schematic cross-sectional view for describing the manufacturing method;

FIG. 45 is a schematic cross-sectional view for describing the manufacturing method;

FIG. 46 is a schematic cross-sectional view for describing the manufacturing method;

FIG. 47 is a schematic cross-sectional view for describing the manufacturing method;

FIG. 48 is a schematic cross-sectional view for describing the manufacturing method;

FIG. 49 is a schematic cross-sectional view for describing the manufacturing method;

FIG. 50 is a schematic cross-sectional view for describing the manufacturing method;

FIG. 51 is a schematic cross-sectional view for describing the manufacturing method;

FIG. 52 is a schematic plan view illustrating a part of a configuration of a semiconductor memory device according to a second embodiment;

FIG. 53 is a schematic plan view illustrating a part of the configuration of the semiconductor memory device;

FIG. 54 is a schematic cross-sectional view illustrating a part of the configuration of the semiconductor memory device;

FIG. 55 is a schematic cross-sectional view illustrating a part of the configuration of the semiconductor memory device;

FIG. 56 is a schematic cross-sectional view illustrating a part of the configuration of the semiconductor memory device;

FIG. 57 is a schematic cross-sectional view for describing a method for manufacturing the semiconductor memory device according to the second embodiment;

FIG. 58 is a schematic cross-sectional view for describing the manufacturing method;

FIG. 59 is a schematic cross-sectional view for describing the manufacturing method;

FIG. 60 is a schematic cross-sectional view for describing the manufacturing method;

FIG. 61 is a schematic cross-sectional view for describing the manufacturing method;

FIG. 62 is a schematic cross-sectional view for describing the manufacturing method;

FIG. 63 is a schematic cross-sectional view for describing the manufacturing method;

FIG. 64 is a schematic cross-sectional view for describing the manufacturing method;

FIG. 65 is a schematic cross-sectional view for describing the manufacturing method;

FIG. 66 is a schematic cross-sectional view for describing the manufacturing method;

FIG. 67 is a schematic cross-sectional view for describing the manufacturing method;

FIG. 68 is a schematic cross-sectional view for describing the manufacturing method;

FIG. 69 is a schematic cross-sectional view illustrating a part of a configuration of a semiconductor memory device according to a third embodiment;

FIG. 70 is a schematic cross-sectional view illustrating a part of the configuration of the semiconductor memory device;

FIG. 71 is a schematic cross-sectional view illustrating a part of a configuration of a semiconductor memory device according to a fourth embodiment;

FIG. 72 is a schematic plan view illustrating a part of a configuration of a semiconductor memory device according to another embodiment;

FIG. 73 is a schematic cross-sectional view illustrating a part of the configuration of the semiconductor memory device according to the embodiment corresponding to FIG. 72;

FIG. 74 is a schematic cross-sectional view illustrating a part of a configuration of a semiconductor memory device according to another embodiment; and

FIG. 75 is a schematic cross-sectional view illustrating a part of the configuration of the semiconductor memory device according to the embodiment corresponding to FIG. 74.

### DETAILED DESCRIPTION

A semiconductor memory device according to one embodiment comprises: a plurality of finger structures arranged in a first direction and extending in a second direction intersecting with the first direction; a first inter-finger insulating member disposed between a first finger structure and a second finger structure adjacent in the first direction among the plurality of finger structures, the first inter-finger insulating member extending in a stacking direction intersecting with the first direction and the second direction and extending in the second direction; and a plurality of bit lines disposed on one side in the stacking direction with respect to the plurality of finger structures and the first inter-finger insulating member, the plurality of bit lines being arranged in the second direction and extending in the first direction.

Each of the plurality of finger structures includes a first structure and a second structure disposed on a plurality of bit lines side in the stacking direction with respect to the first structure. The first structure and the second structure include: a plurality of conductive layers stacked in the stacking direction, extending in the second direction over a first region and a second region arranged in the second direction, and including a plurality of terrace portions disposed in the second region; a first semiconductor column disposed in the first region, extending in the stacking direction, opposed to the plurality of conductive layers, and electrically connected to any of the plurality of bit lines; a first electric charge accumulating film disposed between the plurality of conductive layers and the first semiconductor column; and a plurality of insulating member rows disposed in the second region and arranged in the first direction, each of the plurality of insulating member rows including a plurality of insulating members different in position in the second direction, each of the plurality of insulating members having an outer peripheral surface at least partially surrounded by at least a part of the plurality of conductive layers when viewed in the stacking direction.

The first inter-finger insulating member widens in the first direction from an opposite side of the plurality of bit lines in the stacking direction toward the plurality of bit lines side in the stacking direction in a portion at least partially over both of a position in the stacking direction corresponding to the first structure and a position in the stacking direction corresponding to the second structure of each of the plurality of finger structures in the second region. Among the plurality of insulating member rows in the first finger structure, an insulating member row disposed at a position closest to the second finger structure includes a first insulating member disposed at a first position in the second direction at the position in the stacking direction corresponding to the first structure of the first finger structure and a second insulating member disposed at the first position in the second direction at the position in the stacking direction corresponding to the second structure of the first finger structure. Among the plurality of insulating member rows in the second finger structure, an insulating member row disposed at a position closest to the first finger structure includes a third insulating member disposed at the first position in the second direction at the position in the stacking direction corresponding to the first structure of the second finger structure and a fourth insulating member disposed at the first position in the second direction at the position in the stacking direction corresponding to the second structure of the second finger structure. A distance in the first direction between the first insulating member and the third insulating member is smaller than a distance in the first direction between the second insulating member and the fourth insulating member.

Next, the semiconductor memory devices according to embodiments are described in detail with reference to the drawings. The following embodiments are only examples, and not described for the purpose of limiting the present invention. The following drawings are schematic, and for convenience of description, a part of a configuration and the like is sometimes omitted. Parts common in a plurality of embodiments are attached by same reference numerals and their descriptions may be omitted.

In this specification, when referring to a “semiconductor memory device”, it may mean a memory die and may mean a memory system including a controller die, such as a memory chip, a memory card, and a Solid State Drive (SSD). Further, it may mean a configuration including a host computer, such as a smartphone, a tablet terminal, and a personal computer.

In this specification, when it is referred that a first configuration “is electrically connected” to a second configuration, the first configuration may be directly connected to the second configuration, and the first configuration may be connected to the second configuration via a wiring, a semiconductor member, a transistor, or the like. For example, when three transistors are connected in series, even when the second transistor is in an OFF state, the first transistor is “electrically connected” to the third transistor.

In this specification, a direction parallel to a surface of the substrate is referred to as an X-direction, a direction parallel to the surface of the substrate and perpendicular to the X-direction is referred to as a Y-direction, and a direction perpendicular to the surface of the substrate is referred to as a Z-direction.

In this specification, a direction intersecting with a surface of the substrate is referred to as a stacking direction in some cases. A direction along a predetermined plane intersecting with the stacking direction may be referred to as a first direction, and a direction along the plane and intersecting with the first direction may be referred to as a second direction. The stacking direction may correspond to the Z-direction and need not correspond to the Z-direction. The first direction and the second direction may and need not each correspond to any of the X-direction or the Y-direction.

Expressions such as “above” and “below” in this specification are based on a bit line and a plurality of conductive layers. For example, a direction from the plurality of conductive layers toward the bit line along the Z-direction is referred to as above and a direction from the bit line toward the plurality of conductive layers along the Z-direction is referred to as below.

### First Embodiment

### [Circuit Configuration]

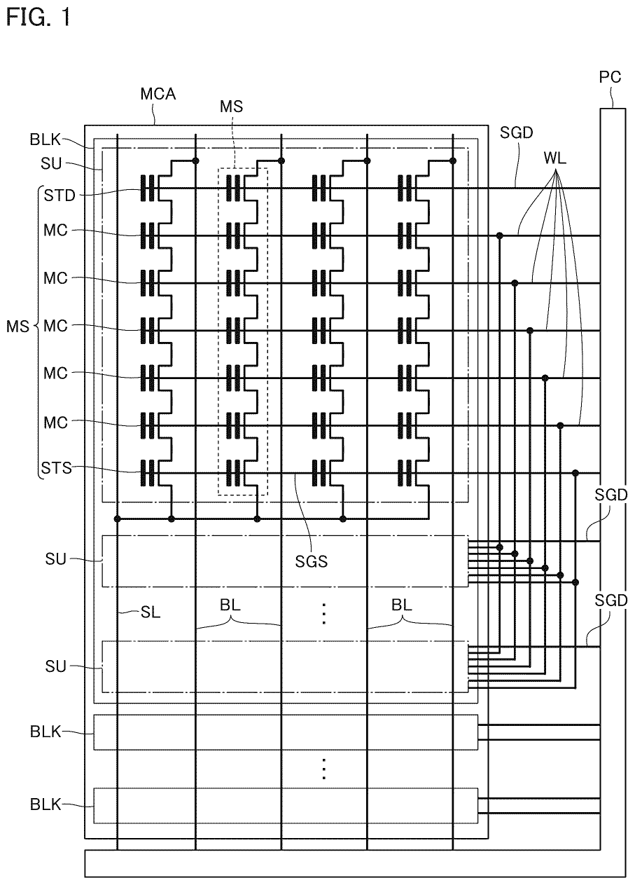

FIG. 1 is a schematic circuit diagram illustrating a configuration of a semiconductor memory device according to a first embodiment. As illustrated in FIG. 1, the semiconductor memory device according to the embodiment includes a memory cell array MCA and a peripheral circuit PC.

The memory cell array MCA includes a plurality of memory blocks BLK. Each of these plurality of memory blocks BLK includes a plurality of string units SU. Each of these plurality of string units SU includes a plurality of memory strings MS. Each of these plurality of memory strings MS has one end connected to the peripheral circuit PC via a bit line BL. Each of these plurality of memory strings MS has the other end connected to the peripheral circuit PC via a common source line SL.

The memory string MS includes a drain-side select transistor STD, a plurality of memory cells MC (memory transistors), and a source-side select transistor STS. The drain-side select transistor STD, the plurality of memory cells MC, and the source-side select transistor STS are connected in series between the bit line BL and the source line SL. Hereinafter, the drain-side select transistor STD and the source-side select transistor STS may be simply referred to as select transistors (STD, STS).

The memory cell MC is a field-effect type transistor. The memory cell MC includes a part of a semiconductor column, a gate insulating film, and a gate electrode. The part of the semiconductor column functions as a channel region. The gate insulating film includes an electric charge accumulating film. The memory cell MC has a threshold voltage that changes according to an electric charge amount in the electric charge accumulating film. The memory cell MC stores the data of one bit or a plurality of bits. Respective word lines WL are connected to the gate electrodes of the plurality of memory cells MC corresponding to one memory string MS. Each of these word lines WL is connected to all of the memory strings MS in one memory block BLK in common.

The select transistors (STD, STS) are a field-effect type transistor. The select transistors (STD, STS) include a part of a semiconductor column, a gate insulating film, and a gate electrode. The part of the semiconductor column functions as a channel region. The select gate lines (SGD, SGS) are connected to the gate electrodes of the select transistors (STD, STS), respectively. One drain-side select gate line SGD is connected to all of the memory strings MS in one string unit SU in common. One source-side select gate line SGS is connected to all of the memory strings MS in one memory block BLK in common.

The peripheral circuit PC includes, for example, a voltage generation circuit that generates an operating voltage, a voltage transfer circuit that transfers the generated operating voltage to selected bit line BL, word line WL, source line SL, select gate lines (SGD, SGS), and the like, a sense amplifier module connected to the bit lines BL, and a sequencer that controls them.

### [Structure]

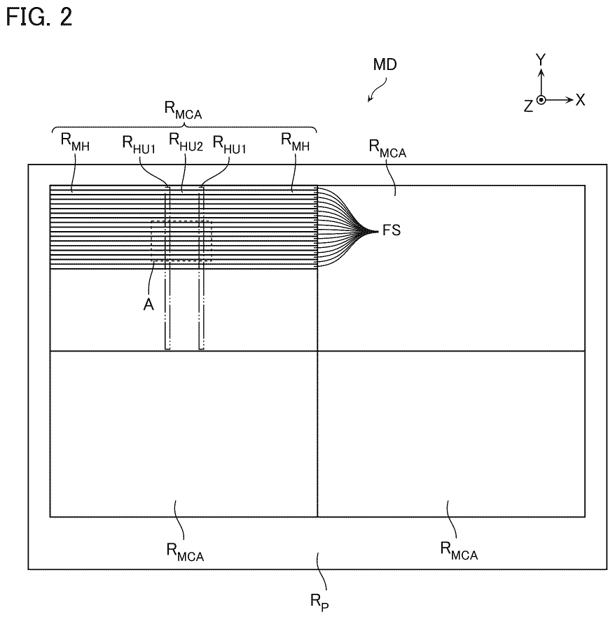

Next, with reference to FIG. 2 to FIG. 13, the structure of the semiconductor memory device according to the first embodiment is described.

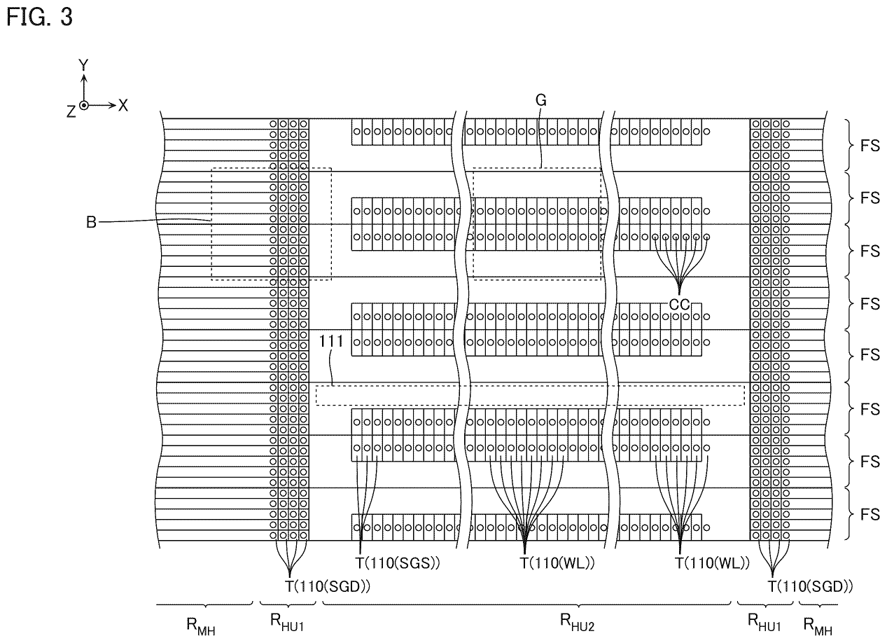

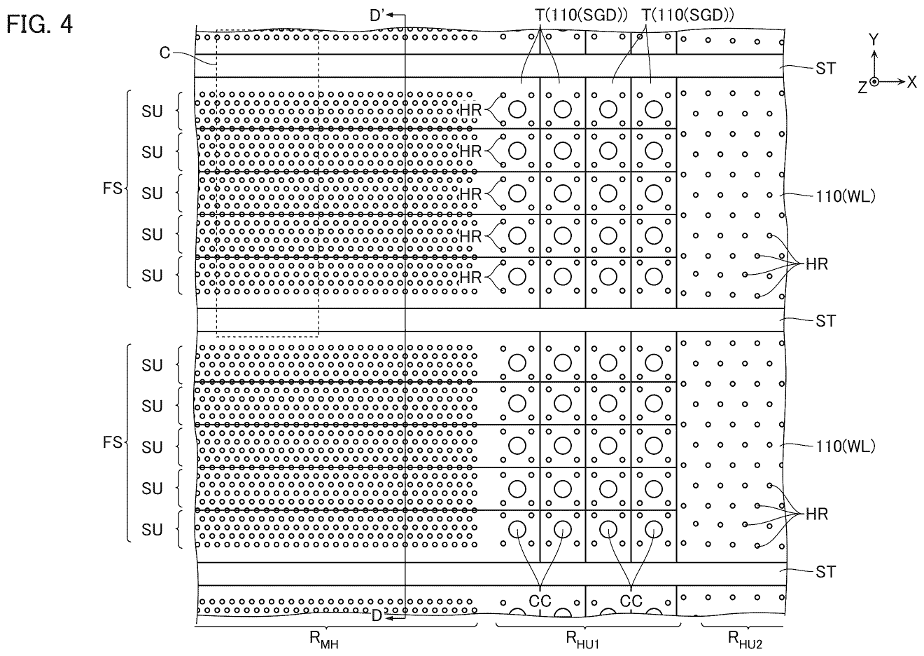

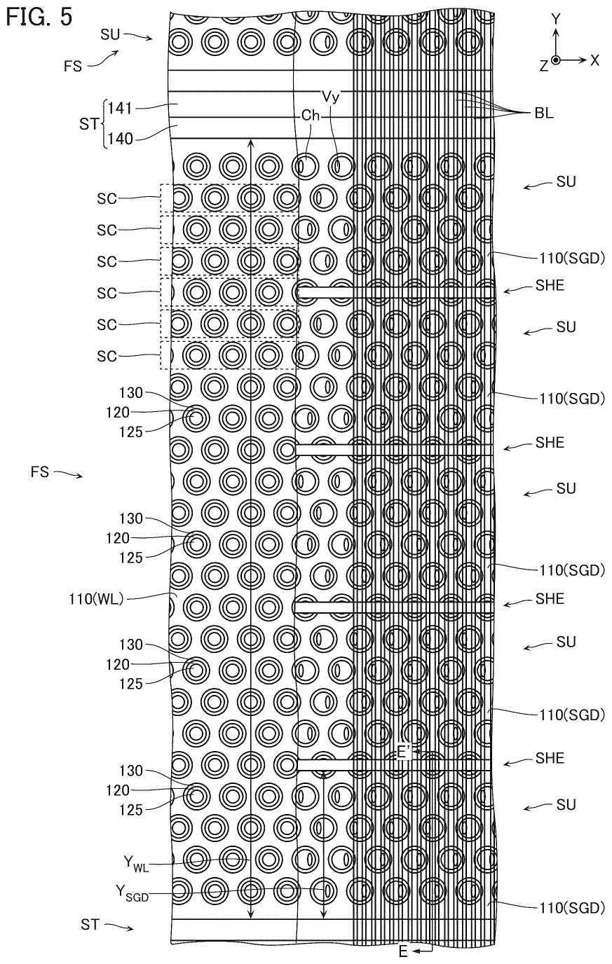

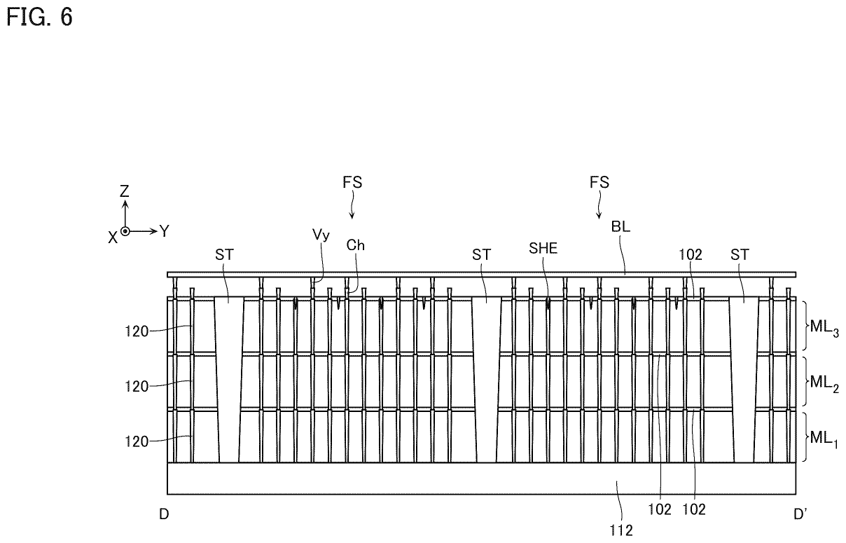

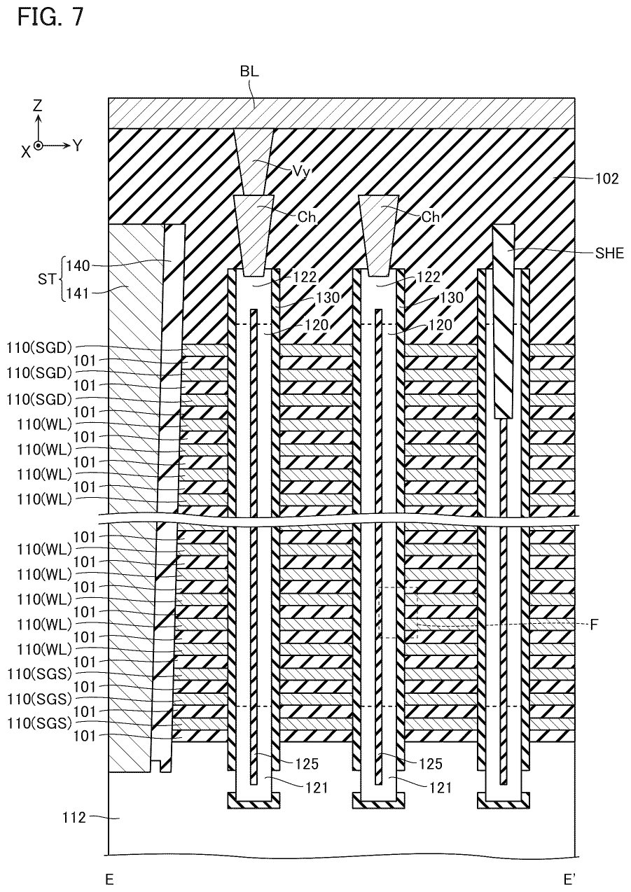

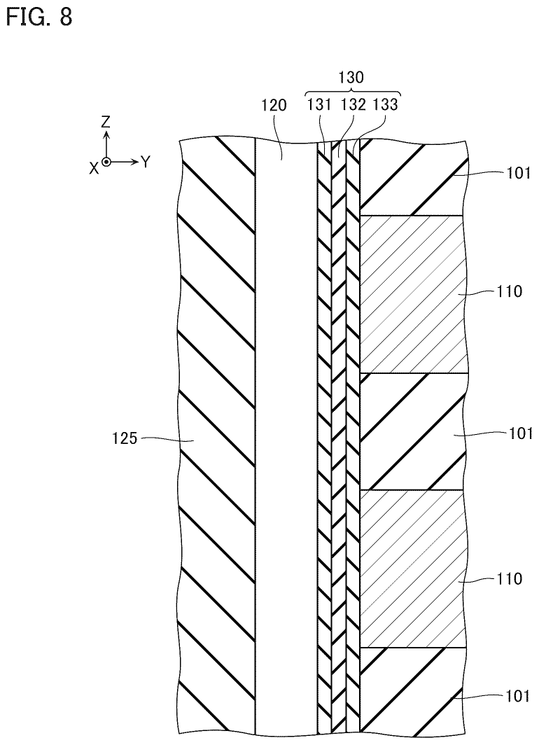

FIG. 2 is a schematic plan view illustrating a part of the configuration of the semiconductor memory device. FIG. 3 is a schematic plan view illustrating a part of the configuration of the semiconductor memory device, and an enlarged view of the partially omitted part A of FIG. 2. FIG. 4 is a schematic plan view illustrating a part of the configuration of the semiconductor memory device, and an enlarged view of the part B of FIG. 3. FIG. 5 is a schematic plan view illustrating a part of the configuration of the semiconductor memory device, and an enlarged view of the part C of FIG. 4. A part of FIG. 5 illustrates an XY cross-sectional surface at a height position corresponding to a conductive layer 110 (WL) described later. A part of FIG. 5 illustrates a plane in which the bit lines BL and insulating layers 102 described later are omitted. A part of FIG. 5 illustrates the bit lines BL. FIG. 6 is a schematic cross-sectional view illustrating a part of the configuration of the semiconductor memory device, and illustrates a cross-sectional surface of the structure illustrated in FIG. 4 taken along the line D-D′ and viewed in the arrow direction. FIG. 7 is a schematic cross-sectional view illustrating a part of the configuration of the semiconductor memory device, and illustrates a cross-sectional surface of the structure illustrated in FIG. 5 taken along the line E-E′ and viewed in the arrow direction. FIG. 8 is a schematic cross-sectional view illustrating a part of the configuration of the semiconductor memory device, and an enlarged view of the part F of FIG. 7. Note that while FIG. 8 illustrates an YZ cross-sectional surface, also when cross-sectional surfaces other than the YZ cross-sectional surface (for example, an XZ cross-sectional surface) along a central axis of a semiconductor column 120 is observed, a structure similar to that in FIG. 8 is observed.

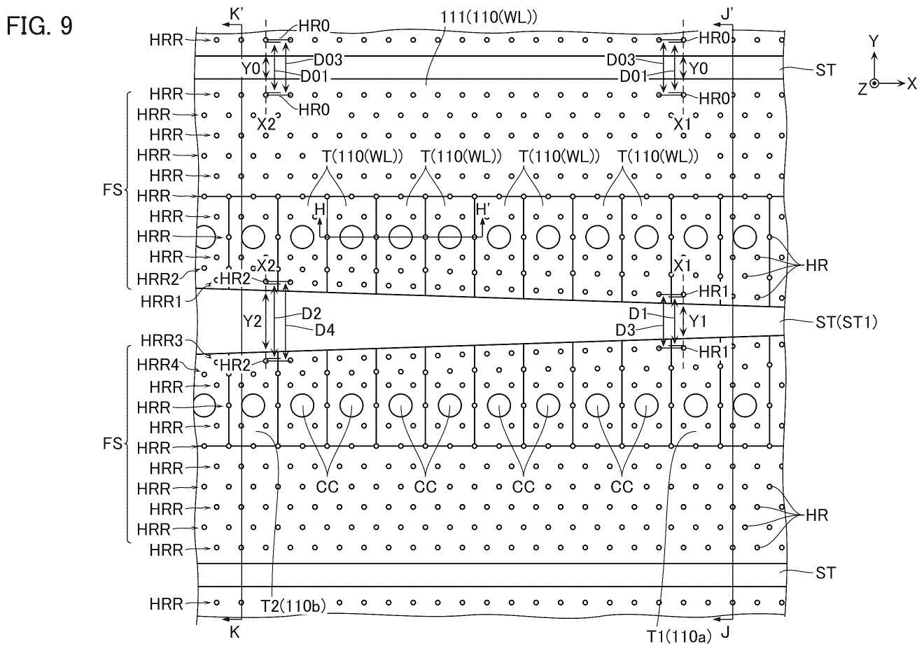

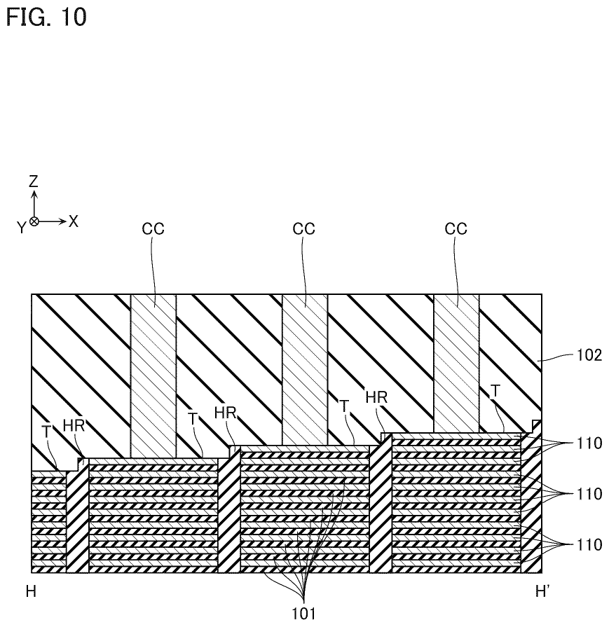

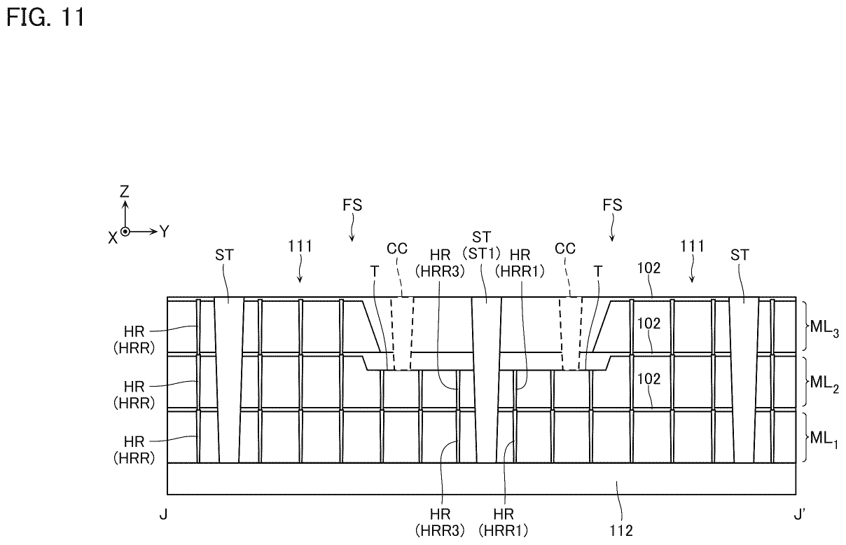

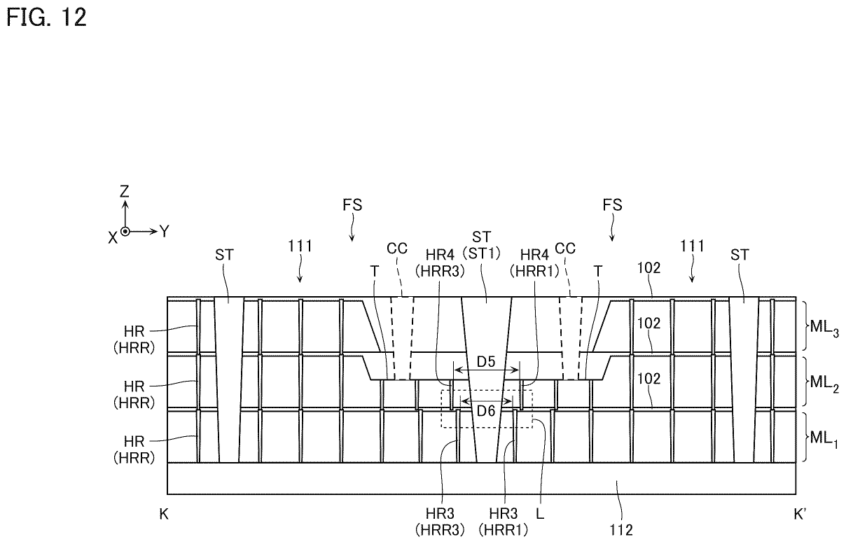

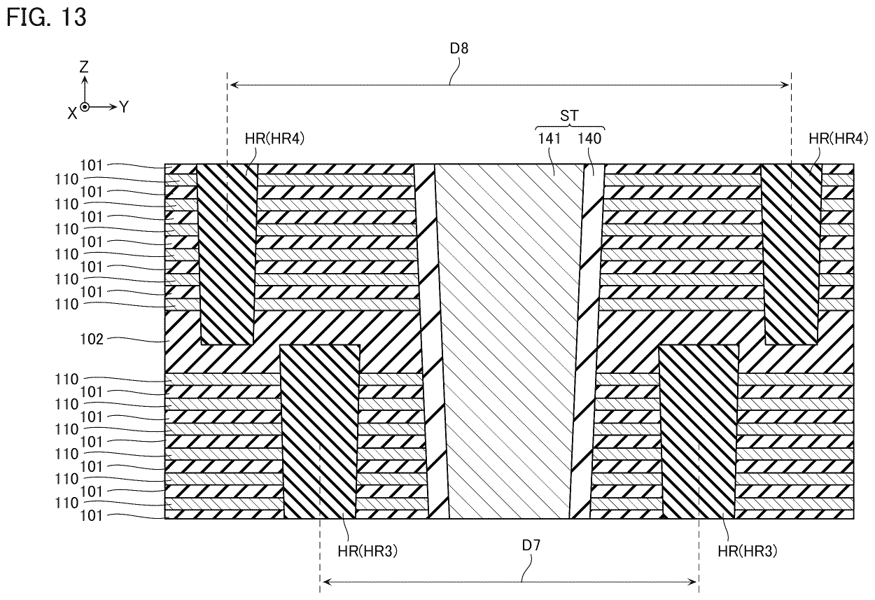

FIG. 9 is a schematic plan view illustrating a part of the configuration of the semiconductor memory device, and an enlarged view of the part G of FIG. 3. FIG. 10 is a schematic cross-sectional view illustrating a part of the configuration of the semiconductor memory device, and illustrates a cross-sectional surface of the structure illustrated in FIG. 9 taken along the line H-H′ and viewed in the arrow direction. FIG. 11 is a schematic cross-sectional view illustrating a part of the configuration of the semiconductor memory device, and illustrates a cross-sectional surface of the structure illustrated in FIG. 9 taken along the line J-J′ and viewed in the arrow direction. FIG. 12 is a schematic cross-sectional view illustrating a part of the configuration of the semiconductor memory device, and illustrates a cross-sectional surface of the structure illustrated in FIG. 9 taken along the line K-K′ and viewed in the arrow direction. FIG. 13 is a schematic cross-sectional view illustrating a part of the configuration of the semiconductor memory device, and an enlarged view of the part L of FIG. 12.

FIG. 2 to FIG. 13 are schematic drawings, and a part of the configurations is omitted in some cases.

As illustrated in FIG. 2, the semiconductor memory device according to the embodiment includes a memory die MD. In the example of the drawing, the memory die MD includes four memory cell array regions R_{MCA} arranged in the X-direction and the Y-direction. The memory cell array region R_{MCA} includes two memory hole regions R_{MH} arranged in the X-direction, two hook-up regions R_{HU1} arranged in the X-direction between these two memory hole regions R_{MH}, and a hook-up region R_{HU2} disposed between these two hook-up regions R_{HU1}. At an end portion in the Y-direction of the memory die MD, a peripheral circuit region R_{P} is disposed.

The memory cell array region R_{MCA} includes a plurality of finger structures FS arranged in the Y-direction. These plurality of finger structure FS extend in the X-direction over the two memory hole regions R_{MH} arranged in the X-direction, the two hook-up regions R_{HU1} disposed between the two memory hole regions R_{MH}, and the hook-up region R_{HU2} disposed between the two hook-up regions R_{HU1}. The finger structure FS includes a plurality of string units SU arranged in the Y-direction, for example, as illustrated in FIG. 4. An inter-finger structure ST is disposed between two finger structures FS adjacent in the Y-direction. Between two string units SU adjacent in the Y-direction, for example, as illustrated in FIG. 5, an inter-string unit insulating member SHE of silicon oxide (SiO₂) or the like is disposed.

In this embodiment, one finger structure FS functions as one memory block BLK (FIG. 1). Each of the finger structures FS includes five string units SU. However, a plurality of finger structures FS may function as one memory block BLK. The finger structure FS may include two to four string units SU, and may include six or more string units SU.

### [Structure of Memory Hole Region R_{MH}]

For example, as illustrated in FIG. 6, the finger structure FS includes a plurality of (in the example of the drawing, three) structures ML₁, ML₂, ML₃ arranged in the Z-direction. A wiring layer 112 is disposed below these plurality of structures ML₁, ML₂, ML₃. A plurality of bit lines BL are disposed above the plurality of structures ML₁, ML₂, ML₃.

For example, as illustrated in FIG. 7, the plurality of structures ML₁, ML₂, ML₃ include a plurality of conductive layers 110 stacked in the Z-direction, a plurality of semiconductor columns 120 extending in the Z-direction, and gate insulating films 130 disposed between the plurality of conductive layers 110 and the plurality of semiconductor columns 120.

The conductive layer 110 has an approximately plate shape extending in the X-direction. The conductive layer 110 may include, for example, a stacked film of a barrier conductive film of titanium nitride (TiN) or the like and a metal film of tungsten (W) or the like. The conductive layer 110 may contain, for example, polycrystalline silicon containing impurities, such as phosphorus (P) or boron (B). Between the plurality of conductive layers 110 arranged in the Z-direction, insulating layers 101 of silicon oxide (SiO₂) or the like are disposed. At upper surfaces of the uppermost conductive layers 110 of the respective structures ML₁, ML₂, ML₃, insulating layers 102 of silicon oxide (SiO₂) or the like are disposed (see FIG. 6).

Among the plurality of conductive layers 110 included in the structure ML₁, one or a plurality of conductive layers 110 disposed at lowermost layers function as the source-side select gate line SGS and gate electrodes of the plurality of select transistors STS (FIG. 1) connected to the source-side select gate line SGS. In the following description, such conductive layers 110 are referred to as conductive layers 110 (SGS) in some cases.

Among the plurality of conductive layers 110 included in the structure ML₃, one or a plurality of conductive layers 110 disposed at uppermost layers function as the drain-side select gate line SGD and gate electrodes of the plurality of select transistors STD (FIG. 1) connected to the drain-side select gate line SGD. In the following description, such conductive layers 110 are referred to as conductive layers 110 (SGD) in some cases.

The other conductive layers 110 included in the structures ML₁, ML₃ and the plurality of conductive layers 110 included in the structure ML₂ function as the word lines WL and gate electrodes of the plurality of memory cells MC (FIG. 1) connected to the word lines WL. In the following description, such conductive layers 110 are referred to as conductive layers 110 (WL) in some cases.

The plurality of conductive layers 110 (WL) are each electrically independent for each finger structure FS. When two finger structures FS adjacent in the Y-direction are focused on, the plurality of conductive layers 110 (WL) arranged in the Z-direction and the plurality of insulating layers 101 disposed on the upper surfaces and lower surfaces thereof in these two finger structures FS are separated in the Y-direction via the inter-finger structure ST.

The plurality of conductive layers 110 (SGS) are each electrically independent for each finger structure FS. When two finger structures FS adjacent in the Y-direction are focused on, the one or plurality of conductive layers 110 (SGS) and the plurality of insulating layers 101 disposed on the upper surfaces and lower surfaces thereof in these two finger structures FS are separated in the Y-direction via the inter-finger structure ST.

As illustrated in FIG. 5, the conductive layer 110 (SGD) has a width Y_{SGD} in the Y-direction smaller than a width Y_{WL} in the Y-direction of the conductive layer 110 (WL).

The plurality of conductive layers 110 (SGD) are each electrically independent for each string unit SU. When two string units SU adjacent in the Y-direction are focused on in each finger structure FS, the one or plurality of conductive layers 110 (SGD) and the plurality of insulating layers 101 disposed on the upper surfaces and lower surfaces thereof in these two string units SU are separated in the Y-direction via the inter-string unit insulating member SHE. In the two finger structures FS adjacent in the Y-direction, when one closest to one finger structure FS among a plurality of string units SU included in the other finger structure FS and one closest to the other finger structure FS among a plurality of string units SU included in the one finger structure FS are focused on, the one or plurality of conductive layers 110 (SGD) and the plurality of insulating layers 101 disposed on the upper surfaces and lower surfaces thereof in these two string units SU are separated in the Y-direction via the inter-finger structure ST.

For example, as illustrated in FIG. 5, the semiconductor columns 120 are arranged in the X-direction and the Y-direction in a predetermined pattern. For example, the finger structure FS includes 24 semiconductor column rows SC disposed from one side in the Y-direction toward the other side in the Y-direction. Each of these 24 semiconductor column rows SC includes the plurality of semiconductor columns 120 arranged in the X-direction.

The semiconductor column 120 contains, for example, polycrystalline silicon (Si). For example, as illustrated in FIG. 7, the semiconductor column 120 has an approximately cylindrical shape, and includes an insulating column 125 of silicon oxide (SiO₂) or the like in the center portion. The semiconductor columns 120 function as channel regions of the memory cells MC and the select transistors (STS, STD).

The semiconductor column 120 included in the structure ML₁ has a lower end portion disposed with an impurity region 121. The semiconductor column 120 included in the structure ML₁ has an upper end portion continuous with a lower end portion of the semiconductor column 120 included in the structure ML₂. The semiconductor column 120 included in the structure ML₂ has an upper end portion continuous with a lower end portion of the semiconductor column 120 included in the structure ML₃. The semiconductor column 120 included in the structure ML₃ has an upper end portion disposed with an impurity region 122.

The impurity region 121 contains N-type impurities, such as phosphorus (P). The impurity region 121 has an approximately cylindrical shape. The impurity region 121 is connected to the wiring layer 112.

The impurity region 122 contains N-type impurities, such as phosphorus (P). The impurity region 122 has an approximately columnar shape. The impurity region 122 is connected to a via-contact electrode Ch. The semiconductor column 120 is electrically connected to the bit lines BL via via-contact electrodes Ch, Vy.

The gate insulating film 130 has an approximately cylindrical shape that covers an outer peripheral surface of the semiconductor column 120. For example, as illustrated in FIG. 8, the gate insulating film 130 includes a tunnel insulating film 131, an electric charge accumulating film 132, and a block insulating film 133 stacked between the semiconductor column 120 and the conductive layers 110. The tunnel insulating film 131 and the block insulating film 133 contain, for example, silicon oxide (SiO₂). The electric charge accumulating film 132 includes a film of silicon nitride (SiN) or the like that allows accumulation of electric charge. The tunnel insulating film 131, the electric charge accumulating film 132, and the block insulating film 133 have approximately cylindrical shapes, and for example, as illustrated in FIG. 7, extend in the Z-direction along an outer peripheral surface of the semiconductor column 120 excluding a contact portion of the semiconductor column 120 with the wiring layer 112.

FIG. 8 illustrates an example of the gate insulating film 130 including the electric charge accumulating film 132 of silicon nitride or the like. However, the electric charge accumulating film included in the gate insulating film 130 may be, for example, a floating gate of polycrystalline silicon containing N-type or P-type impurities or the like.

The wiring layer 112 (FIG. 7) may contain, for example, polycrystalline silicon containing N-type impurities, such as phosphorus (P). At a lower surface of the wiring layer 112, a conductive member of a metal, such as tungsten (W), tungsten silicide, or the like, or another conductive member may be disposed. The wiring layer 112 functions as a part of the source line SL (FIG. 1).

For example, as illustrated in FIG. 5 and FIG. 7, the inter-string unit insulating member SHE extends in the X-direction and the Z-direction. The inter-string unit insulating member SHE contains, for example, silicon oxide (SiO₂). The inter-string unit insulating member SHE has a lower end positioned above a lower surface the conductive layer 110 (WL) positioned at the uppermost layer. The inter-string unit insulating member SHE has a lower end positioned below a lower surface of the conductive layer 110 (SGD) positioned at the lowermost layer. A position in the Z-direction of an upper end of the inter-string unit insulating member SHE is positioned above the upper surface of the conductive layer 110 (SGD) positioned at the uppermost layer.

For example, as illustrated in FIG. 5 and FIG. 7, the inter-finger structure ST extends in the X-direction and the Z-direction. The inter-finger structure ST widens in the Y-direction from the lower side toward the upper side. The inter-finger structure ST includes an inter-finger insulating member 140 extending in the X-direction and the Z-direction, and an inter-finger electrode 141 disposed inside the inter-finger insulating member 140. The inter-finger insulating member 140 contains silicon oxide (SiO₂) or the like. The inter-finger electrode 141 is separated from the plurality of conductive layers 110 arranged in the Z-direction, the plurality of insulating layers 101 disposed between the plurality of conductive layers 110, and the insulating layer 102 in the Y-direction via the inter-finger insulating member 140. Lower ends of the inter-finger insulating member 140 and the inter-finger electrode 141 are connected to the wiring layer 112. The inter-finger electrode 141 may be a conductive member including, for example, a stacked film of a barrier conductive film of titanium nitride (TiN) or the like and a metal film of tungsten (W) or the like. The inter-finger electrode 141 may be, for example, a semiconductor member of polycrystalline silicon containing impurities, such as phosphorus (P) or boron (B). The inter-finger electrode 141 may contain both the conductive member and the semiconductor member. The inter-finger electrode 141 functions as a part of the source line SL (FIG. 1).

For example, as illustrated in FIG. 5, the via-contact electrodes Ch are arranged in the X-direction and the Y-direction in a predetermined pattern corresponding to the semiconductor columns 120. As illustrated in FIG. 7, the via-contact electrode Ch extends in the Z-direction, has a lower end connected to the impurity region 122 of the semiconductor column 120, and has an upper end connected to the via-contact electrode Vy.

As illustrated in FIG. 5, the bit lines BL extend in the Y-direction, and are arranged in the X-direction. The bit lines BL are arranged in the X-direction at pitches a quarter of pitches in the X-direction of the plurality of semiconductor columns 120 arranged in the X-direction. The bit line BL may include, for example, a stacked film of a barrier conductive film of titanium nitride (TiN) or the like and a metal film of copper (Cu) or the like. The via-contact electrodes Vy described above are disposed at positions at which the bit lines BL overlap with the via-contact electrodes Ch when viewed in the Z-direction.

### [Structure of Hook-Up Region R_{HU1}]

As illustrated in FIG. 4, in the hook-up region R_{HU1}, a plurality of terrace portions T corresponding to the plurality of conductive layers 110 (SGD) are disposed. For example, the terrace portions T are portions of the upper surfaces of the conductive layers 110 not overlapping with other conductive layers 110 when viewed from above. The terrace portions T of the conductive layers 110 (SGD) are disposed at end portions in the X-direction of the conductive layers 110 (SGD). In the example of FIG. 4, four terrace portions T corresponding to the first to the fourth conductive layers 110 (SGD) counting from above are arranged in the X-direction from an X-direction negative side to an X-direction positive side. These plurality of terrace portions T are covered with the above-described insulating layer 102.

In the hook-up region R_{HU1}, a plurality of via-contact electrodes CC are disposed correspondingly to the plurality of terrace portions T. The via-contact electrode CC may include, for example, a stacked film of a barrier conductive film of titanium nitride (TiN) or the like and a metal film of tungsten (W) or the like. As illustrated in FIG. 10, the via-contact electrode CC penetrates the insulating layer 102 and extends in the Z-direction, and has a lower end connected to the terrace portion T of the conductive layer 110.

In the hook-up region R_{HU1}, a plurality of supporting insulating members HR are disposed. The supporting insulating member HR contains, for example, silicon oxide (SiO₂). As illustrated in FIG. 10, the supporting insulating member HR penetrates the plurality of conductive layers 110 and insulating layers 101 and extends in the Z-direction. In this embodiment, a height position of an upper end of the supporting insulating member HR is approximately matched with a height position of the corresponding terrace portion T. Each of outer peripheral surfaces of the supporting insulating members HR are surrounded by a through-hole disposed at the conductive layers 110. In the example of FIG. 4, one supporting insulating member HR is disposed at each of four corners of each terrace portion T.

### [Structure of Hook-Up Region R_{HU2}]

In the hook-up region R_{HU2}, as illustrated in FIG. 3, a plurality of terrace portions T corresponding to the plurality of conductive layers 110 (WL) and the one or plurality of conductive layers 110 (SGS), and a connecting portion 111 connecting the conductive layers 110 between two memory hole regions R_{MH} arranged in the X-direction are disposed. The connecting portion 111 extends from one end to the other end of the hook-up region R_{HU2} in the X-direction. Portions of the plurality of conductive layers 110 (WL) and the one or plurality of conductive layers 110 (SGS) disposed in the memory hole region R_{MH} on one side in the X-direction are continuous with portions disposed in the memory hole region R_{MH} at the other side in the X-direction via the connecting portion 111. These plurality of terrace portions T and the connecting portion 111 are covered with the above-described insulating layer 102. In the hook-up region R_{HU2}, similarly to the hook-up region R_{HU1}, a plurality of via-contact electrodes CC are disposed correspondingly to the plurality of terrace portions T.

In the example of FIG. 3, in the hook-up region R_{HU2}, a plurality of terrace portions T corresponding to the plurality of conductive layers 110 (WL) and the one or plurality of conductive layers 110 (SGS) are disposed. In these plurality of terrace portions T, for example, those disposed on the X-direction positive side correspond to the conductive layers 110 in the upper side, and those disposed on the X-direction negative side correspond to the conductive layers 110 on the lower side. The insulating layer 102 approximately has a length in the Z-direction reduced toward a portion disposed above the terrace portions T disposed on the X-direction positive side and increased toward a portion disposed above the terrace portions T disposed on the X-direction negative side.

In the example of the drawing, in the plurality of conductive layers 110 (WL) and the one or plurality of conductive layers 110 (SGS) included in an even-numbered finger structure FS counting from one side in the Y-direction, the terrace portions T are disposed on a Y-direction negative side with respect to the connecting portion 111. In the plurality of conductive layers 110 (WL) and the one or plurality of conductive layers 110 (SGS) included in an odd-numbered finger structure FS counting from the one side in the Y-direction, the terrace portions T are disposed on a Y-direction positive side with respect to the connecting portion 111.

Here, in the hook-up region R_{HU2}, an inter-finger structure ST1 (FIG. 9) disposed between 2n+2-th and 2n+3-th finger structures FS counting from the one side in the Y-direction has a widened width portion. As illustrated in FIG. 9, in the widened width portion, the inter-finger structure ST1 widens in the Y-direction from the X-direction positive side toward the X-direction negative side.

That is, the inter-finger structure ST1 has a width in the Y-direction basically increased toward the terrace portions T of the conductive layers 110 disposed on the lower side, in other words, increased as the length in the Z-direction of the insulating layer 102 increases. For example, in the example of FIG. 9, a terrace portion T1 of a conductive layer 110a is disposed at a position X1 in the X-direction. A terrace portion T2 of a conductive layer 110b below the conductive layer 110a is disposed at a position X2 in the X-direction at the negative side with respect to the position X1. Here, a width Y1 in the Y-direction of the inter-finger structure ST1 at the position X1 is smaller than a width Y2 in the Y-direction of the inter-finger structure ST1 at the position X2.

In the hook-up region R_{HU2}, the insulating layer 102 has an approximately constant length in the Z-direction of a portion disposed above the connecting portion 111, and the inter-finger structures ST separating the connecting portions 111 other than the inter-finger structure ST1 are not disposed with the widened width portion as described above. Further, in the insulating layer 102, the length in the Z-direction of the portion disposed above the connecting portion 111 is smaller than a length in the Z-direction of the portion disposed above the terrace portions T. Therefore, for example, when the width Y1 in the Y-direction of the inter-finger structure ST1 is compared with a width Y0 in the Y-direction of the other inter-finger structures ST separating the connecting portions 111 at the position X1 in the X-direction, the width Y1 is larger than the width Y0. Similarly, when the width Y2 in the Y-direction of the inter-finger structure ST1 is compared with the width Y0 in the Y-direction of the other inter-finger structures ST separating the connecting portions 111 at the position X2 in the X-direction, the width Y2 is larger than the width Y0.

In the hook-up region R_{HU2}, a plurality of supporting insulating member rows HRR arranged in the Y-direction are disposed. Each of the supporting insulating member rows HRR includes a plurality of supporting insulating members HR different in position in the X-direction. As illustrated in FIG. 11 and FIG. 12, each of the finger structures FS includes the plurality of supporting insulating member rows HRR arranged in the Y-direction at positions in the Z-direction in the structures ML₁, ML₂, ML₃ excluding the positions of the insulating layer 102 disposed above the terrace portions T.

Here, as illustrated in FIG. 9, the supporting insulating member row HRR basically includes a plurality of supporting insulating members HR arranged in a row in the X-direction. That is, positions in the Y-direction of the plurality of supporting insulating members HR included in a supporting insulating member row HRR are basically approximately the same.

However, in the hook-up region R_{HU2}, among a plurality of supporting insulating member rows HRR corresponding to a 2n+2-th finger structure FS counting from the one side in the Y-direction, in a supporting insulating member row HRR1 closest to the inter-finger structure ST1 and a supporting insulating member row HRR2 adjacent to the supporting insulating member row HRR1, a plurality of supporting insulating members HR are arranged so as to be gradually spaced from a center position in the Y-direction of the inter-finger structure ST1 from the positive side toward the negative side in the X-direction.

Similarly, in the hook-up region R_{HU2}, among a plurality of supporting insulating member rows HRR corresponding to a 2n+3-th finger structure FS counting from the one side in the Y-direction, in a supporting insulating member row HRR3 closest to the inter-finger structure ST1 and a supporting insulating member row HRR4 adjacent to the supporting insulating member row HRR3, a plurality of supporting insulating members HR are arranged so as to be gradually spaced from the center position in the Y-direction of the inter-finger structure ST1 from the positive side toward the negative side in the X-direction.

In the supporting insulating member rows HRR1 to HRR4, positions in the Y-direction of the plurality of supporting insulating members HR are spaced from the center position in the Y-direction of the inter-finger structure ST1 toward the terrace portions T of the conductive layers 110 disposed on the lower side, that is, as the length in the Z-direction of the insulating layer 102 increases. For example, in the example of FIG. 9, among a plurality of supporting insulating members HR included in the supporting insulating member rows HRR1, HRR3 adjacent in the Y-direction via the inter-finger structure ST1, a distance D1 in the Y-direction between two supporting insulating members HR1 disposed at the position X1 is smaller than a distance D2 in the Y-direction between two supporting insulating members HR2 disposed at the position X2. A distance D3 between center positions in the Y-direction of the two supporting insulating members HR1 is smaller than a distance D4 between center positions in the Y-direction of the two supporting insulating members HR2.

As described above, the supporting insulating member row HRR basically includes a plurality of supporting insulating members HR arranged in a row in the X-direction. Therefore, in the hook-up region R_{HU2}, among the plurality of supporting insulating members HR included in the two supporting insulating member rows HRR adjacent in the Y-direction via the inter-finger structure ST separating the connecting portions 111 other than the inter-finger structure ST1, a distance D01 in the Y-direction between two supporting insulating members HR0 disposed at the position X1 is smaller than the distance D1. Similarly, a distance D01 in the Y-direction between two supporting insulating members HR0 disposed at the position X2 is smaller than the distance D2. A distance D03 between the center positions in the Y-direction of the two supporting insulating members HR0 disposed at the position X1 is smaller than the distance D3. Similarly, a distance D03 between the center positions in the Y-direction of the two supporting insulating members HR0 disposed at the position X2 is smaller than the distance D4.

FIG. 9 illustrates a configuration at the proximity of the terrace portions T of the conductive layers 110 included in the structure ML₂. However, configurations at the proximity of the terrace portions T of the conductive layers 110 included in the structures ML₁, ML₃ are approximately the same.

However, the inter-finger structure ST1 widens in the Y-direction from an end portion in the X-direction positive side toward an end portion in the X-direction negative side of the hook-up region R_{HU2} in the widened width portion. Therefore, at the proximity of the terrace portions T of the conductive layers 110 included in the structure ML₁, the width in the Y-direction of the inter-finger structure ST1 is larger than the widths Y1, Y2. In contrast, at the proximity of the terrace portions T of the conductive layers 110 included in the structure ML₃, the width in the Y-direction of the inter-finger structure ST1 is smaller than the widths Y1, Y2.

At the proximity of the terrace portions T of the conductive layers 110 included in the structure ML₃, among the plurality of supporting insulating members HR included in two supporting insulating member rows HRR adjacent in the Y-direction via the inter-finger structure ST1, a distance in the Y-direction between two supporting insulating members HR that are disposed at a predetermined position in the X-direction and included in the structure ML: is smaller than the distances D1, D2.

As illustrated in FIG. 11, a plurality of supporting insulating members HR included in the structure ML₂ are basically disposed at positions overlapping with a plurality of supporting insulating members HR included in the structure ML₁ when viewed in the Z-direction. Similarly, a plurality of supporting insulating members HR included in the structure ML₃ are basically disposed at positions overlapping with the plurality of supporting insulating members HR included in the structure ML: when viewed in the Z-direction.

However, as illustrated in FIG. 12, for example, at the position X2 (FIG. 9) or the proximity thereof, in the supporting insulating member rows HRR close to the inter-finger structure ST1 that widens in the Y-direction from the lower side toward the upper side, a plurality of supporting insulating members HR included in the structure ML₂ and a plurality of supporting insulating members HR included in the structure ML₁ are disposed at positions mutually different in the Y-direction so as to be disposed along side surfaces in the Y-direction of the inter-finger structure ST1. That is, a supporting insulating member HR3 in the supporting insulating member row HRR1 included in the structure ML₁ is disposed at a position closer to the center position in the Y-direction of the inter-finger structure ST1 than a supporting insulating member HR4 in the supporting insulating member row HRR1 included in the structure ML₂. Similarly, respective supporting insulating members HR3 in the supporting insulating member rows HRR2 to HRR4 included in the structure ML are disposed at positions closer to the center position in the Y-direction of the inter-finger structure ST1 than supporting insulating members HR4 in the supporting insulating member rows HRR2 to HRR4 included in the structure ML₂.

In the example of FIG. 12, a distance D6 in the Y-direction between two supporting insulating members HR3 adjacent in the Y-direction via the inter-finger structure ST1 in the structure ML is smaller than a distance D5 in the Y-direction between two supporting insulating members HR4 adjacent in the Y-direction via the inter-finger structure ST1 in the structure ML₂. As illustrated in FIG. 13, a distance D7 between center positions in the Y-direction of these two supporting insulating members HR3 is smaller than a distance D8 between center positions in the Y-direction of these two supporting insulating members HR4.

A length corresponding to a difference between the distance D6 and the distance D5 may be increased toward the terrace portions T of the conductive layers 110 disposed on the lower side, that is, as the length in the Z-direction of the insulating layer 102 increases. Similarly, a length corresponding to a difference between the distance D8 and the distance D7 may be increased toward the terrace portions T of the conductive layers 110 disposed on the lower side, that is, as the length in the Z-direction of the insulating layer 102 increases.

In the example of FIG. 13, an upper end of the supporting insulating member HR3 is spaced from a lower end of the supporting insulating member HR4 in the Y-direction. However, the upper end of the supporting insulating member HR3 may be connected to the lower end of the supporting insulating member HR4.

As described above, the plurality of supporting insulating members HR included in the structure ML₂ are basically disposed at the positions overlapping with the plurality of supporting insulating members HR included in the structure ML₁ when viewed in the Z-direction.

For example, all the supporting insulating members HR included in all the supporting insulating member rows HRR other than the supporting insulating member rows HRR1 to HRR4 (FIG. 9) in the structure ML₂ are disposed at the positions overlapping with all the supporting insulating members HR included in all the supporting insulating member rows HRR other than the supporting insulating member rows HRR1 to HRR4 in the structure ML; when viewed in the Z-direction.

FIG. 12 and FIG. 13 illustrate a positional relation between the plurality of supporting insulating members HR included in the structure ML₂ and the plurality of supporting insulating members HR included in the structure ML₁. A positional relation between the plurality of supporting insulating members HR included in the structure ML₂ and the plurality of supporting insulating members HR included in the structure ML₃ may be similar. That is, the plurality of supporting insulating members HR included in the structure ML₃ are basically disposed at positions overlapping with the plurality of supporting insulating members HR included in the structure ML₂ when viewed in the Z-direction. However, for example, in the supporting insulating member rows HRR close to the inter-finger structure ST1, the plurality of supporting insulating members HR included in the structure ML₃ and the plurality of supporting insulating members HR included in the structure ML₂ may be disposed to be close to the inter-finger structure ST1 at positions mutually different in the Y-direction so as to be disposed along the side surfaces in the Y-direction of the inter-finger structure ST1 widening in the Y-direction from the lower side toward the upper side at positions in the X-direction at the proximity of the terrace portions T of the conductive layers 110 included in the structure ML₃.

### [Manufacturing Method]

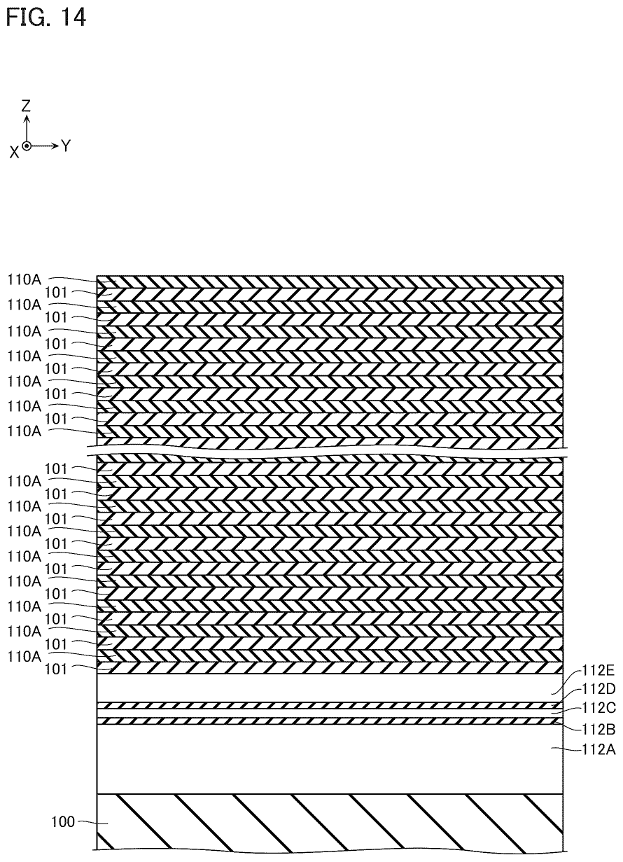

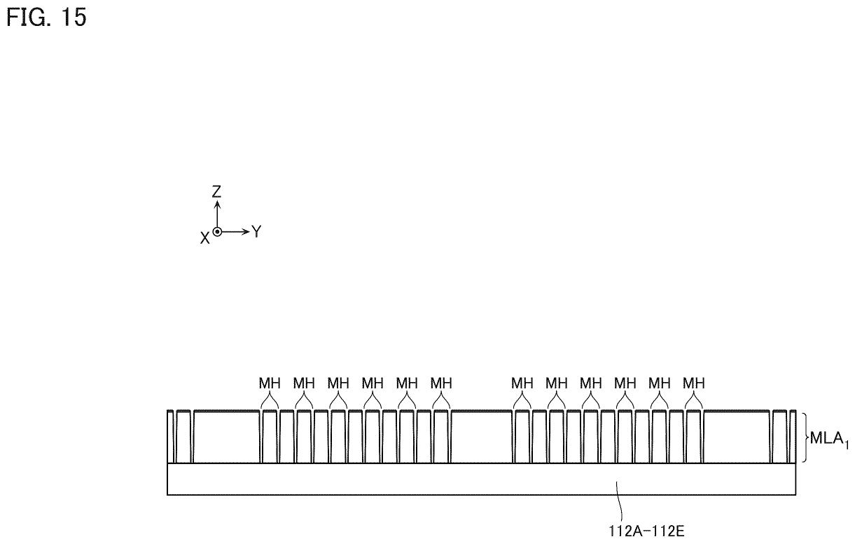

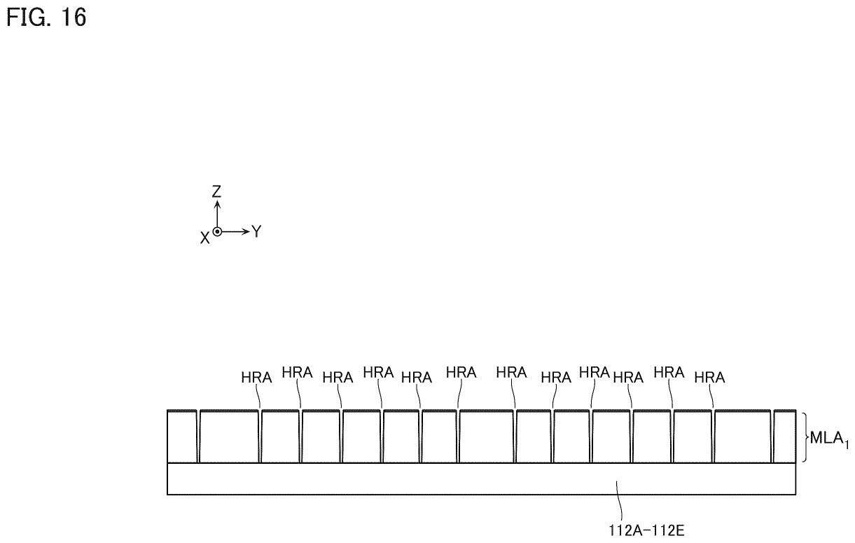

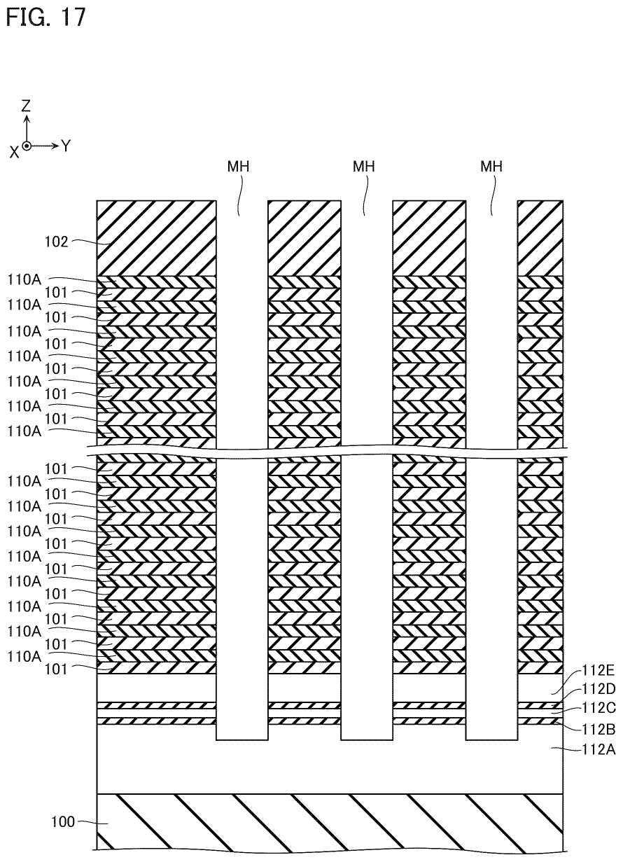

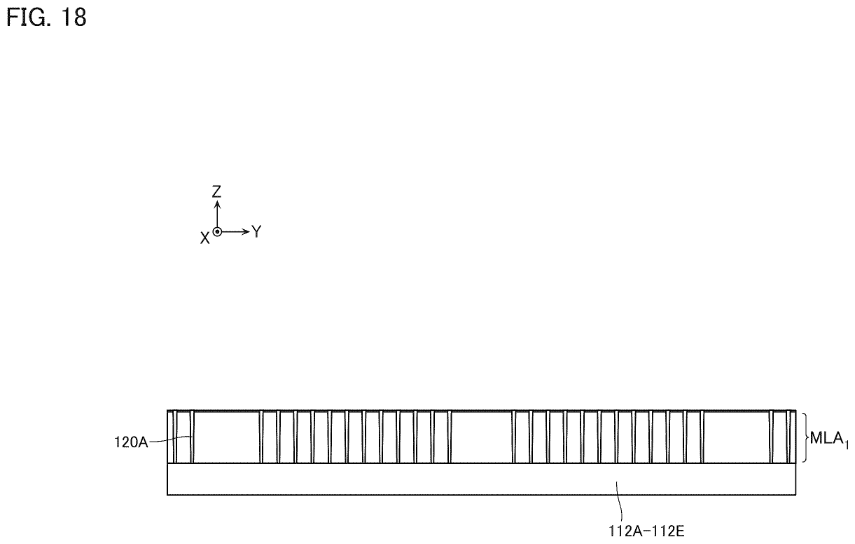

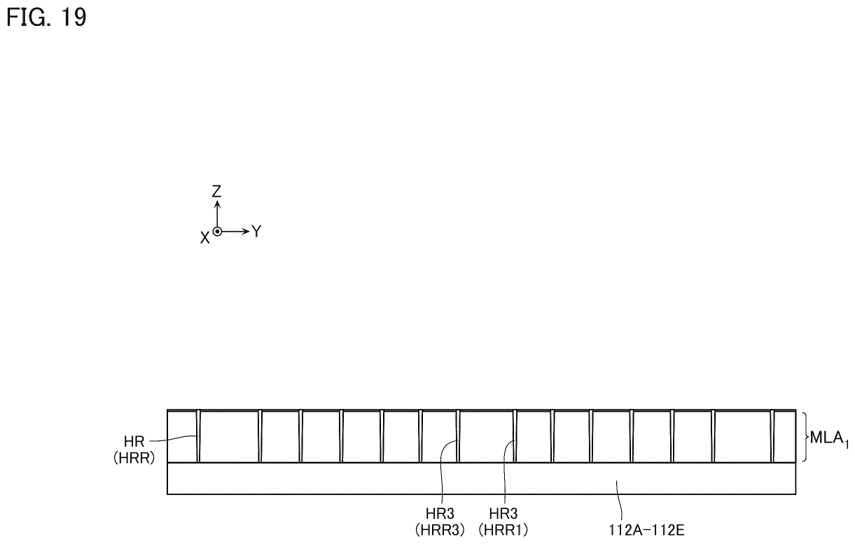

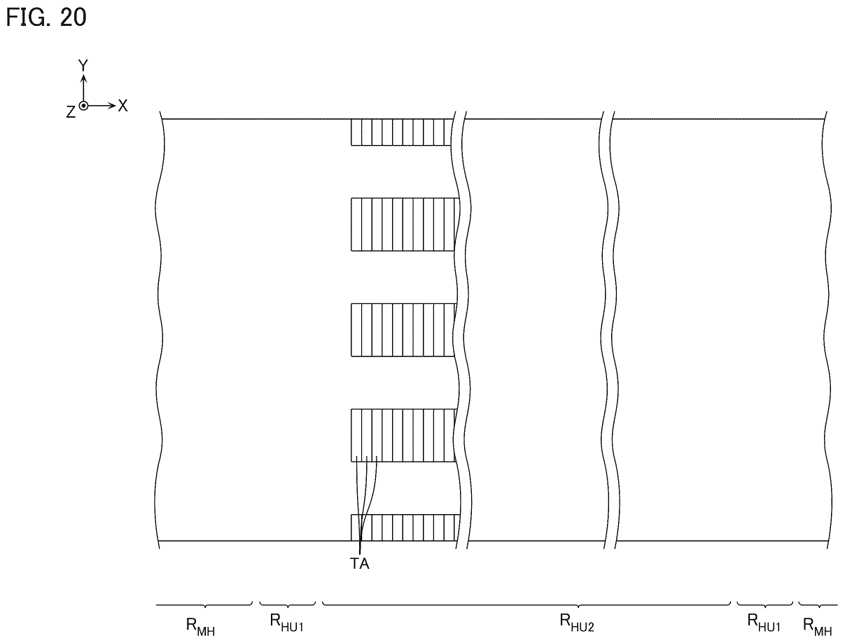

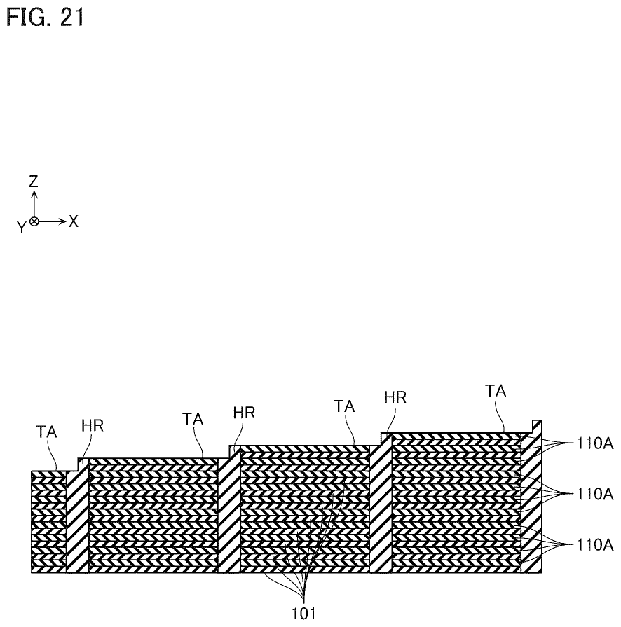

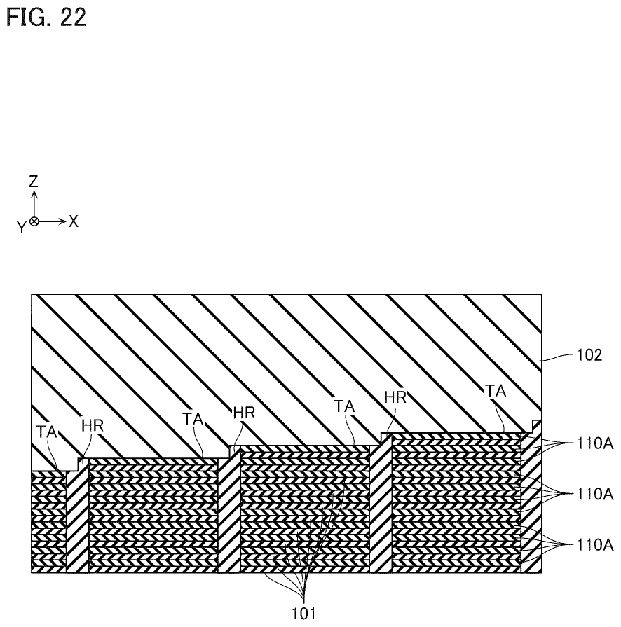

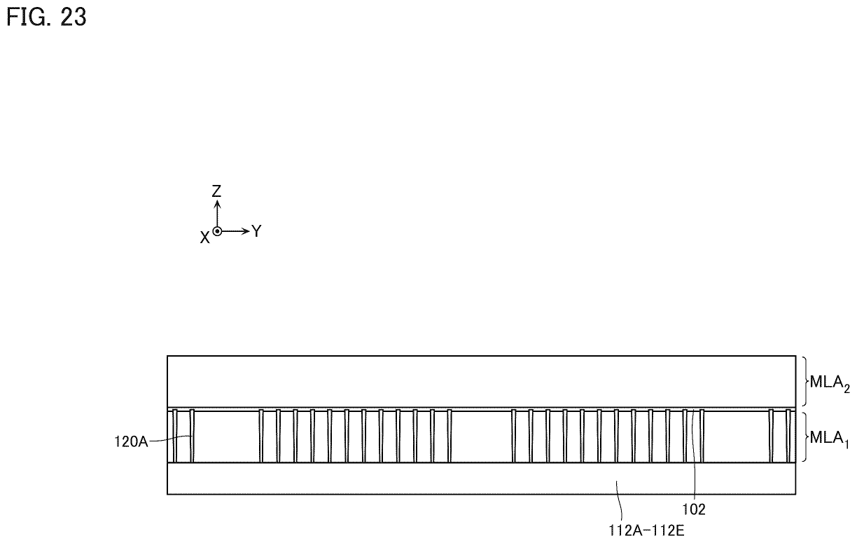

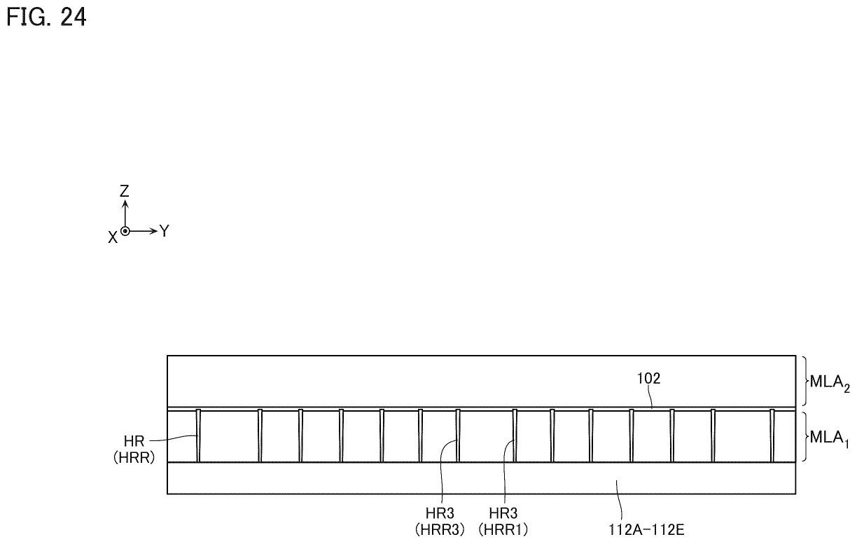

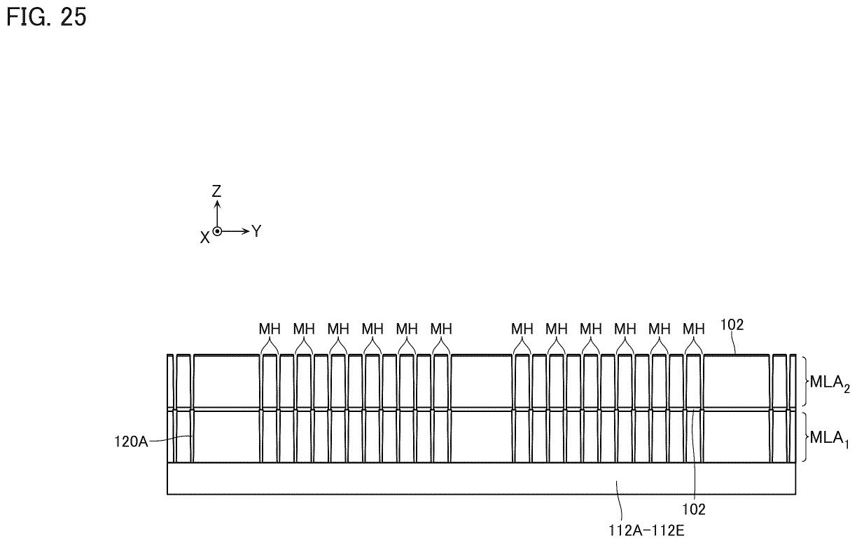

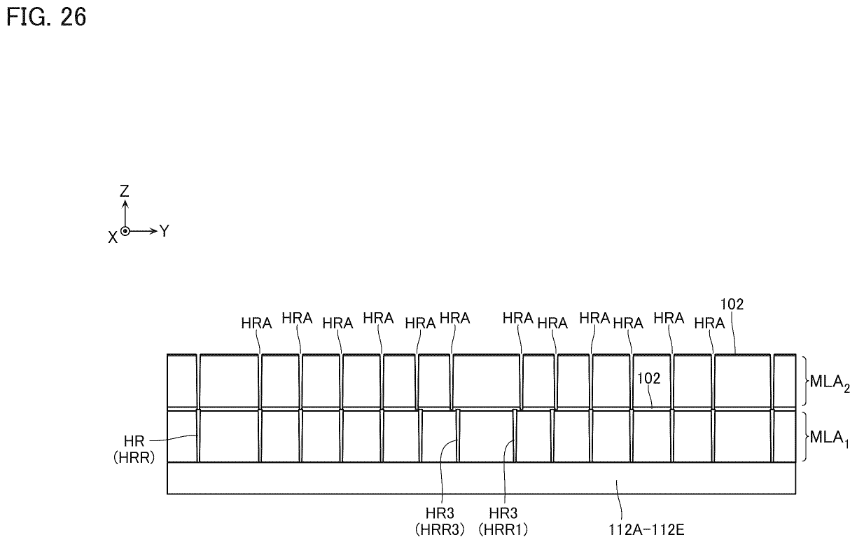

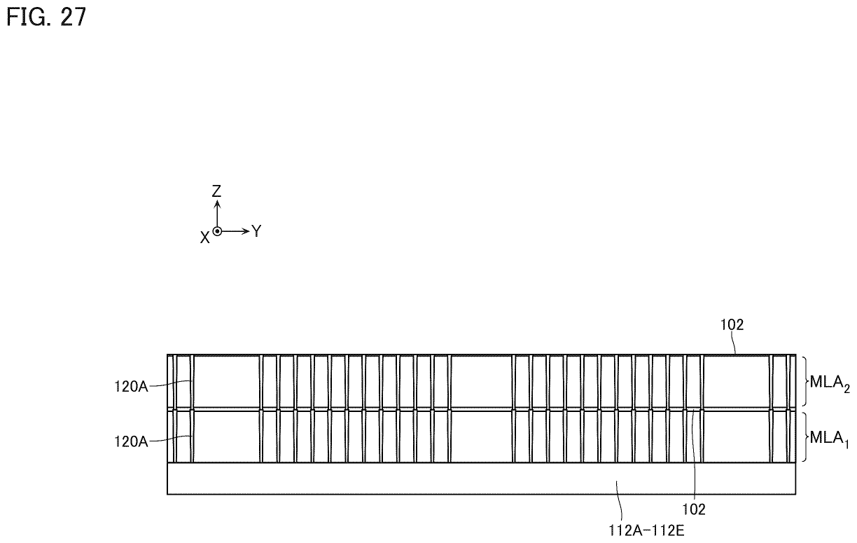

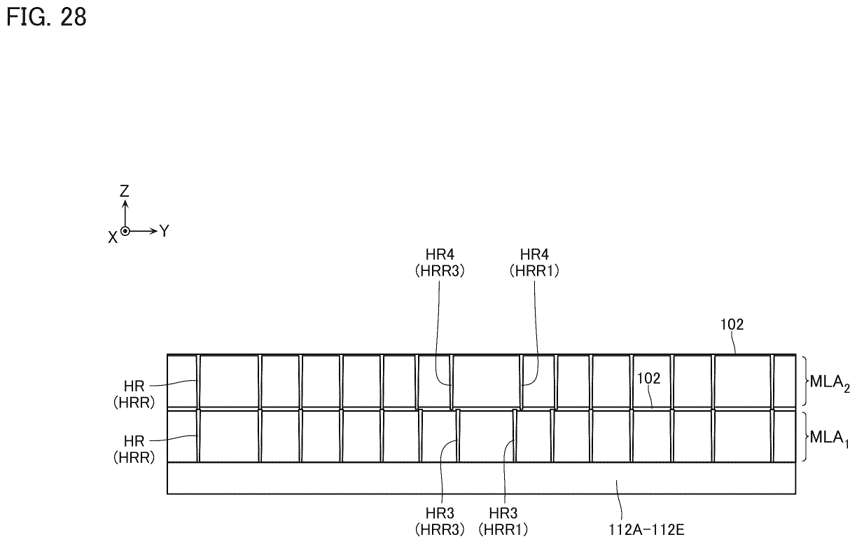

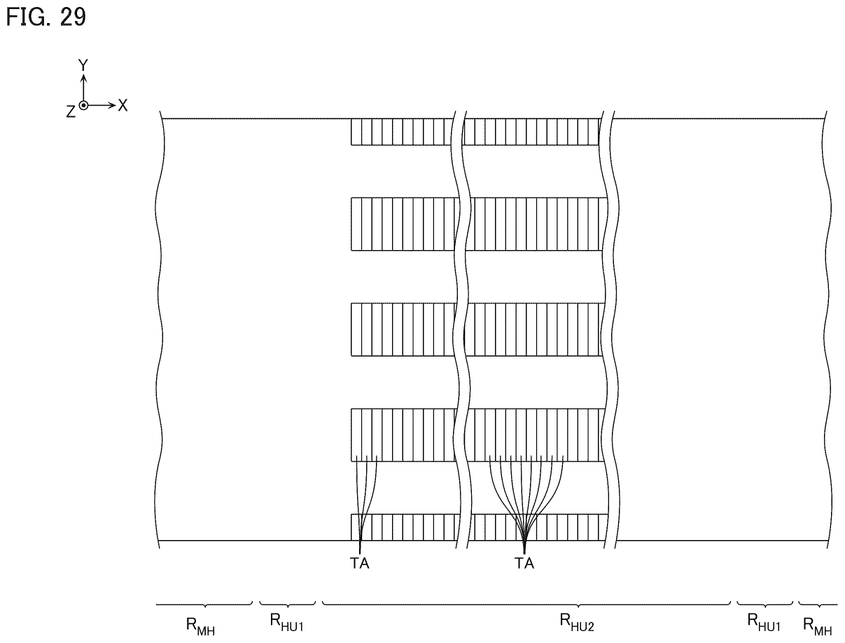

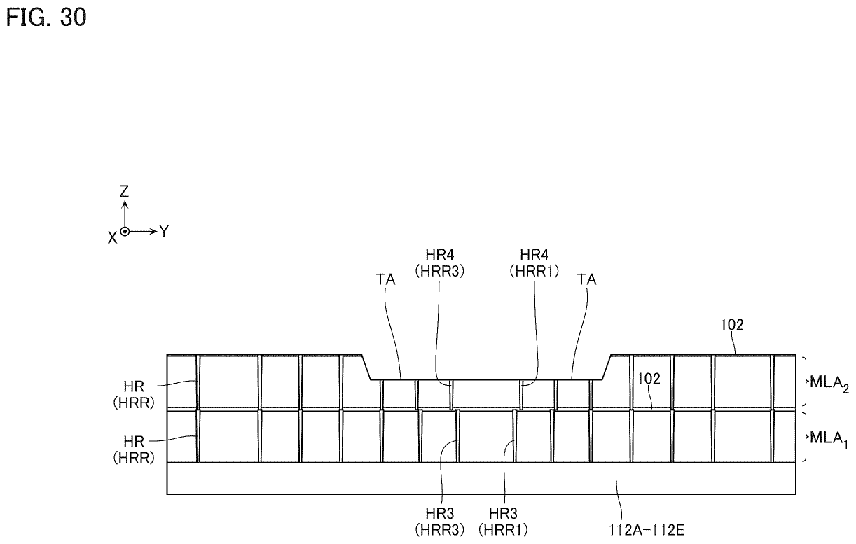

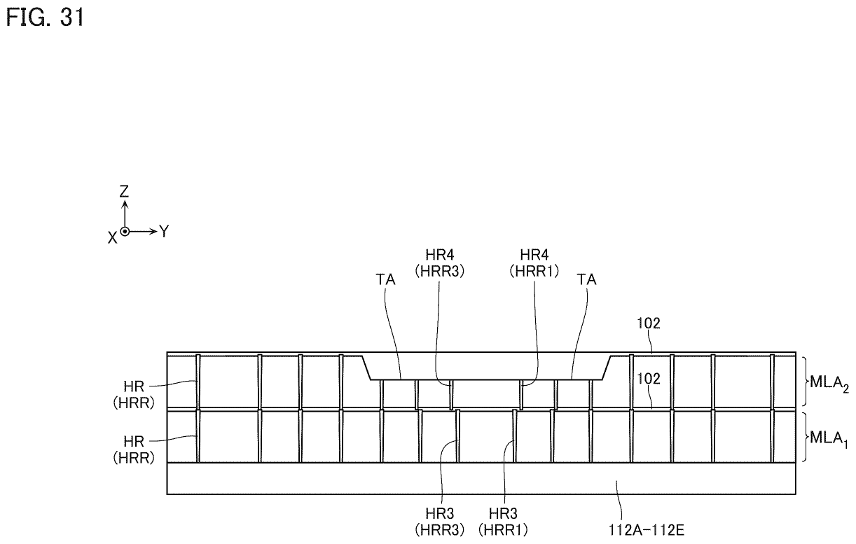

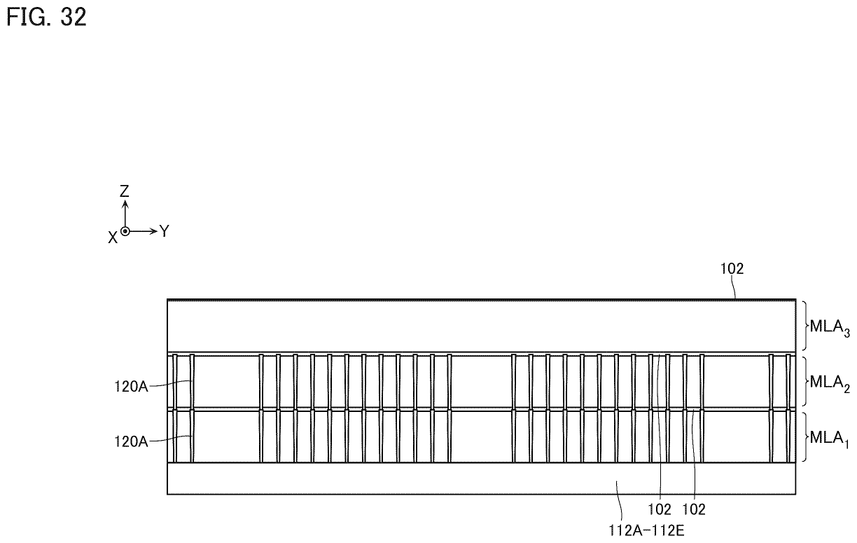

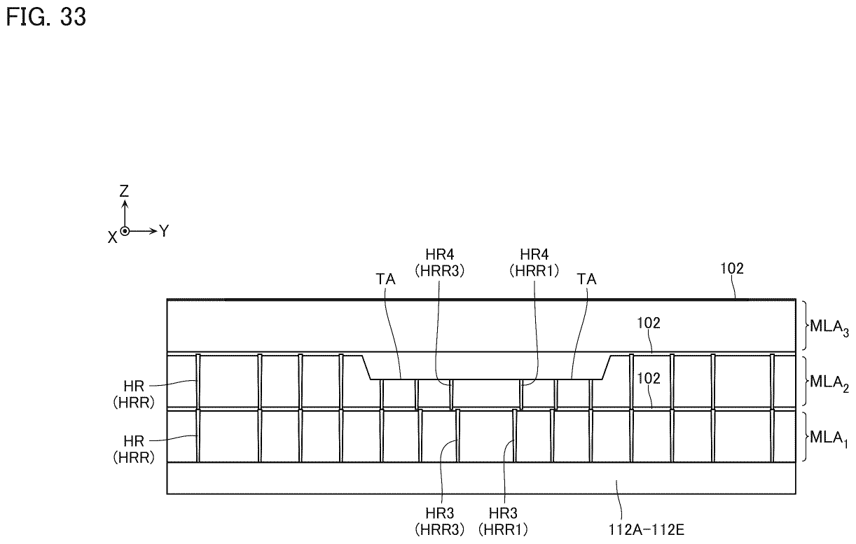

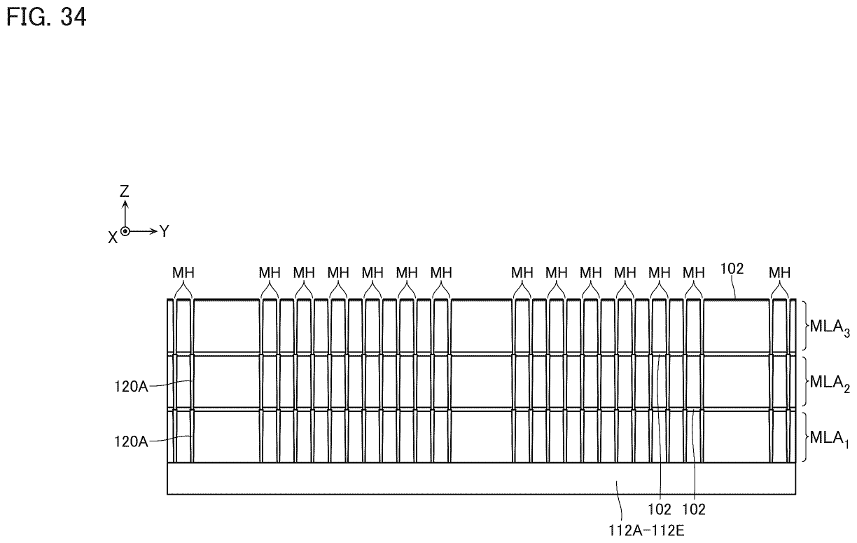

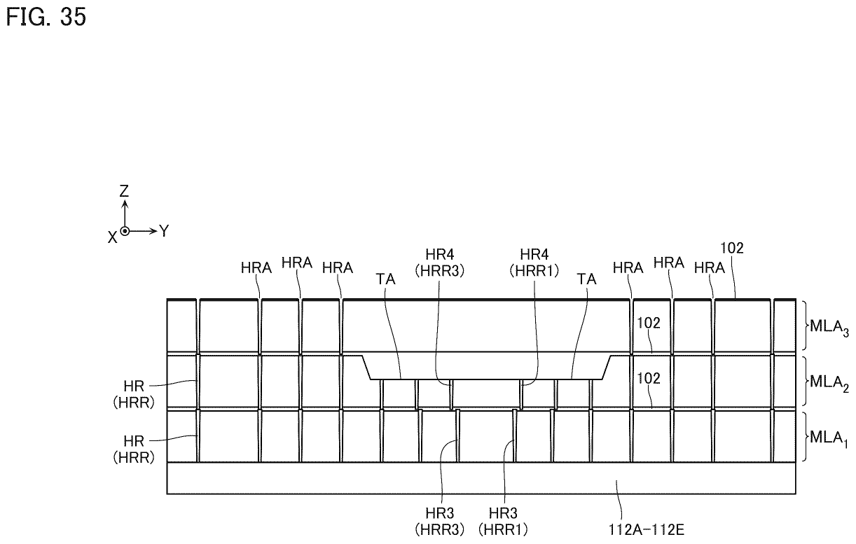

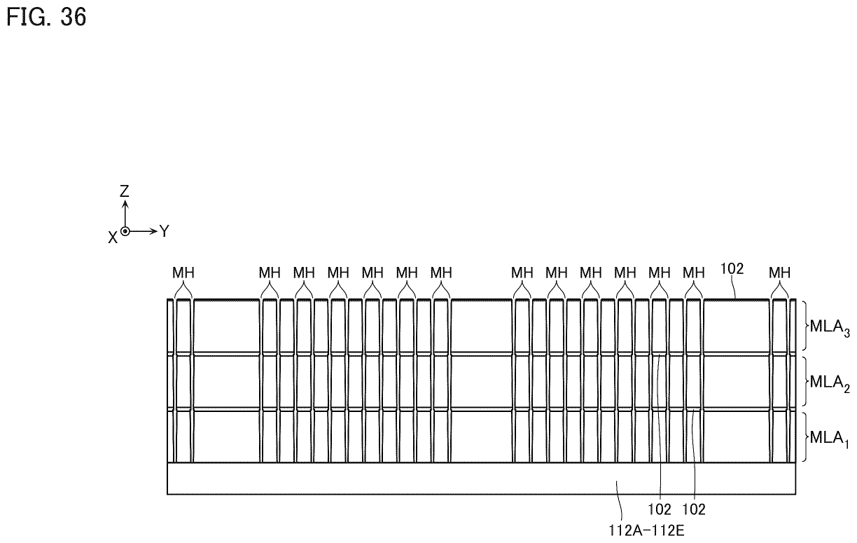

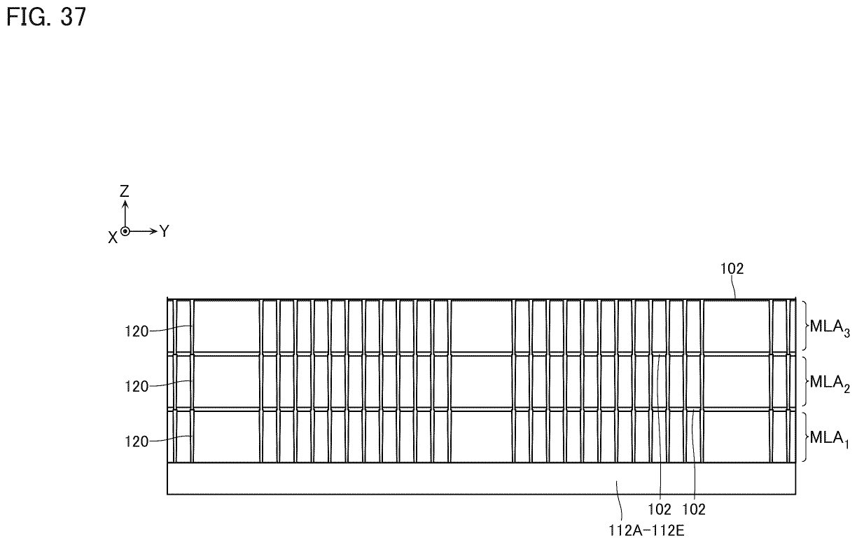

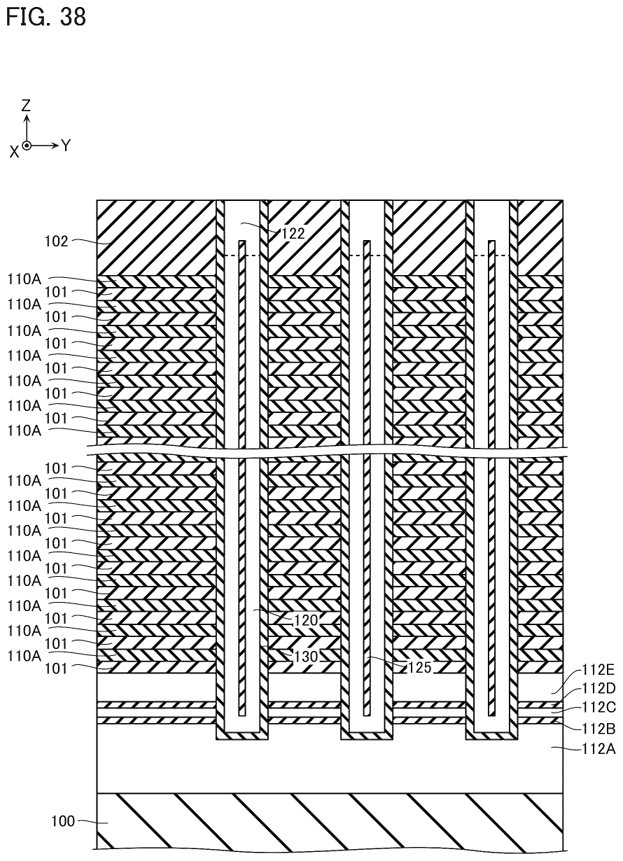

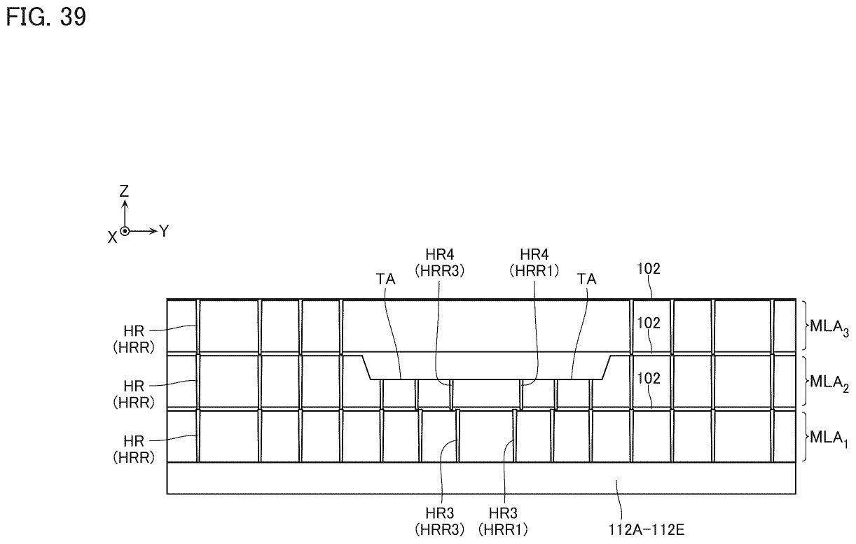

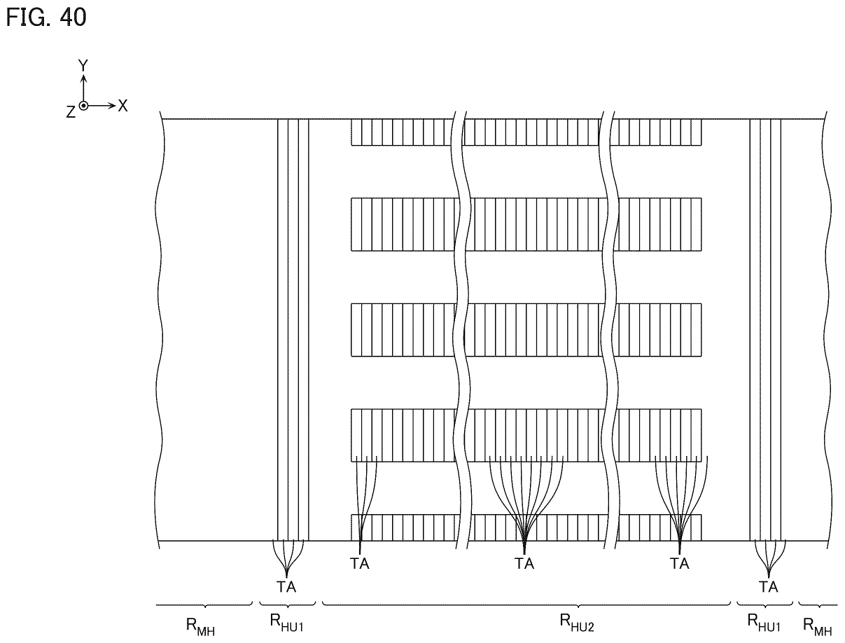

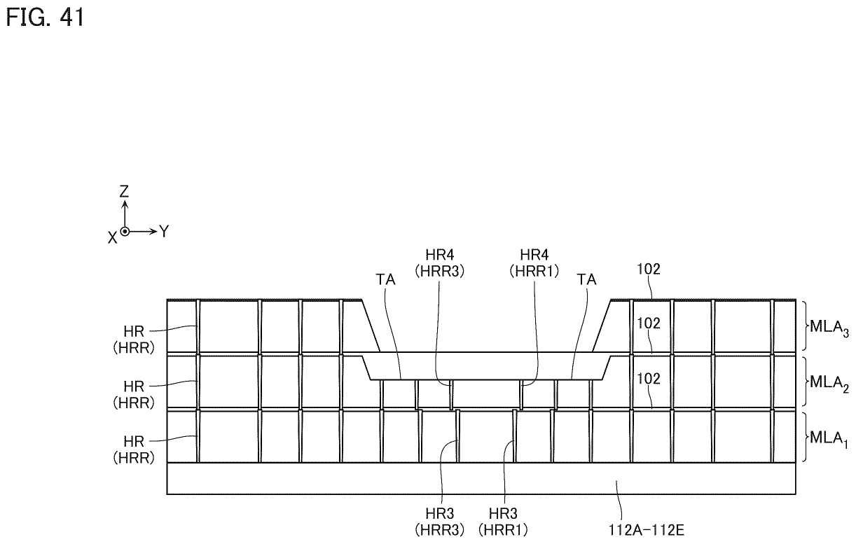

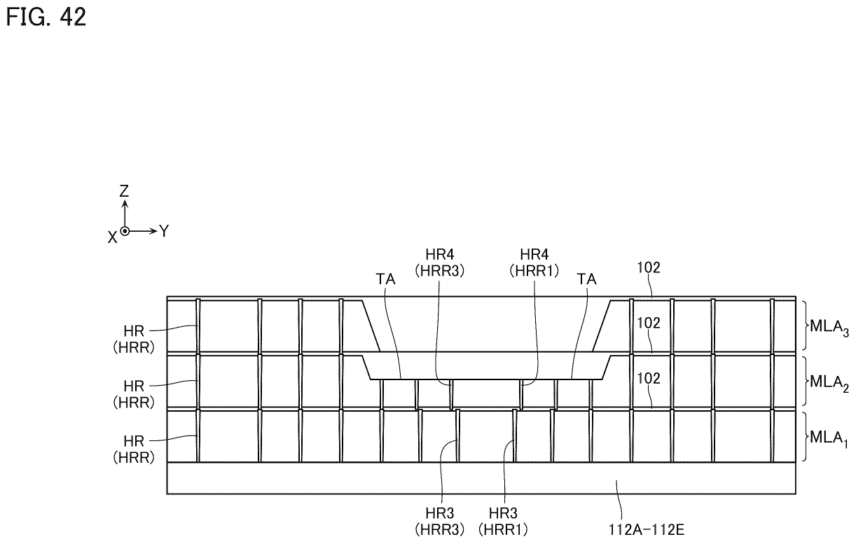

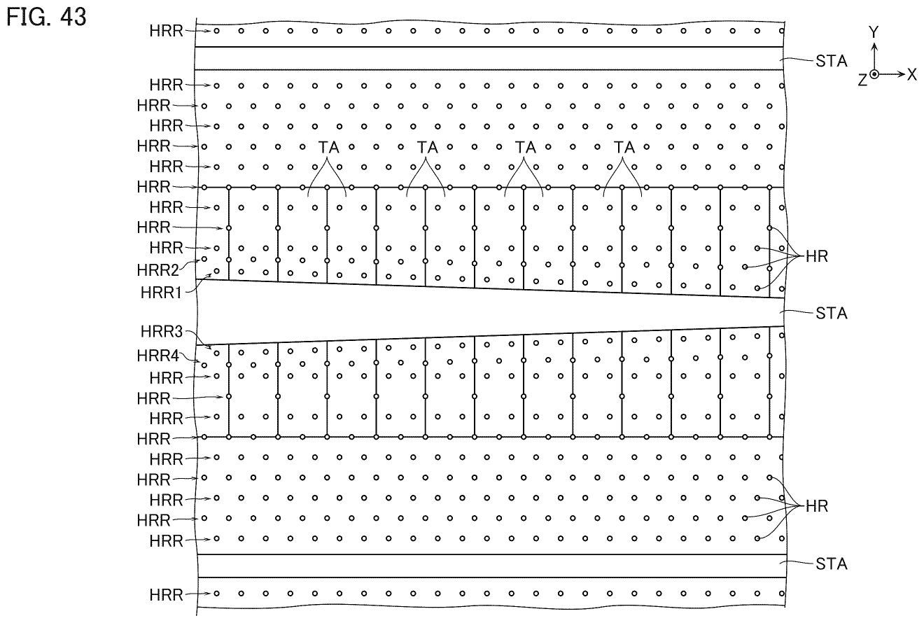

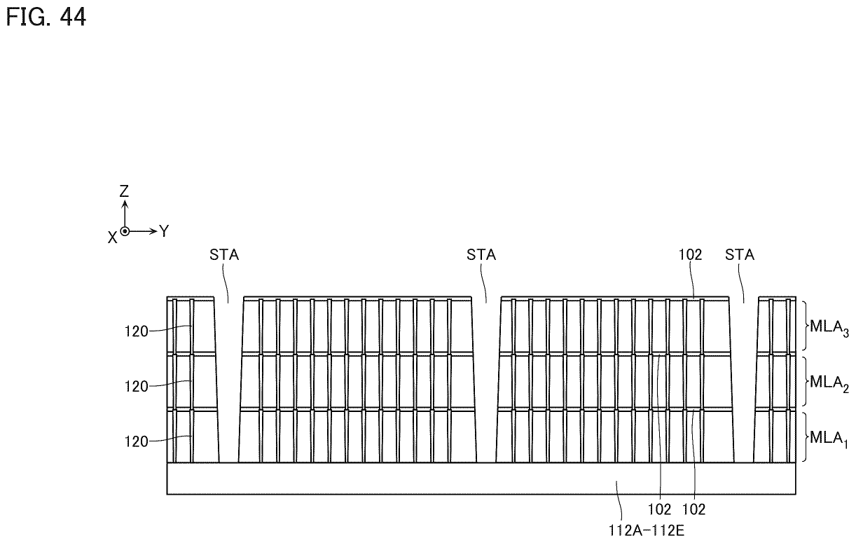

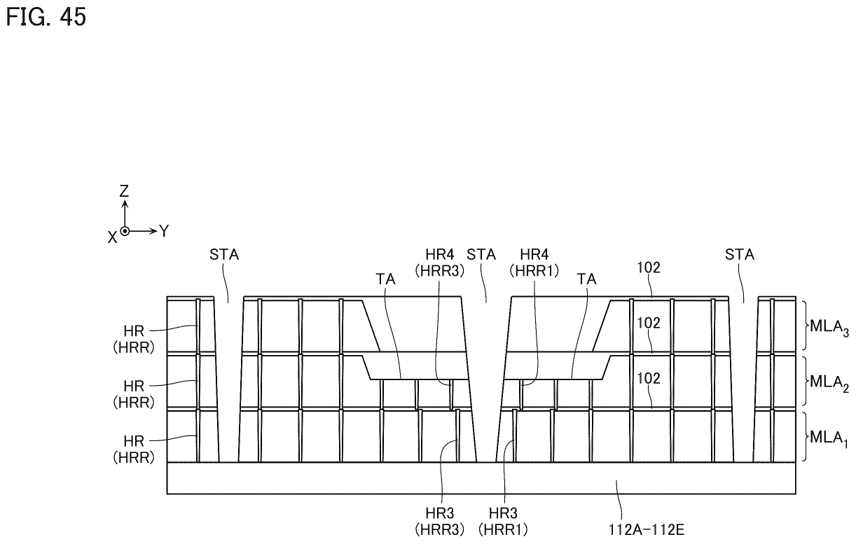

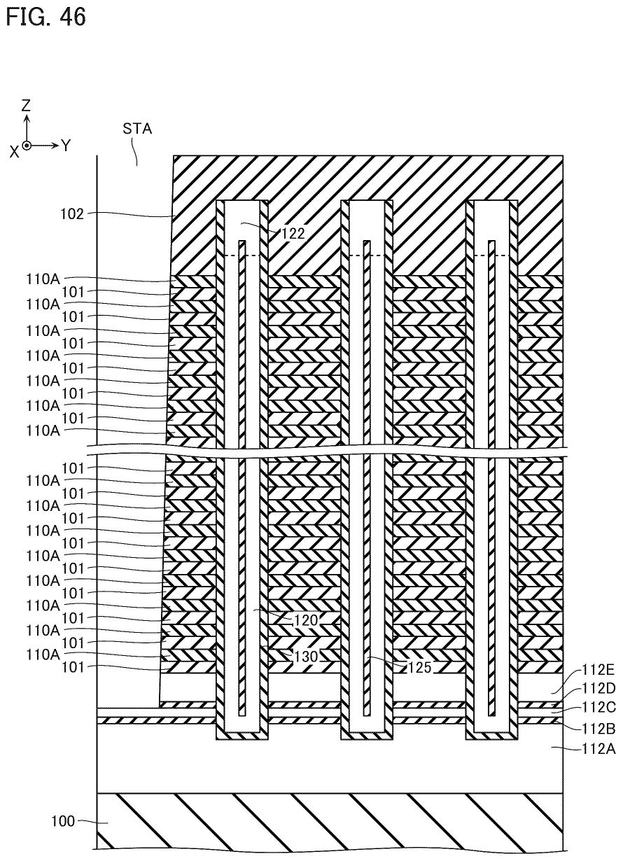

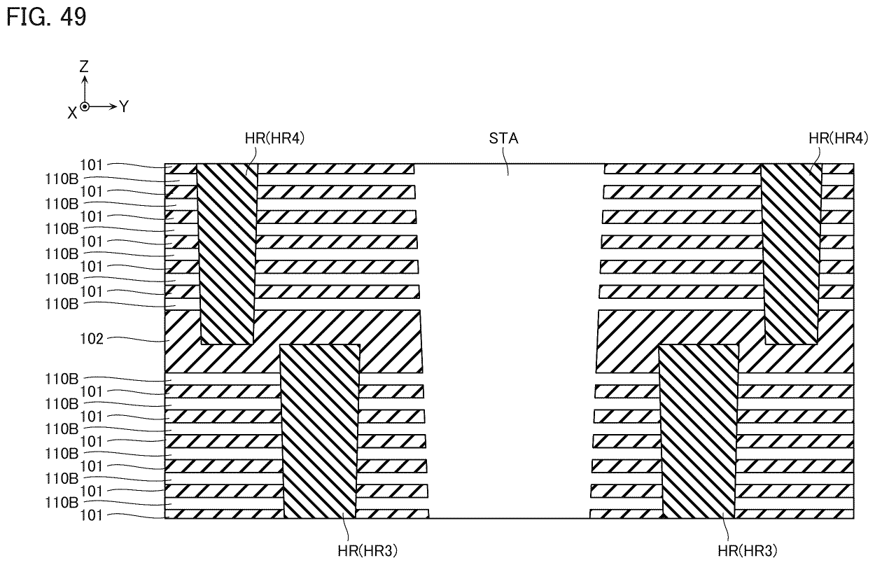

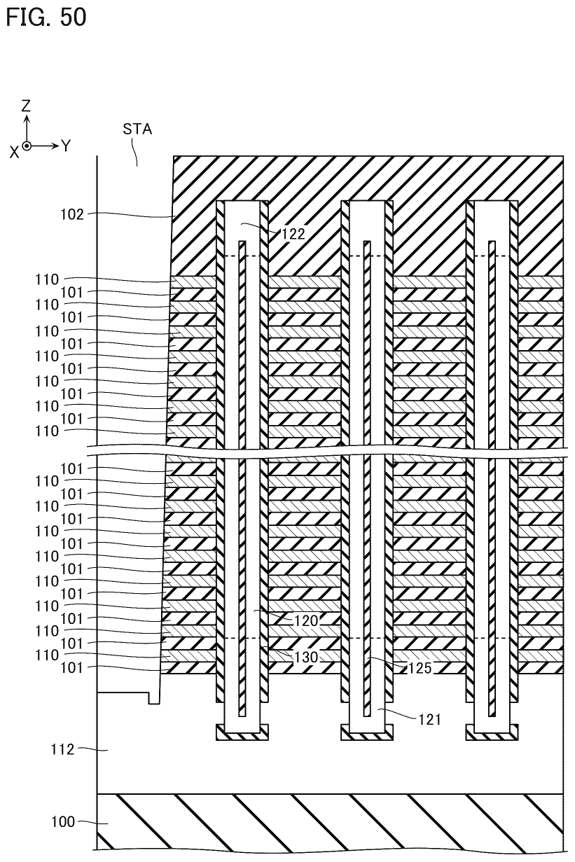

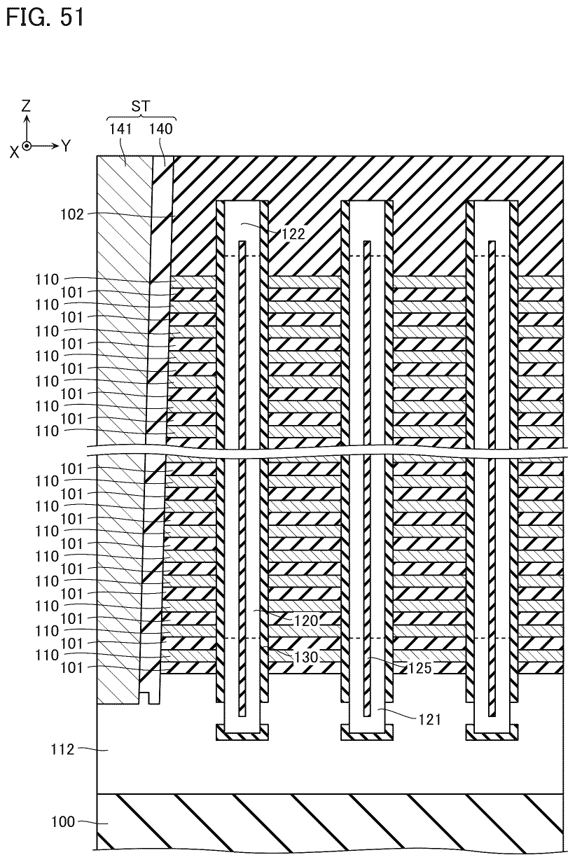

Next, with reference to FIG. 14 to FIG. 51, a method for manufacturing the semiconductor memory device according to the first embodiment is described. FIG. 14, FIG. 17, FIG. 38, FIG. 46 to FIG. 48, FIG. 50, and FIG. 51 are schematic cross-sectional views for describing the manufacturing method, and illustrate cross-sectional surfaces corresponding to FIG. 7. FIG. 15, FIG. 18, FIG. 23, FIG. 25, FIG. 27, FIG. 32, FIG. 34, FIG. 36, FIG. 37, and FIG. 44 are schematic cross-sectional views for describing the manufacturing method, and illustrate cross-sectional surfaces corresponding to FIG. 6. FIG. 16, FIG. 19, FIG. 24, FIG. 26, FIG. 28, FIG. 30, FIG. 31, FIG. 33, FIG. 35, FIG. 39, FIG. 41, FIG. 42, and FIG. 45 are schematic cross-sectional views for describing the manufacturing method, and illustrate cross-sectional surfaces corresponding to FIG. 12. FIG. 20, FIG. 29, and FIG. 40 are schematic plan views for describing the manufacturing method, and illustrate planar surfaces corresponding to FIG. 3. FIG. 21 and FIG. 22 are schematic cross-sectional views for describing the manufacturing method, and illustrate cross-sectional surfaces corresponding to FIG. 10. FIG. 43 is a schematic plan view for describing the manufacturing method, and illustrates a planar surface corresponding to FIG. 9. FIG. 49 is a schematic cross-sectional view for describing the manufacturing method, and illustrates a cross-sectional surface corresponding to FIG. 13.

In the manufacture of the semiconductor memory device according to the embodiment, for example, as illustrated in FIG. 14, a semiconductor layer 112A of silicon or the like, a sacrifice layer 112B of silicon oxide or the like, a sacrifice layer 112C of silicon nitride (SiN) or the like, a sacrifice layer 112D of silicon oxide or the like, and a semiconductor layer 112E of silicon or the like are formed above a wafer (not illustrated in FIG. 14) via an insulating layer 100. A plurality of insulating layers 101 and a plurality of sacrifice layers 110A are alternately formed. The sacrifice layer 110A contains, for example, silicon nitride (SiN). This process is performed by a method, such as Chemical Vapor Deposition (CVD).

In this process, among the plurality of insulating layers 101, those included in the structure ML₁ (FIG. 6) are formed, and among the plurality of sacrifice layers 110A, those corresponding to the conductive layers 110 in the structure ML are formed. Hereinafter, a configuration including them may be referred to as a structure MLA₁.

Next, for example, as illustrated in FIG. 15 to FIG. 17, a plurality of memory holes MH are formed at positions corresponding to the plurality of semiconductor columns 120 described with reference to FIG. 6, FIG. 7, and the like. A plurality of via holes HRA are formed at positions corresponding to the plurality of supporting insulating members HR described with reference to FIG. 12 and the like. These memory holes MH and via holes HRA each extend in the Z-direction, and penetrate the insulating layers 101 and the sacrifice layers 110A, the semiconductor layer 112E, and the sacrifice layers 112D, 112C, 112B to expose an upper surface of the semiconductor layer 112A. This process is performed by a method, such as RIE.

Next, for example, as illustrated in FIG. 18, sacrifice columns 120A of silicon (Si) or the like are formed inside the plurality of memory holes MH. This process is performed by, for example, CVD.

Next, for example, as illustrated in FIG. 19, the supporting insulating members HR are formed inside the plurality of via holes HRA. This process is performed by, for example, CVD.

Next, for example, as illustrated in FIG. 20 and FIG. 21, the plurality of insulating layers 101 and the plurality of sacrifice layers 110A are partially removed in the hook-up region R_{HU2}, thus forming a plurality of terrace portions TA. The terrace portion TA is, for example, a portion of an upper surface of the sacrifice layer 110A not overlapping with other sacrifice layers 110A when viewed from above. In this process, for example, a resist is formed on an upper surface of a structure as illustrated in FIG. 18 and FIG. 19. Removal of the sacrifice layer 110A, removal of the insulating layer 101, and removal of a part of the resist are repeatedly performed. The removal of the resist is performed by isotropic etching, such as wet etching. In this process, a part of the supporting insulating member HR is also removed, and consequently, a height position of an upper end of the supporting insulating member HR is approximately matched with a height position of the corresponding terrace portion TA.

Next, for example, as illustrated in FIG. 22, the insulating layer 102 of silicon oxide (SiO₂) or the like that covers the plurality of terrace portions TA is formed. This process is performed by a method, such as CVD.

Next, for example, as illustrated in FIG. 23 and FIG. 24, a plurality of insulating layers 101 and a plurality of sacrifice layers 110A are alternately formed on an upper surface of the insulating layer 102. In this process, among the plurality of insulating layers 101, those included in the structure ML₂ (FIG. 6) are formed, and among the plurality of sacrifice layers 110A, those corresponding to the conductive layers 110 in the structure ML₂ are formed. Hereinafter, a configuration including them may be referred to as a structure MLA₂.

Next, for example, as illustrated in FIG. 25 and FIG. 26, a plurality of memory holes MH are formed at positions corresponding to the plurality of semiconductor columns 120. A plurality of via holes HRA are formed at positions corresponding to the plurality of supporting insulating members HR. These memory holes MH and via holes HRA each extend in the Z-direction, and penetrate the insulating layers 101 and the sacrifice layers 110A to expose the sacrifice column 120A, an upper surface of the supporting insulating member HR, or an upper surface of the insulating layer 102. This process is performed by a method, such as RIE.

Next, for example, as illustrated in FIG. 27, sacrifice columns 120A of silicon (Si) or the like are formed inside the plurality of memory holes MH. This process is performed by, for example, CVD.

Next, for example, as illustrated in FIG. 28, the supporting insulating members HR are formed inside the plurality of via holes HRA. This process is performed by, for example, CVD.

Next, for example, as illustrated in FIG. 29 and FIG. 30, the plurality of insulating layers 101 and the plurality of sacrifice layers 110A are partially removed in the hook-up region R_{HU2}, thus forming a plurality of terrace portions TA. In this process, a part of the supporting insulating member HR is also removed, and consequently, a height position of an upper end of the supporting insulating member HR is approximately matched with a height position of the corresponding terrace portion TA.

Next, for example, as illustrated in FIG. 31, the insulating layer 102 of silicon oxide (SiO₂) or the like that covers the plurality of terrace portions TA is formed. This process is performed by a method, such as CVD.

Next, for example, as illustrated in FIG. 32 and FIG. 33, a plurality of insulating layers 101 and a plurality of sacrifice layers 110A are alternately formed on an upper surface of the insulating layer 102. In this process, among the plurality of insulating layers 101, those included in the structure ML₃ (FIG. 6) are formed, and among the plurality of sacrifice layers 110A, those corresponding to the conductive layers 110 in the structure ML₃ are formed. Here, a configuration including them is referred to as a structure MLA₃.

Next, for example, as illustrated in FIG. 34 and FIG. 35, a plurality of memory holes MH are formed at positions corresponding to the plurality of semiconductor columns 120. A plurality of via holes HRA are formed at positions corresponding to the plurality of supporting insulating members HR. These memory holes MH and via holes HRA each extend in the Z-direction, and penetrate the insulating layers 101 and the sacrifice layers 110A to expose the sacrifice column 120A, an upper surface of the supporting insulating member HR, or an upper surface of the insulating layer 102. This process is performed by a method, such as RIE.

Next, for example, as illustrated in the FIG. 36, the sacrifice columns 120A in the structures MLA₁, MLA₂ are removed via the plurality of memory holes MH. This process is performed by a method, such as wet etching.

Next, for example, as illustrated in FIG. 37 and FIG. 38, the gate insulating films 130, the semiconductor columns 120, and the insulating columns 125 are formed inside the plurality of memory holes MH. This process is performed by, for example, CVD.

Next, for example, as illustrated in FIG. 39, the supporting insulating members HR are formed inside the plurality of via holes HRA. This process is performed by, for example, CVD.

Next, for example, as illustrated in FIG. 40 and FIG. 41, the plurality of insulating layers 101 and the plurality of sacrifice layers 110A are partially removed in the hook-up regions R_{HU1}, R_{HU2}, thus forming a plurality of terrace portions TA. In this process, a part of the supporting insulating member HR is also removed, and consequently, a height position of an upper end of the supporting insulating member HR is approximately matched with a height position of the corresponding terrace portion TA.

Here, in the process described with reference to FIG. 20 and FIG. 21, the process described with reference to FIG. 29 and FIG. 30, and the process described with reference to FIG. 40 and FIG. 41, as illustrated in FIG. 40, a plurality of terrace portions TA are formed. Among these plurality of terrace portions TA, for example, those disposed on the X-direction positive side correspond to the sacrifice layers 110A on the upper side, and those disposed on the X-direction negative side correspond to the sacrifice layers 110A on the lower side.

Next, for example, as illustrated in FIG. 42, the insulating layer 102 of silicon oxide (SiO₂) or the like that covers the plurality of terrace portions TA is formed. This process is performed by a method, such as CVD.

Next, for example, as illustrated in FIG. 43 to FIG. 46, trenches STA are formed at positions corresponding to the inter-finger structures ST. The trench STA extends in the Z-direction and the X-direction, separates the insulating layer 102, the insulating layers 101 and the sacrifice layers 110A, the semiconductor layer 112E, and the sacrifice layer 112D in the Y-direction, and exposes an upper surface of the sacrifice layer 112C. The trench STA widens in the Y-direction from the lower side toward the upper side. This process is performed by a method, such as RIE.

As described above, the insulating layers 101, 102 contain silicon oxide. The sacrifice layer 110A and the like contain silicon nitride. Here, in the formation of the trench STA, by employing a condition in which silicon oxide is removed more easily than silicon nitride, a length in the Y-direction of the trench STA may become relatively large in a region in which a length in the Z-direction of the insulating layer 102 is large, for example, a region corresponding to the terrace portion TA of the sacrifice layer 110A on the lower side.

For example, as illustrated in FIG. 43, in the hook-up region R_{HU2}, a widened width portion of the trench STA disposed at a position corresponding to the inter-finger structure ST1 (FIG. 9) is formed. This trench STA widens in the Y-direction from the X-direction positive side toward the X-direction negative side in the widened width portion.

For example, as illustrated in FIG. 42, in the region corresponding to the terrace portion TA, the length in the Z-direction of the insulating layer 102 becomes large compared with a region corresponding to the connecting portion 111 (FIG. 9). Therefore, in such a region, as illustrated in FIG. 45, the length in the Y-direction of the trench STA becomes relatively large in some cases.

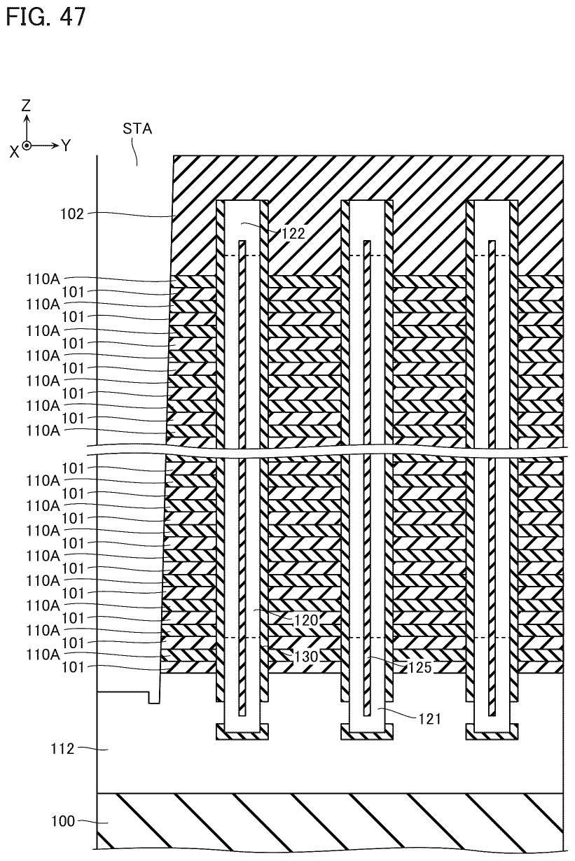

Next, for example, as illustrated in FIG. 47, the wiring layer 112 is formed. In this process, the sacrifice layers 112B, 112C, 112D are removed by, for example, the method of wet etching. The gate insulating film 130 is partially removed by the method of wet etching or the like to expose a part of the outer peripheral surface of the semiconductor column 120. The wiring layer 112 is formed by a method of epitaxial growth or the like.

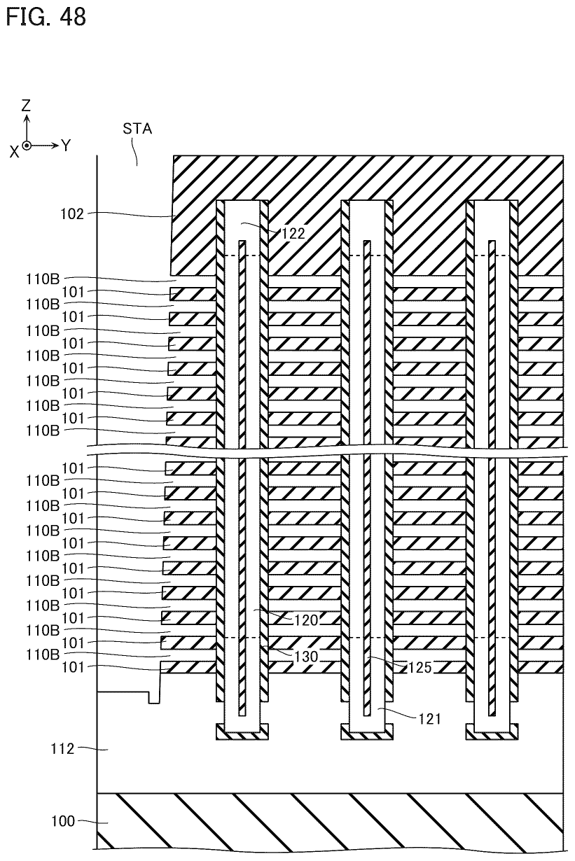

Next, for example, as illustrated in FIG. 48 and FIG. 49, the sacrifice layers 110A are removed via the trench STA. Consequently, a plurality of cavities 110B arranged in the Z-direction are formed. In other words, a hollow structure including a plurality of insulating layers 101 arranged in the Z-direction and a structure supporting the insulating layers 101 is formed. In the memory hole region R_{MH}, a structure inside the memory hole MH (semiconductor column 120, gate insulating film 130, and insulating column 125) supports the insulating layers 101. In the hook-up regions R_{HU1}, R_{HU2}, the supporting insulating members HR support the insulating layers 101. This process is performed by a method, such as wet etching.

Next, for example, as illustrated in FIG. 50, a plurality of conductive layers 110 are formed at the plurality of cavities 110B arranged in the Z-direction. This process is performed by a method, such as CVD.

Next, for example, as illustrated in FIG. 51, the inter-finger structure ST is formed inside the trench STA. This process is performed by, for example, CVD.

Then, the via-contact electrodes CC, Ch, Vy, the bit lines BL, and the like described with reference to FIG. 4, FIG. 5, and the like are formed, and individualization is performed by dicing or the like, thereby forming the semiconductor memory device according to the first embodiment.

### [Effects]

In the manufacture of the semiconductor memory device according to the embodiment, as described with reference to FIG. 48 and FIG. 49, the hollow structure including the plurality of insulating layers 101 arranged in the Z-direction and the structure supporting the insulating layers 101 is formed. In the hook-up regions R_{HU1}, R_{HU2}, the supporting insulating members HR support the insulating layers 101.

Here, as described above, the trench STA widens in the Y-direction from the lower side toward the upper side. Therefore, the supporting insulating members HR excessively close to the trench STA cause a concern that the supporting insulating member HR is partially removed in the processing of the trench STA and the supporting insulating member HR is exposed to the trench STA. For example, when a cavity is formed inside the supporting insulating member HR, in the process described with reference to FIG. 50, a metal, such as titanium nitride or tungsten, is formed inside the cavity, thus causing a leakage current between the conductive layers 110.

On the other hand, when the supporting insulating members HR are excessively spaced from the trench STA, in the process described with reference to FIG. 48 and FIG. 49, a distance from a side surface in the Y-direction of a supporting insulating member HR to an end portion in the Y-direction of the insulating layers 101 becomes large, thus causing deflection of the insulating layers 101.

Therefore, in this embodiment, in the hook-up region R_{HU2}, the supporting insulating members HR in the supporting insulating member rows HRR1 to HRR4 (FIG. 9) corresponding to the structure MLA₁ are disposed at positions closer to the center position in the Y-direction of the inter-finger structure ST1 than the supporting insulating members HR in the supporting insulating member rows HRR1 to HRR4 included in the structure MLA₂, respectively.

With this configuration, the distance from a side surface of a supporting insulating member HR in the Y-direction to an end portion in the Y-direction of the insulating layers 101 can be appropriately adjusted, the leakage current as described above can be suppressed, and the deflection of the insulating layers 101 can be suppressed.

As described with reference to FIG. 43, in the hook-up region R_{HU2}, the trench STA has the widened width portion formed to be widened in the Y-direction from the X-direction positive side toward the X-direction negative side.

Therefore, for example, when a plurality of supporting insulating members HR included in the supporting insulating member rows HRR1, HRR3 closest to the inter-finger structure ST1 are arranged in a row in the X-direction, there is a concern that a part of the supporting insulating members HR are exposed to the trench STA or a part of the supporting insulating members HR are excessively spaced from the trench STA.

Therefore, in this embodiment, as described with reference to FIG. 9, the plurality of supporting insulating members HR in the supporting insulating member rows HRR1, HRR3 are arranged to be gradually spaced from the center position in the Y-direction of the inter-finger structure ST1 from the positive side toward the negative side in the X-direction.

With this configuration, the distance from a side surface in the Y-direction of a supporting insulating member HR to an end portion in the Y-direction of the insulating layers 101 can be appropriately adjusted, the leakage current as described above can be suppressed, and the deflection of the insulating layers 101 can be suppressed.

### Second Embodiment

As described with reference to FIG. 2, in the first embodiment, the hook-up regions R_{HU1}, R_{HU2} are disposed between two memory hole regions R_{MH} arranged in the X-direction. As described with reference to FIG. 3, in the hook-up region R_{HU2}, the plurality of terrace portions T corresponding to the plurality of conductive layers 110 (WL) and the plurality of conductive layers 110 (SGS), and the connecting portion 111 are disposed. However, this configuration is merely an example, and specific configurations can be adjusted as appropriate. For example, the hook-up regions R_{HU1}, R_{HU2} may be disposed at one end portion or both end portions in the X-direction of the memory cell array region R_{MCA}. In the hook-up region R_{HU2}, the connecting portion 111 does not need to be disposed.

Such a configuration is described as a second embodiment below. In the following description, same reference numerals are attached to parts similar to those in the first embodiment, and the explanation may be omitted.

### [Structure]

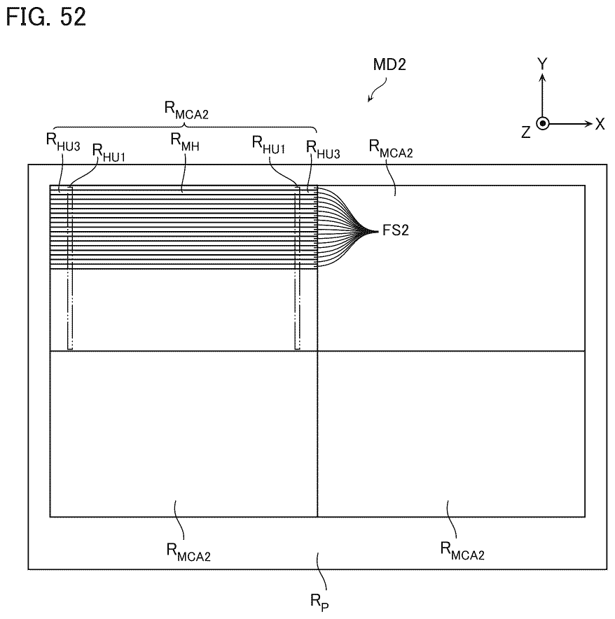

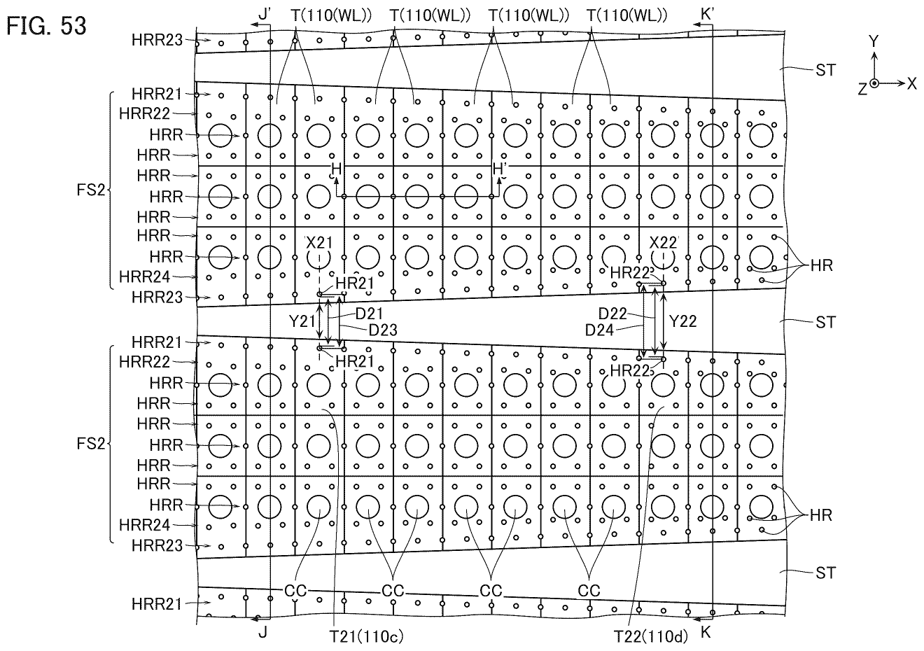

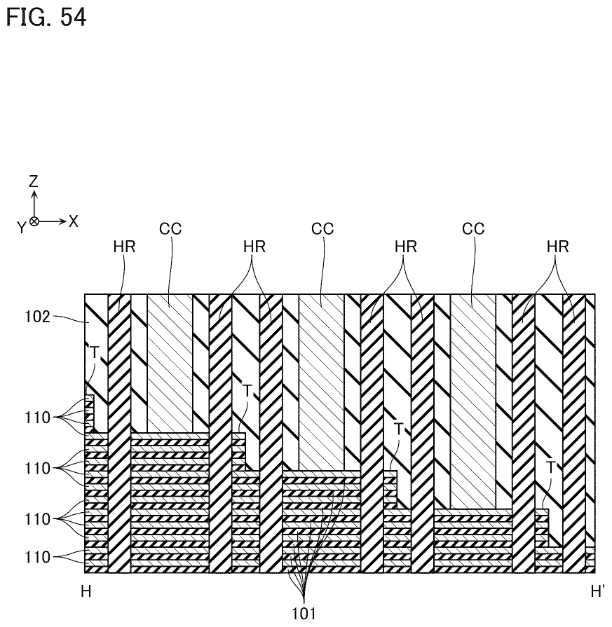

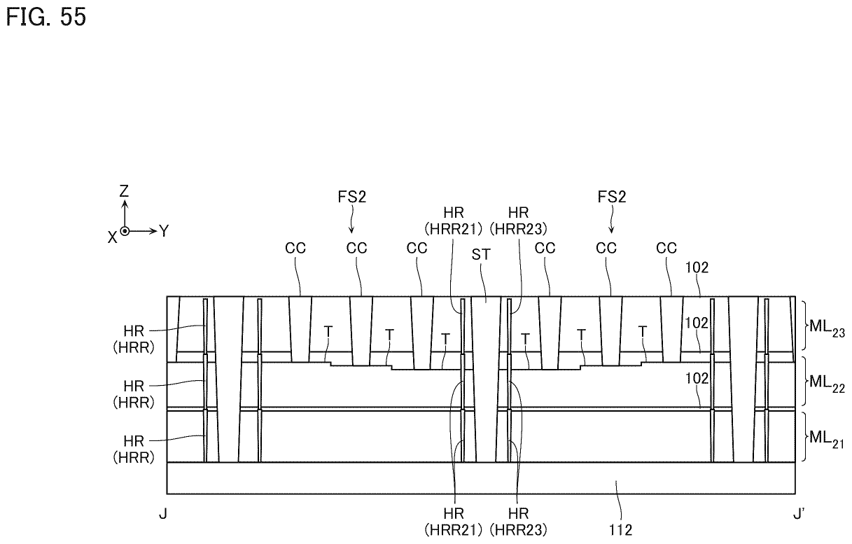

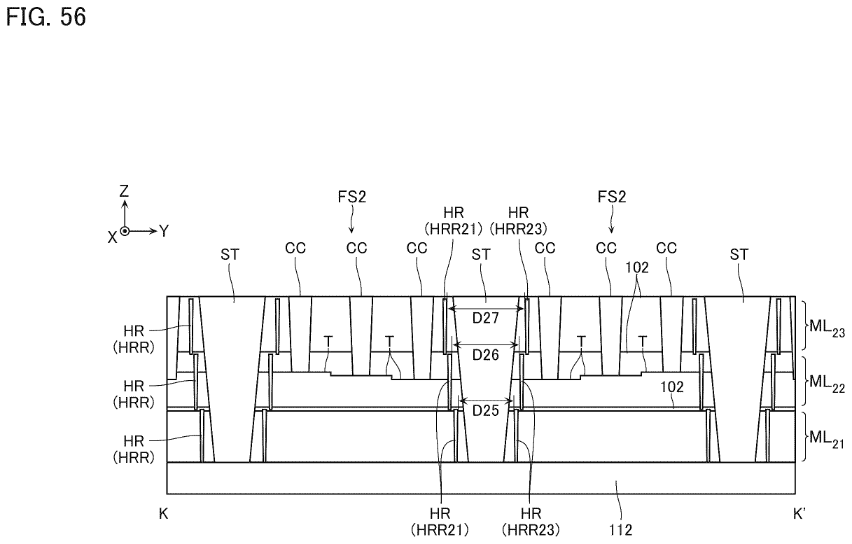

FIG. 52 and FIG. 53 are schematic plan views illustrating a part of a configuration of a semiconductor memory device according to the second embodiment. FIG. 54 is a schematic cross-sectional view illustrating a part of the configuration of the semiconductor memory device, and illustrates a cross-sectional surface of the structure illustrated in FIG. 53 taken along the line H-H′ and viewed in the arrow direction. FIG. 55 is a schematic cross-sectional view illustrating a part of the configuration of the semiconductor memory device, and illustrates a cross-sectional surface of the structure illustrated in FIG. 53 taken along the line J-J′ and viewed in the arrow direction. FIG. 56 is a schematic cross-sectional view illustrating a part of the configuration of the semiconductor memory device, and illustrates a cross-sectional surface of the structure illustrated in FIG. 53 taken along the line K-K′ and viewed in the arrow direction.

As illustrated in FIG. 52, the semiconductor memory device according to the second embodiment includes a memory die MD2. In the example of the drawing, the memory die MD2 includes four memory cell array regions R_{MCA2} arranged in the X-direction and the Y-direction. The memory cell array region R_{MCA2} includes two hook-up regions R_{HU3} arranged in the X-direction, two hook-up regions R_{HU1} arranged in the X-direction between these two hook-up regions R_{HU3}, and a memory hole region R_{MH} disposed between these two hook-up regions R_{HU1}. At an end portion in the Y-direction of the memory die MD2, a peripheral circuit region R_{P} is disposed.

The memory cell array region R_{MCA2} includes a plurality of finger structures FS2 arranged in the Y-direction. These plurality of finger structure FS2 extend in the X-direction over the two hook-up regions R_{HU3} arranged in the X-direction, the two hook-up regions R_{HU1} disposed between the two hook-up regions R_{HU3}, and the memory hole region R_{MH} disposed between the two hook-up regions R_{HU1}.

The finger structure FS2 is basically configured similarly to the finger structure FS. However, the finger structure FS2 includes a plurality of (in the example of the drawing, three) structures ML₂₁, ML₂₂, ML₂₃ (FIG. 55, FIG. 56) arranged in the Z-direction instead of the plurality of structures ML₁, ML₂, ML₃.

The plurality of structures ML₂₁, ML₂₂, ML₂₃ are basically configured similarly to the plurality of structures ML₁, ML₂, ML₃. However, the structures of the plurality of structures ML₂₁, ML₂₂, ML₂₃ in the hook-up region R_{HU3} are different from the structures of the plurality of structures ML₁, ML₂, ML₃ in the hook-up region R_{HU2}.

As illustrated in FIG. 53, in the hook-up region R_{HU3}, terrace portions T of the plurality of conductive layers 110 are disposed. In this embodiment, the terrace portions T of the plurality of conductive layers 110 (WL) and the one or plurality of conductive layers 110 (SGS) are disposed at end portions in the X-direction of the plurality of conductive layers 110 (WL) and the one or plurality of conductive layers 110 (SGS), respectively. As illustrated in FIG. 54, these plurality of terrace portions T are covered with the insulating layer 102. In the hook-up region R_{HU3}, a plurality of via-contact electrodes CC are disposed correspondingly to the plurality of terrace portions T.

In the example of FIG. 53, a plurality of terrace portions T corresponding to a 3n+1-th (n is an integer of 0 or more) conductive layer 110 (WL) counting from above are arranged in the X-direction when viewed from above. Similarly, a plurality of terrace portions T corresponding to a 3n+2-th conductive layer 110 (WL) counting from above are arranged in the X-direction when viewed from above. Similarly, a plurality of terrace portions T corresponding to a 3n+3-th conductive layer 110 (WL) counting from above are arranged in the X-direction when viewed from above. In these plurality of terrace portions T, for example, those disposed on the X-direction negative side correspond to the conductive layers 110 on the upper side, and those disposed on the X-direction positive side correspond to the conductive layers 110 on the lower side.

In the example of the drawing, the terrace portions T corresponding to the 3n+1-th conductive layer 110 (WL) counting from above are each arranged with two terrace portions T corresponding to the 3n+2-th and 3n+3-th conductive layers 110 (WL) in the Y-direction when viewed from above.

Here, in the hook-up region R_{HU3}, the inter-finger structure ST has a widened width portion. The inter-finger structure ST widens in the Y-direction from one side (memory hole region R_{MH} side) in the X-direction toward the other side (opposite side of memory hole region R_{MH}) in the X-direction in the widened width portion.

In the hook-up region R_{HU3}, the inter-finger structure ST has a width in the Y-direction increased toward the terrace portions T of the conductive layers 110 disposed on the lower side, that is, increased as the length in the Z-direction of the insulating layer 102 increases. For example, in the example of FIG. 53, a terrace portion T21 of a conductive layer 110c is disposed at a position X21 in the X-direction. A terrace portion T22 of a conductive layer 110d below the conductive layer 110c is disposed at a position X22 in the X-direction. Here, a width Y21 in the Y-direction of the inter-finger structure ST at the position X21 is smaller than a width Y22 in the Y-direction of the inter-finger structure ST at the position X22.

In the hook-up region R_{HU3}, a plurality of supporting insulating member rows HRR arranged in the Y-direction are disposed. As illustrated in FIG. 54, in this embodiment, a height position of an upper end of the supporting insulating member HR is disposed above a height position of the corresponding terrace portion T. That is, as illustrated in FIG. 55 and FIG. 56, in each of the finger structures FS2, a plurality of supporting insulating member rows HRR arranged in the Y-direction are disposed in the structures ML₂₁, ML₂₂, ML₂₃ including the positions in the Z-direction corresponding to the insulating layers 102 disposed to cover the terrace portions T.

Here, as illustrated in FIG. 53, the supporting insulating member row HRR basically includes a plurality of supporting insulating members HR arranged in a row in the X-direction. That is, positions in the Y-direction of the plurality of supporting insulating members HR included in the supporting insulating member row HRR are basically approximately the same.

However, in the hook-up region R_{HU3}, among a plurality of supporting insulating member rows HRR included in each finger structure FS2, in first and second supporting insulating member rows HRR21, HRR22 counting from one side in the Y-direction and first and second supporting insulating member rows HRR23, HRR24 counting from the other side in the Y-direction, a plurality of supporting insulating members HR are arranged so as to be gradually spaced from a center position in the Y-direction of the inter-finger structure ST from one side (memory hole region R_{MH} side) in the X-direction toward the other side (opposite side of memory hole region R_{MH}) in the X-direction.

In these supporting insulating member rows HRR21 to HRR24, positions in the Y-direction of the plurality of supporting insulating members HR are spaced from the center position in the Y-direction of the inter-finger structure ST toward the terrace portions T of the conductive layers 110 disposed on the lower side, that is, as the length in the Z-direction of the insulating layer 102 increases. For example, in the example of FIG. 53, among a plurality of supporting insulating members HR included in the two supporting insulating member rows HRR21, HRR23 adjacent in the Y-direction via the inter-finger structure ST, a distance D21 in the Y-direction between two supporting insulating members HR21 disposed at the position X21 is smaller than a distance D22 in the Y-direction between two supporting insulating members HR22 disposed at the position X22. A distance D23 between center positions in the Y-direction of the two supporting insulating members HR21 is smaller than a distance D24 between center positions in the Y-direction of the two supporting insulating members HR22.

FIG. 53 illustrates a configuration at the proximity of the terrace portions T of the conductive layers 110 included in the structure ML₂₂. However, configurations at the proximity of the terrace portions T of the conductive layers 110 included in the structures ML₂₁, ML₂₃ are approximately the same.

However, the inter-finger structure ST widens in the Y-direction from an end portion on one side (memory hole region R_{MH} side) in the X-direction toward an end portion at the other side (opposite side of memory hole region R_{MH}) in the X-direction of the hook-up region R_{HU3} in the widened width portion. Therefore, at the proximity of the terrace portions T of the conductive layers 110 included in the structure ML₂₁, the width in the Y-direction of the inter-finger structure ST is larger than the widths Y21, Y22. At the proximity of the terrace portions T of the conductive layers 110 included in the structure ML₂₃, the width in the Y-direction of the inter-finger structure ST is smaller than the widths Y21, Y22.

At the proximity of the terrace portions T of the conductive layers 110 included in the structure ML₂₃, among the plurality of supporting insulating members HR included in the two supporting insulating member rows HRR adjacent in the Y-direction via the inter-finger structure ST, a distance in the Y-direction between two supporting insulating members HR that are disposed at a predetermined position in the X-direction and included in the structure ML₂₂ is smaller than the distance D21, D22.

As illustrated in FIG. 55, a plurality of supporting insulating members HR included in the structure ML₂₂ are basically disposed at positions overlapping with a plurality of supporting insulating members HR included in the structure ML₂₁ when viewed in the Z-direction. Similarly, a plurality of supporting insulating members HR included in the structure ML₂₃ are basically disposed at positions overlapping with the plurality of supporting insulating members HR included in the structure ML₂₂ when viewed in the Z-direction.

However, as illustrated in FIG. 56, for example, at the position X22 (FIG. 53) or the proximity thereof, the supporting insulating member HR in the supporting insulating member row HRR21 included in the structure ML₂₁ is disposed at a position closer to the center position in the Y-direction of the inter-finger structure ST than supporting insulating member HR in the supporting insulating member row HRR21 included in the structure ML₂₂. Similarly, respective supporting insulating members HR in the supporting insulating member rows HRR22 to HRR24 included in the structure ML₂₁ are disposed at positions closer to the center position of the inter-finger structure ST in the Y-direction than supporting insulating members HR in the supporting insulating member rows HRR22 to HRR24 included in the structure ML₂₂. Similarly, respective supporting insulating members HR in the supporting insulating member rows HRR21 to HRR24 included in the structure ML₂₂ are disposed at positions closer to the center position in the Y-direction of the inter-finger structure ST than supporting insulating members HR in the supporting insulating member rows HRR21 to HRR24 included in the structure ML₂₃.

In the example of FIG. 56, a distance D25 in the Y-direction between the supporting insulating members HR in the supporting insulating member rows HRR21, HRR23 adjacent in the Y-direction via the inter-finger structure ST in the structure ML₂₁ is smaller than a distance D26 in the Y-direction between the supporting insulating members HR in the supporting insulating member rows HRR21, HRR23 adjacent in the Y-direction via the inter-finger structure ST in the structure ML₂₂. The distance D26 is smaller than a distance D27 in the Y-direction between the supporting insulating members HR in the supporting insulating member rows HRR21, HRR23 adjacent in the Y-direction via the inter-finger structure ST in the structure ML₂₃.

A length corresponding to a difference between the distance D25 and the distance D26 may be increased toward the terrace portions T of the conductive layers 110 disposed on the lower side, that is, as the length in the Z-direction of the insulating layer 102 increases. Similarly, a length corresponding to a difference between the distance D26 and the distance D27 may be increased toward the terrace portions T of the conductive layers 110 disposed on the lower side, that is, as the length in the Z-direction of the insulating layer 102 increases.

### [Manufacturing Method]

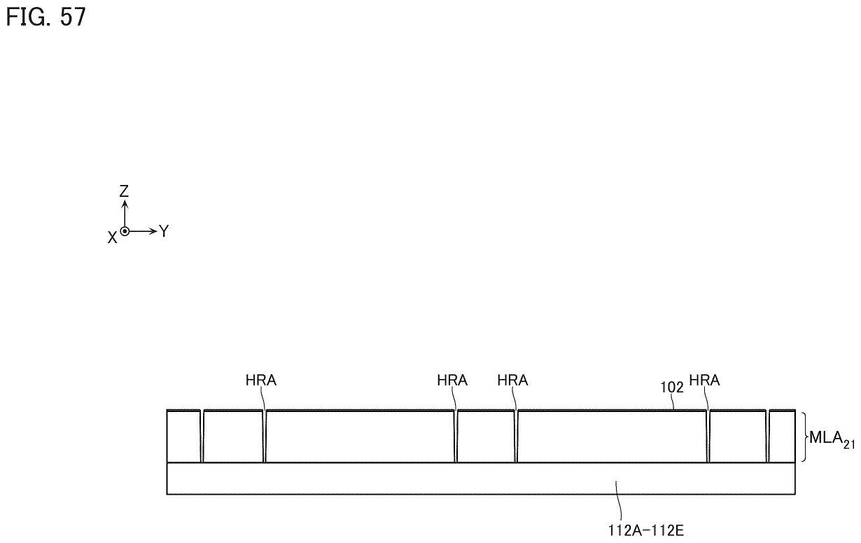

Next, with reference to FIG. 57 to FIG. 68, a method for manufacturing the semiconductor memory device according to the second embodiment is described. FIG. 57 to FIG. 68 are schematic cross-sectional views for describing the manufacturing method, and illustrate cross-sectional surfaces corresponding to FIG. 56.

In the manufacture of the semiconductor memory device according to the embodiment, the process described with reference to FIG. 14 is performed. In this process, among the plurality of insulating layers 101, those included in the structure ML₂₁ (FIG. 56) are formed, and among the plurality of sacrifice layers 110A, those corresponding to the conductive layers 110 in the structure ML₂₁ are formed. Hereinafter, a configuration including them may be referred to as a structure MLA₂₁.

Next, the plurality of insulating layers 101 and the plurality of sacrifice layers 110A are partially removed in the hook-up region R_{HU3}, thus forming a plurality of terrace portions TA. In this process, for example, similarly to the process described with reference to FIG. 20 and FIG. 21, a resist is formed on an upper surface of a structure as illustrated in FIG. 14. Removal of the sacrifice layer 110A, removal of the insulating layer 101, and removal of a part of the resist are repeatedly performed.

Next, the insulating layer 102 of silicon oxide (SiO₂) or the like that covers the plurality of terrace portions TA is formed. This process is performed, for example, similarly to the process described with reference to FIG. 22.

Next, for example, as illustrated in FIG. 15, FIG. 17, and FIG. 57, a plurality of memory holes MH are formed at positions corresponding to the plurality of semiconductor columns 120. A plurality of via holes HRA are formed at positions corresponding to the plurality of supporting insulating members HR. This process is performed, for example, similarly to the process described with reference to FIG. 15 to FIG. 17.

Next, for example, the process described with reference to FIG. 18 is performed.

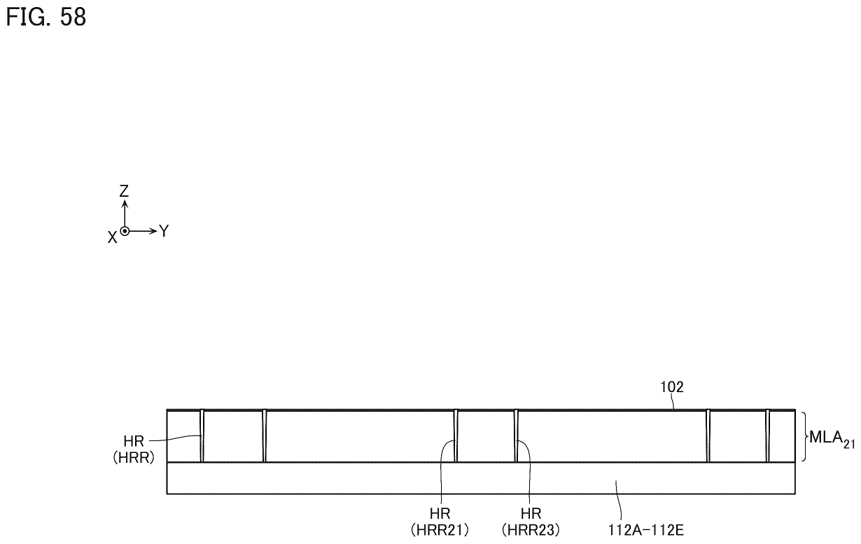

Next, for example, as illustrated in FIG. 58, the supporting insulating members HR are formed inside the plurality of via holes HRA. This process is performed, for example, similarly to the process described with reference to FIG. 19.

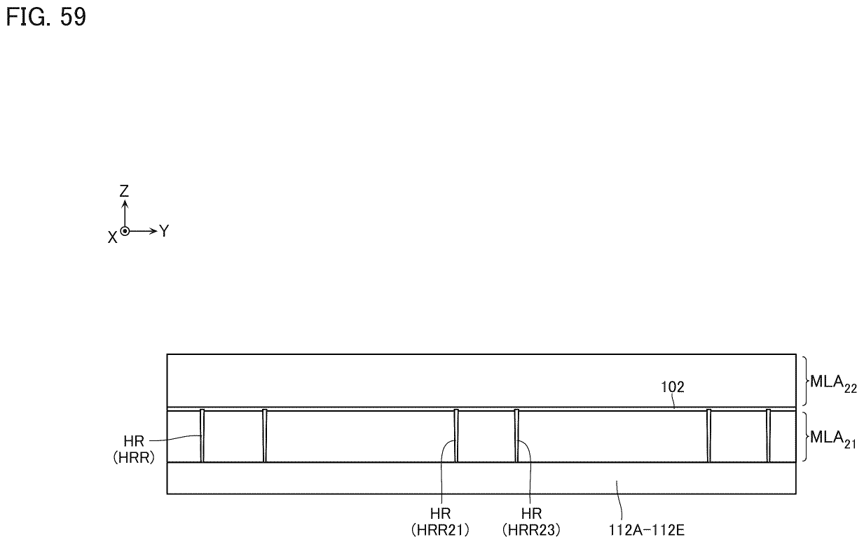

Next, for example, as illustrated in FIG. 23 and FIG. 59, a plurality of insulating layers 101 and a plurality of sacrifice layers 110A are alternately formed on an upper surface of the insulating layer 102. In this process, among the plurality of insulating layers 101, those included in the structure ML₂₂ (FIG. 56) are formed, and among the plurality of sacrifice layers 110A, those corresponding to the conductive layers 110 in the structure ML₂₂ are formed. Hereinafter, a configuration including them may be referred to as a structure MLA₂₂.

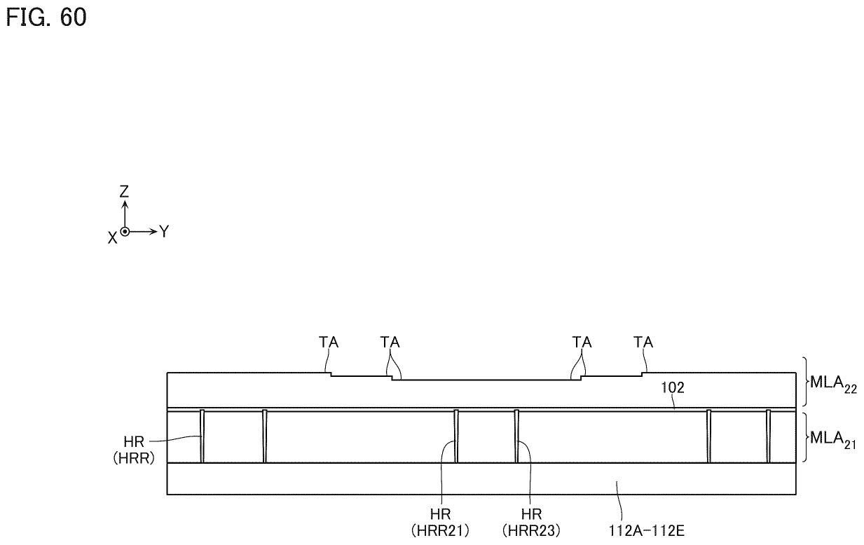

Next, as illustrated in FIG. 60, the plurality of insulating layers 101 and the plurality of sacrifice layers 110A are partially removed in the hook-up region R_{HU3}, thus forming a plurality of terrace portions TA. This process is performed, for example, similarly to the process described with reference to FIG. 29 and FIG. 30.

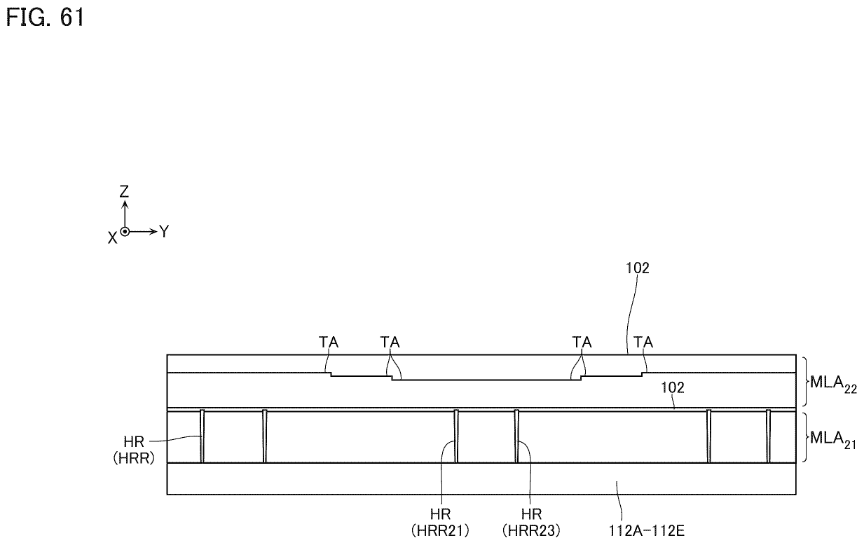

Next, as illustrated in FIG. 61, the insulating layer 102 of silicon oxide (SiO₂) or the like that covers the plurality of terrace portions TA is formed. This process is performed, for example, similarly to the process described with reference to FIG. 31.

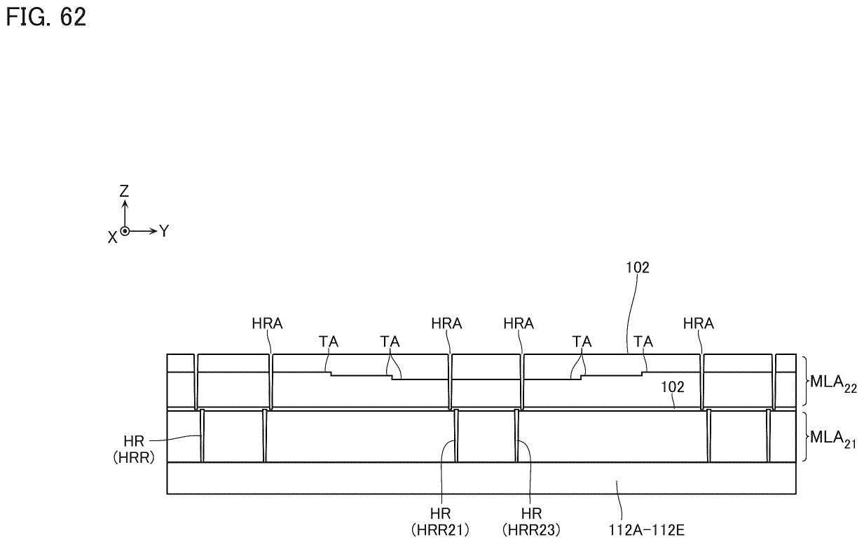

Next, for example, as illustrated in FIG. 25 and FIG. 62, a plurality of memory holes MH are formed at positions corresponding to the plurality of semiconductor columns 120. A plurality of via holes HRA are formed at positions corresponding to the plurality of supporting insulating members HR. This process is performed, for example, similarly to the process described with reference to FIG. 25 and FIG. 26.

Next, for example, the process described with reference to FIG. 27 is performed.

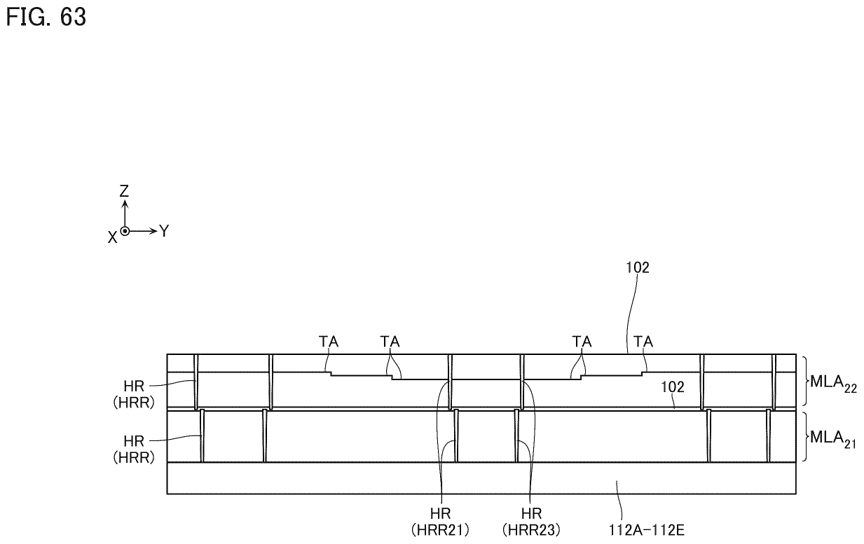

Next, for example, as illustrated in FIG. 63, the supporting insulating members HR are formed inside the plurality of via holes HRA. This process is performed, for example, similarly to the process described with reference to FIG. 28.

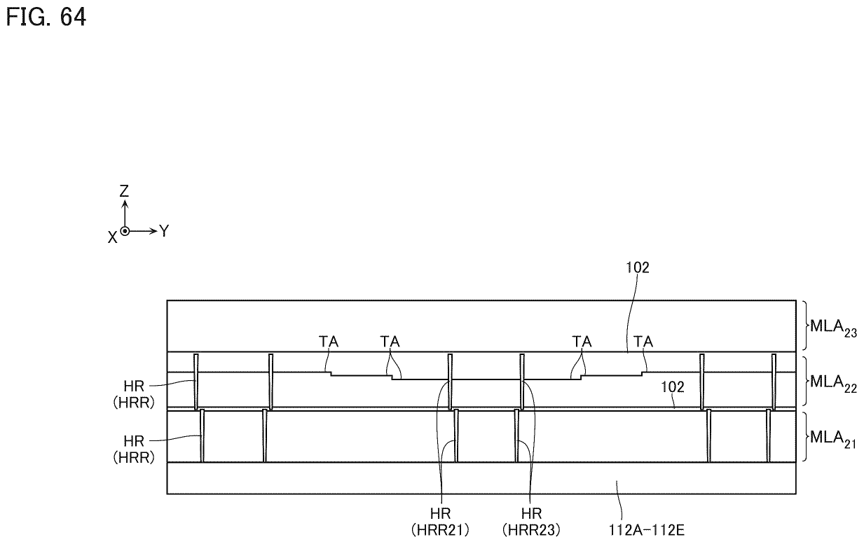

Next, for example, as illustrated in FIG. 32 and FIG. 64, a plurality of insulating layers 101 and a plurality of sacrifice layers 110A are alternately formed on an upper surface of the insulating layer 102. In this process, among the plurality of insulating layers 101, those included in the structure ML₂₃ (FIG. 56) are formed, and among the plurality of sacrifice layers 110A, those corresponding to the conductive layers 110 in the structure ML₂₃ are formed. Here, a configuration including them is referred to as a structure MLA₂₃.

Next, the plurality of insulating layers 101 and the plurality of sacrifice layers 110A are partially removed in the hook-up region R_{HU3}, thus forming a plurality of terrace portions TA. This process is performed, for example, similarly to the process described with reference to FIG. 40 and FIG. 41.

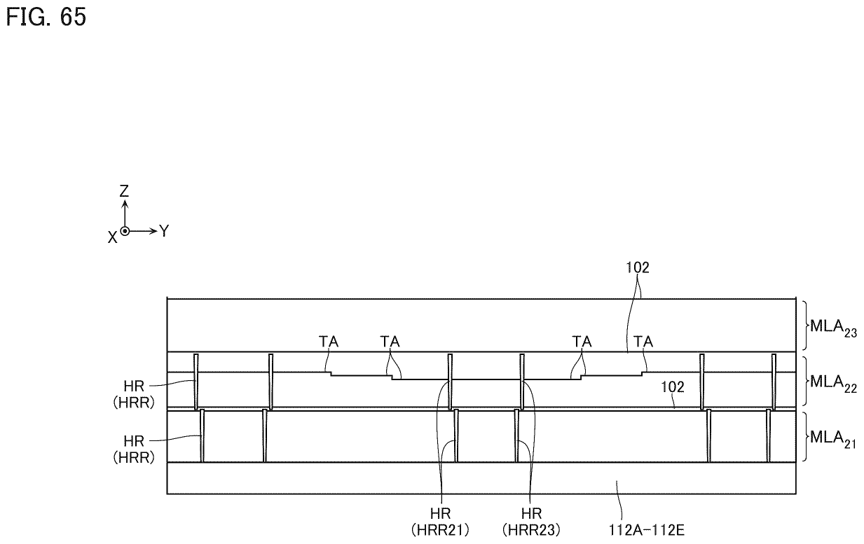

Next, for example, as illustrated in FIG. 65, the insulating layer 102 of silicon oxide (SiO₂) or the like that covers the plurality of terrace portions TA is formed. This process is performed, for example, similarly to the process described with reference to FIG. 42.

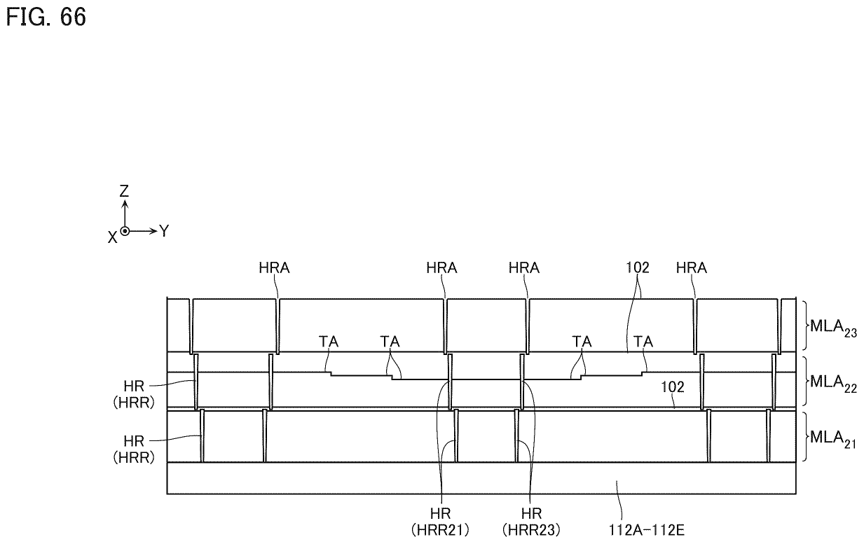

Next, for example, as illustrated in FIG. 34 and FIG. 66, a plurality of memory holes MH are formed at positions corresponding to the plurality of semiconductor columns 120. A plurality of via holes HRA are formed at positions corresponding to the plurality of supporting insulating members HR. This process is performed, for example, similarly to the process described with reference to FIG. 34 and FIG. 35.

Next, for example, the process described with reference to FIG. 36 to FIG. 38 is performed.

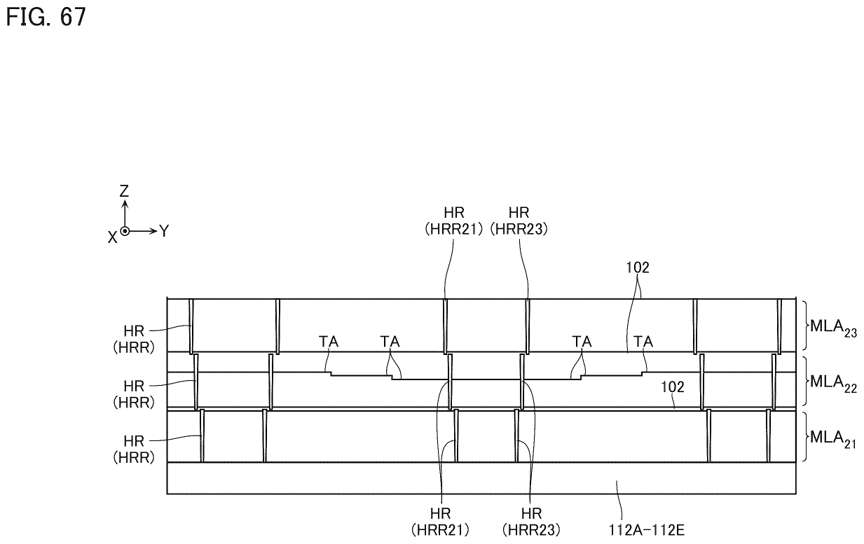

Next, for example, as illustrated in FIG. 67, the supporting insulating members HR are formed inside the plurality of via holes HRA. This process is performed, for example, similarly to the process described with reference to FIG. 39.

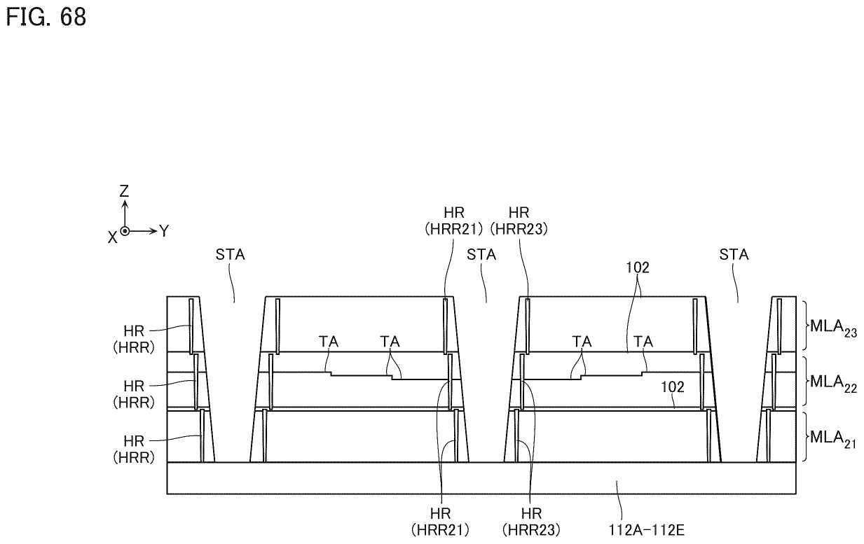

Next, for example, as illustrated in FIG. 44 and FIG. 68, trenches STA are formed at positions corresponding to the inter-finger structures ST. This process is performed, for example, similarly to the process described with reference to FIG. 43 to FIG. 46.

Subsequently, the processes following the process described with reference to FIG. 47 in the manufacturing method of the semiconductor memory device according to the first embodiment are performed, thus forming the semiconductor memory device according to the second embodiment.

### [Effects]

Also in the structure as described in the second embodiment, the supporting insulating members HR in the supporting insulating member rows HRR21 to HRR24 corresponding to the structure MLA₂₁ are disposed at positions closer to the center position in the Y-direction of the inter-finger structure ST than the supporting insulating members HR in the supporting insulating member rows HRR21 to HRR24 included in the structure MLA₂₂, respectively. This allows suppressing the leakage current, and reducing the deflection of the insulating layers 101.

In the hook-up region R_{HU3}, the plurality of supporting insulating members HR in the supporting insulating member rows HRR21, HRR23 are arranged to be gradually spaced from the center position in the Y-direction of the inter-finger structure ST from one side (memory hole region R_{MH} side) in the X-direction toward the other side (opposite side of memory hole region R_{MH}) in the X-direction. This allows suppressing the leakage current, and reducing the deflection of the insulating layers 101.

### Third Embodiment

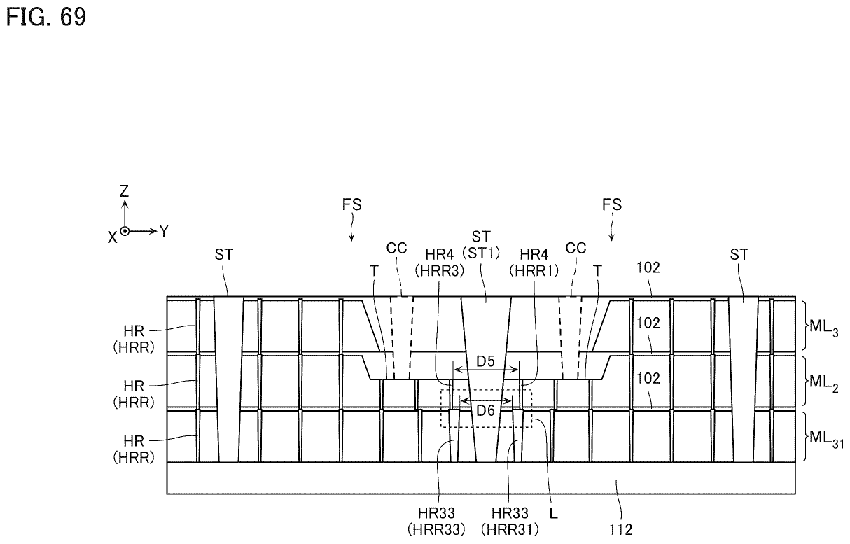

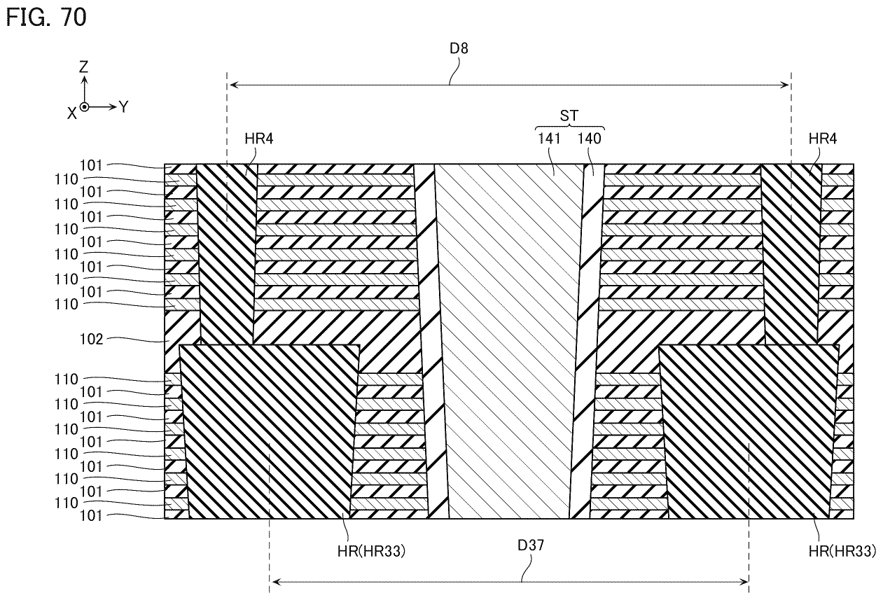

Next with reference to FIG. 69 and FIG. 70, a semiconductor memory device according to the third embodiment is described. In the following description, same reference numerals are attached to parts similar to those in the first embodiment, and the explanation may be omitted.

FIG. 69 is a schematic cross-sectional view illustrating a part of a configuration of the semiconductor memory device. FIG. 70 is a schematic cross-sectional view illustrating a part of the configuration of the semiconductor memory device, and illustrates an enlarged part L of FIG. 69.

The semiconductor memory device according to the third embodiment is basically configured similarly to the semiconductor memory device according to the first embodiment, but includes a structure ML₃₁ instead of the structure ML₁. The structure ML₃₁ is basically configured similarly to the structure ML₁, but includes supporting insulating member rows HRR31, HRR33 instead of the supporting insulating member rows HRR1, HRR3. The supporting insulating member rows HRR31, HRR33 are basically configured similarly to the supporting insulating member rows HRR1, HRR3, but includes a supporting insulating member HR33 instead of the supporting insulating member HR3.

The supporting insulating member HR33 is basically configured similarly to the supporting insulating member HR3. However, while the supporting insulating member HR3 has lengths in the X-direction and the Y-direction similar to lengths of other supporting insulating members HR in the X-direction and the Y-direction, the supporting insulating member HR33 has lengths in the X-direction and the Y-direction larger than lengths of other supporting insulating members HR in the X-direction and the Y-direction.

For example, at the position X2 (FIG. 9) or the proximity thereof, the supporting insulating member HR33 in the supporting insulating member row HRR31 included in the structure ML₃₁ is disposed at a position closer to the center position in the Y-direction of the inter-finger structure ST1 than the supporting insulating member HR4 in the supporting insulating member row HRR1 included in the structure ML₂. Similarly, the supporting insulating member HR33 in the supporting insulating member row HRR33 included in the structure ML₃₁ is disposed at a position closer to the center position in the Y-direction of the inter-finger structure ST1 than the supporting insulating member HR4 in the supporting insulating member row HRR3 included in the structure ML₂. That is, a distance D6 in the Y-direction between two supporting insulating members HR33 adjacent in the Y-direction via the inter-finger structure ST1 in the structure ML₃₁ is smaller than a distance D5 in the Y-direction between two supporting insulating members HR4 adjacent in the Y-direction via the inter-finger structure ST1 in the structure ML₂.

In the example of FIG. 70, a distance D37 between center positions in the Y-direction of the two supporting insulating members HR33 adjacent in the Y-direction via the inter-finger structure ST1 in the structure ML₃₁ is smaller than a distance D8 between center positions in the Y-direction of the two supporting insulating members HR4 adjacent in the Y-direction via the inter-finger structure ST1 in the structure ML₂. However, the distance D37 may be approximately the same as the distance D8, and may be larger than the distance D8.

In the example of FIG. 70, an upper end of the supporting insulating member HR33 is connected to a lower end of the supporting insulating member HR4. However, the upper end of the supporting insulating member HR33 may be spaced from the lower end of the supporting insulating member HR4 in the Y-direction.

The semiconductor memory device according to the third embodiment can be basically manufactured by a method similar to that of the semiconductor memory device according to the first embodiment. However, in the manufacture of the semiconductor memory device according to the third embodiment, in the process described with reference to FIG. 15 to FIG. 17, a via hole HRA larger than other via holes HRA is formed at a position corresponding to the supporting insulating member HR33.

Also with the structure as described in the third embodiment, the leakage current can be suppressed, and the deflection of the insulating layers 101 can be suppressed. In the semiconductor memory device according to the second embodiment, a part of the ordinary supporting insulating members HR included in the supporting insulating member rows HRR21, HRR23 in the structure ML₂₁ may be replaced with the supporting insulating members HR33 according to the third embodiment.

### Fourth Embodiment

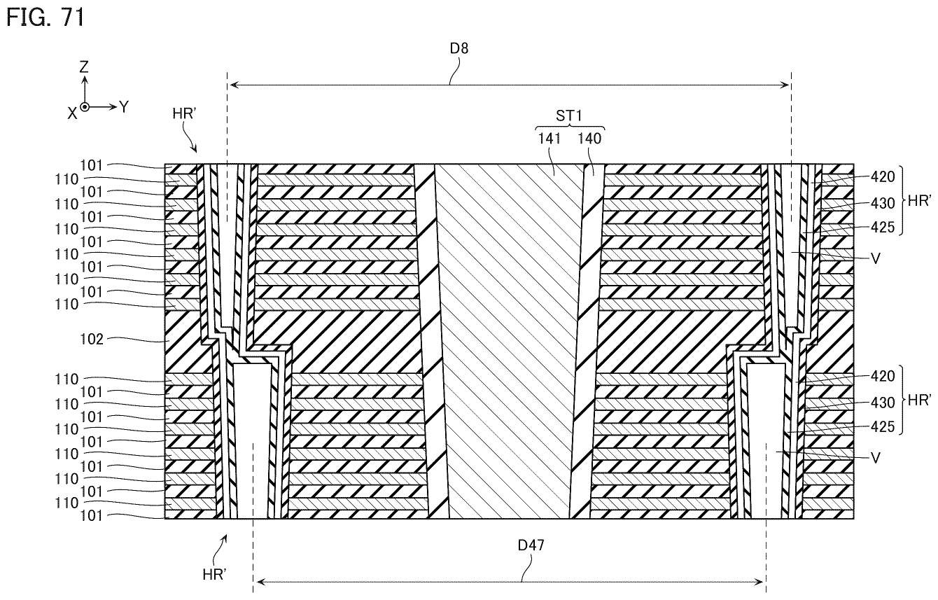

Next with reference to FIG. 71, a semiconductor memory device according to the fourth embodiment is described. FIG. 71 is a schematic cross-sectional view illustrating a part of a configuration of the semiconductor memory device. In the following description, same reference numerals are attached to parts similar to those in the first embodiment, and the explanation may be omitted.

The semiconductor memory device according to the fourth embodiment is basically configured similarly to the semiconductor memory device according to the first embodiment, but includes a supporting insulating member HR′ instead of the supporting insulating member HR.

The supporting insulating member HR′ includes a semiconductor column 420 extending in the Z-direction, an insulating film 430 disposed between a plurality of conductive layers 110 and the semiconductor column 420, and an insulating column 425 disposed at a center portion of the semiconductor column 420. The semiconductor column 420, the insulating film 430, and the insulating column 425 are basically configured similarly to the semiconductor column 120, the gate insulating film 130, and the insulating column 125, respectively. However, the semiconductor column 420 is not electrically connected to the bit line BL, and neither the semiconductor column 420 nor the insulating film 430 function as a configuration of the memory cell MC and the like. In the example of the drawing, a cavity V is disposed inside the insulating column 425.

As illustrated in FIG. 71, a distance D47 between center positions in the Y-direction of two supporting insulating members HR′ adjacent in the Y-direction via the inter-finger structure ST1 in the structure ML is smaller than a distance D8 between center positions in the Y-direction of two supporting insulating members HR′ adjacent in the Y-direction via the inter-finger structure ST1 in the structure ML₂.

As illustrated in FIG. 71, the semiconductor column 420, the insulating film 430, and the insulating column 425 included in the supporting insulating member HR′ in the structure ML₁ has upper ends connected to lower ends of the semiconductor column 420, the insulating film 430, and the insulating column 425 included in the supporting insulating member HR′ in the structure ML₂, respectively.

The semiconductor memory device according to the fourth embodiment can be basically manufactured by a method similar to that of the semiconductor memory device according to the first embodiment. However, in the manufacture of the semiconductor memory device according to the fourth embodiment, in the process described with reference to FIG. 18, and the process described with reference to FIG. 27, the sacrifice column 120A is formed not only inside the memory hole MH but also inside the via hole HRA. Further, in the process described with reference to FIG. 37 and FIG. 38, the insulating film 430, the semiconductor column 420, and the insulating column 425 are formed inside the via hole HRA.

In the manufacture of the semiconductor memory device according to the fourth embodiment, the process described with reference to FIG. 19, the process described with reference to FIG. 28, or the process described with reference to FIG. 39 is not performed.

Also with the structure as described in the fourth embodiment, the leakage current can be suppressed, and the deflection of the insulating layers 101 can be suppressed.

In the semiconductor memory device according to the first embodiment, only a part of the supporting insulating members HR may be replaced with the supporting insulating member HR′ according to fourth embodiment. In the semiconductor memory device according to the second embodiment or the third embodiment, a part of or all of the supporting insulating members HR may be replaced with the supporting insulating members HR′ according to fourth embodiment.

### Other Embodiments

The semiconductor memory devices according to the first embodiment to the fourth embodiment are described above. However, the configurations described above are merely examples, and the specific configurations can be adjusted as necessary.

For example, the arrangements of the supporting insulating members HR as illustrated in FIG. 4, FIG. 9, and FIG. 53 are merely examples, and the specific arrangement can be adjusted as appropriate.

For example, in the semiconductor memory device according to the first embodiment, in each of the finger structures FS, in the supporting insulating member rows HRR1 to HRR4 close to the inter-finger structure ST1, the supporting insulating members HR in the structure ML₁ are disposed at the positions closer to the center position in the Y-direction of the inter-finger structure ST1 than the supporting insulating members HR in the structure ML₂. On the other hand, in each of the finger structures FS, in one or a plurality of supporting insulating member rows HRR close to the other inter-finger structures ST, the supporting insulating members HR in the structure ML₂ are disposed at the positions overlapping with the supporting insulating members HR in the structure ML₁ when viewed in the Z-direction.

However, for example, in the semiconductor memory device according to the first embodiment, in one or a plurality of supporting insulating member rows HRR close to the inter-finger structures ST other than the inter-finger structure ST1, the supporting insulating members HR in the structure ML₁ may be disposed at the positions closer to the center position in the Y-direction of the inter-finger structure ST than the supporting insulating members HR in the structure ML₂.

For example, in the first embodiment to the fourth embodiment, in all of the supporting insulating member rows HRR in each of the finger structures FS (FS2), the supporting insulating members HR (HR′) in the structure ML₂ (ML₂₂) may be disposed at the positions overlapping with the supporting insulating members HR (HR′) in the structure ML₁ (ML₂₁, ML₃₁) when viewed in the Z-direction. Further, in all of the supporting insulating member rows HRR in each of the finger structures FS (FS2), the supporting insulating members HR (HR′) in the structure ML₃ (ML₂₃) may be disposed at the positions overlapping with the supporting insulating members HR (HR′) in the structure ML₂ (ML₂₂) when viewed in the Z-direction.

For example, in the first embodiment to the third embodiment, an example in which every supporting insulating member HR has the outer peripheral surface surrounded by the conductive layers 110 over the whole circumference is described. However, such a configuration is merely an example, and the specific configuration can be adjusted as appropriate.

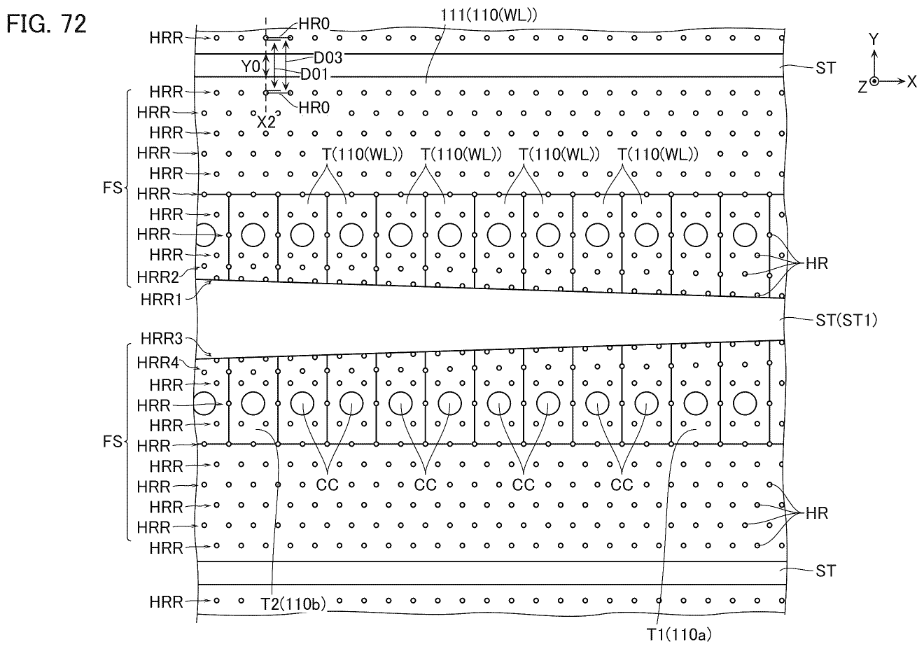

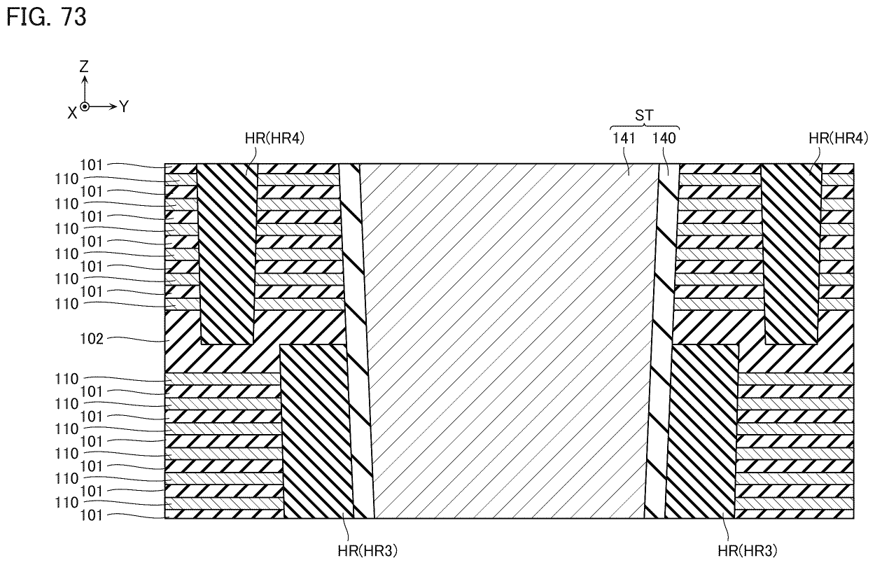

FIG. 72 is a schematic plan view illustrating a part of a configuration of a semiconductor memory device according to another embodiment. FIG. 73 is a schematic cross-sectional view illustrating a part of the configuration of the semiconductor memory device according to the embodiment corresponding to FIG. 72.

As described above, in the manufacture of the semiconductor memory device, when the supporting insulating member HR is exposed to the trench STA, in the process described with reference to FIG. 50, a metal, such as titanium nitride or tungsten, may be formed in the cavity inside the supporting insulating member HR, thus causing a leakage current between the conductive layers 110. However, such a cavity tends to be formed at the proximity of the center axis of the supporting insulating member HR. Therefore, even when the supporting insulating member HR is exposed to the trench STA, the generation of the leakage current can be suppressed as long as the cavity inside the supporting insulating member HR is not exposed to the trench STA. Accordingly, in the first embodiment to the third embodiment, it is not necessary that every supporting insulating member HR has the outer peripheral surface surrounded by the conductive layers 110 over the whole circumference. However, as illustrated in FIG. 72 and FIG. 73, at least a part of the outer peripheral surface of the supporting insulating member HR may be surrounded by the conductive layers 110.

For example, in the first embodiment to the fourth embodiment, an example in which the inter-finger structure ST widens in the Y-direction from the lower end toward the upper end is described. However, such a configuration is merely an example, and the specific configuration can be adjusted as appropriate.

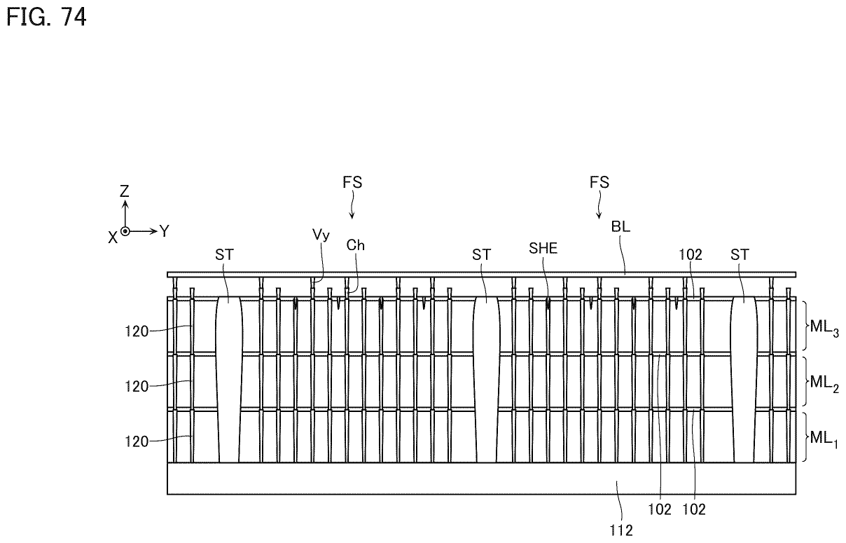

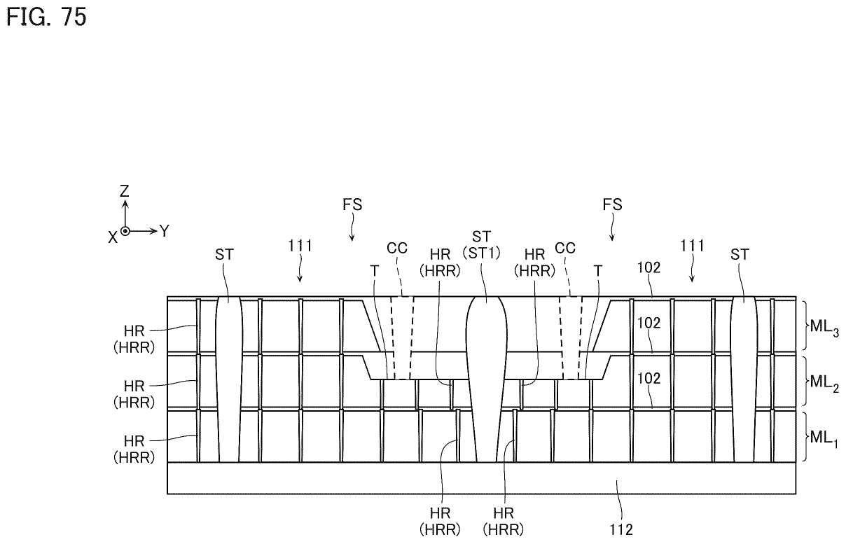

FIG. 74 is a schematic cross-sectional view illustrating a part of a configuration of a semiconductor memory device according to another embodiment. FIG. 75 is a schematic cross-sectional view illustrating a part of a configuration of a semiconductor memory device according to the embodiment corresponding to FIG. 74.

In the example of FIG. 74 and FIG. 75, the inter-finger structure ST has a widened width portion widening in the Y-direction from a lower end toward a height position corresponding to the structure ML₃. In the example of FIG. 74 and FIG. 75, the inter-finger structure ST widens in the Y-direction from an upper end toward the height position corresponding to the structure ML₃. The inter-finger structure ST according to the first embodiment to the fourth embodiment may have a shape as described above.

The manufacturing methods described above are merely examples, and the specific method can be adjusted as appropriate.

For example, in the manufacture of the semiconductor memory device according to the first embodiment, the memory hole MH, the via hole HRA, and the configuration of the inside thereof are formed as described with reference to FIG. 15 to FIG. 19, and then the plurality of terrace portions TA and the insulating layer 102 thereabove are formed as described with reference to FIG. 20 to FIG. 22. This order is common to all the processes of the process of forming the configuration corresponding to the structure ML₁, the process of forming the configuration corresponding to the structure ML₂, and the process of forming the configuration corresponding to the structure ML₃.

In the manufacture of the semiconductor memory device according to the second embodiment, the plurality of terrace portions TA are formed, and then the memory hole MH, the via hole HRA, and the configuration of the inside thereof are formed. This order is common to all the processes of the process of forming the configuration corresponding to the structure ML₂₁, the process of forming the configuration corresponding to the structure ML₂₂, and the process of forming the configuration corresponding to the structure ML₂₃.

However, such methods are merely examples, and the specific method can be adjusted as appropriate.

For example, in the manufacture of the semiconductor memory device according to the first embodiment, in a part of or all of the process of forming the configuration corresponding to the structure ML₁, the process of forming the configuration corresponding to the structure ML₂, and the process of forming the configuration corresponding to the structure ML₃, the plurality of terrace portions TA may be formed before the memory hole MH, the via hole HRA, and the configuration of the inside thereof. When the semiconductor memory device according to the first embodiment is formed with this method, in a part of or all of the structures ML₁, ML₂, ML₃, the height position of the upper end of the supporting insulating member HR is disposed above the height position of the corresponding terrace portion T.

Further, for example, in the manufacture of the semiconductor memory device according to the second embodiment, in a part of or all of the process of forming the configuration corresponding to the structure ML₂₁, the process of forming the configuration corresponding to the structure ML₂₂, and the process of forming the configuration corresponding to the structure ML₂₃, the memory hole MH, the via hole HRA, and the configuration of the inside thereof may be formed before the plurality of terrace portions TA. When the semiconductor memory device according to the second embodiment is formed with this method, in a part of or all of the structures ML₂₁, ML₂₂, ML₂₃, the height position of the upper end of the supporting insulating member HR is approximately matched with the height position of the corresponding terrace portion T.

### [Others]

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor memory device comprising:
a plurality of finger structures arranged in a first direction and extending in a second direction intersecting with the first direction;
a first inter-finger insulating member disposed between a first finger structure and a second finger structure adjacent in the first direction among the plurality of finger structures, the first inter-finger insulating member extending in a stacking direction intersecting with the first direction and the second direction and extending in the second direction; and
a plurality of bit lines disposed on one side in the stacking direction with respect to the plurality of finger structures and the first inter-finger insulating member, the plurality of bit lines being arranged in the second direction and extending in the first direction, wherein
each of the plurality of finger structures includes a first structure and a second structure disposed on a plurality of bit lines side in the stacking direction with respect to the first structure,
the first structure and the second structure include:
a plurality of conductive layers stacked in the stacking direction, extending in the second direction over a first region and a second region arranged in the second direction, and including a plurality of terrace portions disposed in the second region;
a first semiconductor column disposed in the first region, extending in the stacking direction, opposed to the plurality of conductive layers, and electrically connected to any of the plurality of bit lines;
a first electric charge accumulating film disposed between the plurality of conductive layers and the first semiconductor column; and
a plurality of insulating member rows disposed in the second region and arranged in the first direction, each of the plurality of insulating member rows including a plurality of insulating members different in position in the second direction, each of the plurality of insulating members having an outer peripheral surface at least partially surrounded by at least a part of the plurality of conductive layers when viewed in the stacking direction,
the first inter-finger insulating member widens in the first direction from an opposite side of the plurality of bit lines in the stacking direction toward the plurality of bit lines side in the stacking direction in a portion at least partially over both of a position in the stacking direction corresponding to the first structure and a position in the stacking direction corresponding to the second structure of each of the plurality of finger structures in the second region,
among the plurality of insulating member rows in the first finger structure, an insulating member row disposed at a position closest to the second finger structure includes a first insulating member disposed at a first position in the second direction at the position in the stacking direction corresponding to the first structure of the first finger structure and a second insulating member disposed at the first position in the second direction at the position in the stacking direction corresponding to the second structure of the first finger structure,
among the plurality of insulating member rows in the second finger structure, an insulating member row disposed at a position closest to the first finger structure includes a third insulating member disposed at the first position in the second direction at the position in the stacking direction corresponding to the first structure of the second finger structure and a fourth insulating member disposed at the first position in the second direction at the position in the stacking direction corresponding to the second structure of the second finger structure, and
a distance in the first direction between the first insulating member and the third insulating member is smaller than a distance in the first direction between the second insulating member and the fourth insulating member.

2. The semiconductor memory device according to claim 1, wherein
a distance in the first direction between a center position in the first direction of the first insulating member and a center position in the first direction of the third insulating member is smaller than a distance in the first direction between a center position in the first direction of the second insulating member and a center position in the first direction of the fourth insulating member.

3. The semiconductor memory device according to claim 1, wherein
a length in the first direction of the first insulating member and a length in the first direction of the third insulating member are larger than a length in the first direction of the second insulating member and a length in the first direction of the fourth insulating member.

4. The semiconductor memory device according to claim 1, wherein
the first insulating member is spaced from the second insulating member, and
the third insulating member is spaced from the fourth insulating member.

5. The semiconductor memory device according to claim 1, wherein
the plurality of finger structures further include a third finger structure disposed on an opposite side of the first finger structure with respect to the second finger structure and adjacent to the second finger structure in the first direction,
among the plurality of insulating member rows in the second finger structure, an insulating member row disposed at a position closest to the third finger structure includes a fifth insulating member disposed at the first position in the second direction at the position in the stacking direction corresponding to the first structure of the second finger structure and a sixth insulating member disposed at the first position in the second direction at the position in the stacking direction corresponding to the second structure of the second finger structure,
among the plurality of insulating member rows in the third finger structure, an insulating member row disposed at a position closest to the second finger structure includes a seventh insulating member disposed at the first position in the second direction at the position in the stacking direction corresponding to the first structure of the third finger structure and an eighth insulating member disposed at the first position in the second direction at the position in the stacking direction corresponding to the second structure of the third finger structure,
the sixth insulating member is disposed at a position overlapping with the fifth insulating member when viewed in the stacking direction, and
the eighth insulating member is disposed at a position overlapping with the seventh insulating member when viewed in the stacking direction.

6. The semiconductor memory device according to claim 5, further comprising
a second inter-finger insulating member disposed between the second finger structure and the third finger structure and extending in the stacking direction and the second direction, wherein
the first inter-finger insulating member has a width in the first direction at the first position larger than a width in the first direction at the first position of the second inter-finger insulating member.

7. The semiconductor memory device according to claim 6, wherein
each of the plurality of conductive layers:
further extends to a third region arranged in the second direction with respect to the second region and disposed on an opposite side of the first region with respect to the second region, in addition to the first region and the second region; and
further includes a connecting portion disposed in the second region, extending in the second direction, and connecting a part disposed in the first region to a part disposed in the third region,
the first structure and the second structure further include:
a second semiconductor column disposed in the third region, extending in the stacking direction, opposed to the plurality of conductive layers, and electrically connected to any of the plurality of bit lines; and
a second electric charge accumulating film disposed between the plurality of conductive layers and the second semiconductor column, and
the terrace portions of the plurality of conductive layers included in the second finger structure are disposed on a first inter-finger insulating member side with respect to the connecting portion.

8. The semiconductor memory device according to claim 1, wherein
the plurality of finger structures further include a third finger structure disposed on an opposite side of the first finger structure with respect to the second finger structure and adjacent to the second finger structure in the first direction,
among the plurality of insulating member rows in the second finger structure, an insulating member row disposed at a position closest to the third finger structure includes a fifth insulating member disposed at the first position in the second direction at the position in the stacking direction corresponding to the first structure of the second finger structure and a sixth insulating member disposed at the first position in the second direction at the position in the stacking direction corresponding to the second structure of the second finger structure,
among the plurality of insulating member rows in the third finger structure, an insulating member row disposed at a position closest to the second finger structure includes a seventh insulating member disposed at the first position in the second direction at the position in the stacking direction corresponding to the first structure of the third finger structure and an eighth insulating member disposed at the first position in the second direction at the position in the stacking direction corresponding to the second structure of the third finger structure,
a distance in the first direction between the fifth insulating member and the seventh insulating member is smaller than a distance in the first direction between the sixth insulating member and the eighth insulating member.

9. The semiconductor memory device according to claim 8, further comprising
a second inter-finger insulating member disposed between the second finger structure and the third finger structure and extending in the stacking direction and the second direction, wherein
the second inter-finger insulating member widens in the first direction from the opposite side of the plurality of bit lines in the stacking direction toward the plurality of bit lines side in the stacking direction in a portion at least partially over both of the position in the stacking direction corresponding to the first structure and the position in the stacking direction corresponding to the second structure of each of the plurality of finger structures in the second region.

10. The semiconductor memory device according to claim 9, wherein
the plurality of terrace portions are disposed at end portions in the second direction of the plurality of conductive layers.

11. The semiconductor memory device according to claim 1, wherein
the first inter-finger insulating member widens in the first direction from the first position in the second direction toward a second position in the second direction in the second region,
a distance in the first direction between one insulating member among the plurality of insulating members disposed at the first position at a position in the stacking direction corresponding to at least one of the first structure or the second structure of the first finger structure in a first insulating member row disposed at the position closest to the second finger structure among the plurality of insulating member rows in the first finger structure and another one insulating member among the plurality of insulating members disposed at the first position at the position in the stacking direction corresponding to at least one of the first structure or the second structure of the second finger structure in a second insulating member row disposed at the position closest to the first finger structure among the plurality of insulating member rows in the second finger structure is smaller than a distance in the first direction between one insulating member among the plurality of insulating members disposed at the second position at the position in the stacking direction corresponding to at least one of the first structure or the second structure of the first finger structure in the first insulating member row and another one insulating member among the plurality of insulating members disposed at the second position at the position in the stacking direction corresponding to at least one of the first structure or the second structure of the second finger structure in the second insulating member row.

12. A semiconductor memory device comprising:
a plurality of finger structures arranged in a first direction and extending in a second direction intersecting with the first direction; and
a first inter-finger insulating member disposed between a first finger structure and a second finger structure adjacent in the first direction among the plurality of finger structures, the first inter-finger insulating member extending in a stacking direction intersecting with the first direction and the second direction and extending in the second direction, wherein
each of the plurality of finger structures includes:
a plurality of conductive layers stacked in the stacking direction, extending in the second direction over a first region and a second region arranged in the second direction, and including a plurality of terrace portions disposed in the second region;
a semiconductor column disposed in the first region, extending in the stacking direction, and opposed to the plurality of conductive layers;
an electric charge accumulating film disposed between the plurality of conductive layers and the semiconductor column; and
a plurality of insulating member rows disposed in the second region and arranged in the first direction, each of the plurality of insulating member rows including a plurality of insulating members different in position in the second direction, each of the plurality of insulating members having an outer peripheral surface at least partially surrounded by at least a part of the plurality of conductive layers when viewed in the stacking direction,
the first inter-finger insulating member widens in the first direction from a first position in the second direction toward a second position in the second direction in the second region, and
a distance in the first direction between a first insulating member disposed at the first position in a first insulating member row disposed at a position closest to the second finger structure among the plurality of insulating member rows in the first finger structure and a second insulating member disposed at the first position in a second insulating member row disposed at a position closest to the first finger structure among the plurality of insulating member rows in the second finger structure is smaller than a distance in the first direction between a third insulating member disposed at the second position in the first insulating member row and a fourth insulating member disposed at the second position in the second insulating member row.

13. The semiconductor memory device according to claim 12, further comprising
a plurality of bit lines disposed on one side in the stacking direction with respect to the plurality of finger structures and the first inter-finger insulating member, the plurality of bit lines being arranged in the second direction and extending in the first direction, wherein
the first position corresponds to a terrace portion of a first conductive layer disposed at a third position in the stacking direction among the plurality of conductive layers in the first finger structure, and a terrace portion of a second conductive layer disposed at the third position in the stacking direction among the plurality of conductive layers in the second finger structure, and
the second position corresponds to a terrace portion of a third conductive layer disposed at a fourth position in the stacking direction at an opposite side of the plurality of bit lines with respect to the third position among the plurality of conductive layers in the first finger structure, and a terrace portion of a fourth conductive layer disposed at the fourth position in the stacking direction among the plurality of conductive layers in the second finger structure.

14. The semiconductor memory device according to claim 12, wherein
the plurality of finger structures further include a third finger structure disposed on an opposite side of the first finger structure with respect to the second finger structure and adjacent to the second finger structure in the first direction, and
a distance in the first direction between a fifth insulating member disposed at the first position in a third insulating member row disposed at a position closest to the third finger structure among the plurality of insulating member rows in the second finger structure and a sixth insulating member disposed at the first position in a fourth insulating member row disposed at a position closest to the second finger structure among the plurality of insulating member rows in the third finger structure, and a distance in the first direction between a seventh insulating member disposed at the second position in the third insulating member row and an eighth insulating member disposed at the second position in the fourth insulating member row are smaller than a distance in the first direction between the third insulating member and the fourth insulating member.

15. The semiconductor memory device according to claim 14, further comprising
a second inter-finger insulating member disposed between the second finger structure and the third finger structure and extending in the stacking direction and the second direction, wherein
a width in the first direction at the second position of the first inter-finger insulating member is larger than a width in the first direction at the second position of the second inter-finger insulating member.

16. The semiconductor memory device according to claim 12, wherein
the plurality of finger structures further include a third finger structure disposed on an opposite side of the first finger structure with respect to the second finger structure and adjacent to the second finger structure in the first direction, and
a distance in the first direction between a ninth insulating member disposed at the first position in a third insulating member row disposed at a position closest to the third finger structure among the plurality of insulating member rows in the second finger structure and a tenth insulating member disposed at the first position in a fourth insulating member row disposed at a position closest to the second finger structure among the plurality of insulating member rows in the third finger structure is smaller than a distance in the first direction between an eleventh insulating member disposed at the second position in the third insulating member row and a twelfth insulating member disposed at the second position in the fourth insulating member row.

17. The semiconductor memory device according to claim 16, further comprising
a second inter-finger insulating member disposed between the second finger structure and the third finger structure and extending in the stacking direction and the second direction, wherein
the second inter-finger insulating member widens in the first direction from the first position in the second direction toward the second position in the second direction in the second region.

18. A semiconductor memory device comprising:
a plurality of finger structures arranged in a first direction and extending in a second direction intersecting with the first direction;
a first inter-finger insulating member disposed between a first finger structure and a second finger structure adjacent in the first direction among the plurality of finger structures, the first inter-finger insulating member extending in a stacking direction intersecting with the first direction and the second direction and extending in the second direction; and
a plurality of bit lines disposed on one side in the stacking direction with respect to the plurality of finger structures and the first inter-finger insulating member, the plurality of bit lines being arranged in the second direction and extending in the first direction, wherein
each of the plurality of finger structures includes a first structure and a second structure disposed on a plurality of bit lines side in the stacking direction with respect to the first structure,
the first structure and the second structure include:
a plurality of conductive layers stacked in the stacking direction, extending in the second direction over a first region and a second region arranged in the second direction, and including a plurality of terrace portions disposed in the second region;
a semiconductor column disposed in the first region, extending in the stacking direction, opposed to the plurality of conductive layers, and electrically connected to any of the plurality of bit lines;
an electric charge accumulating film disposed between the plurality of conductive layers and the semiconductor column; and
a plurality of insulating member rows disposed in the second region and arranged in the first direction, each of the plurality of insulating member rows including a plurality of insulating members different in position in the second direction, each of the plurality of insulating members having an outer peripheral surface at least partially surrounded by at least a part of the plurality of conductive layers when viewed in the stacking direction,
the first inter-finger insulating member widens in the first direction from an opposite side of the plurality of bit lines in the stacking direction toward the plurality of bit lines side in the stacking direction in a portion at least partially over both of a position in the stacking direction corresponding to the first structure and a position in the stacking direction corresponding to the second structure of each of the plurality of finger structures in the second region,
among the plurality of insulating member rows in the first finger structure, an insulating member row disposed at a position closest to the second finger structure includes a first insulating member disposed at a first position in the second direction at the position in the stacking direction corresponding to the first structure of the first finger structure and a second insulating member disposed at the first position in the second direction at the position in the stacking direction corresponding to the second structure of the first finger structure, and
a length in the first direction of the first insulating member is larger than a length in the first direction of the second insulating member.

19. The semiconductor memory device according to claim 18, wherein
among the plurality of insulating member rows in the second finger structure, an insulating member row disposed at a position closest to the first finger structure includes a third insulating member disposed at the first position in the second direction at the position in the stacking direction corresponding to the first structure of the second finger structure and a fourth insulating member disposed at the first position in the second direction at the position in the stacking direction corresponding to the second structure of the second finger structure, and
a length in the first direction of the third insulating member is larger than a length in the first direction of the fourth insulating member.

20. The semiconductor memory device according to claim 19, wherein
a distance in the first direction between a center position in the first direction of the first insulating member and a center position in the first direction of the third insulating member is smaller than a distance in the first direction between a center position in the first direction of the second insulating member and a center position in the first direction of the fourth insulating member.
